(19) United States
(12) Patent Application Publication
(10) Pub. No.: US 2014/0102877 A1
(43) Pub. Date: Apr. 17, 2014

(54) METHOD FOR USING SPUTTERING TARGET AND METHOD FOR MANUFACTURING OXIDE FILM

(71) Applicant: Semiconductor Energy Laboratory Co., Ltd., Atsugi-shi (JP)

(72) Inventor: Shunpei YAMAZAKI, Setagaya (JP)

(73) Assignee: Semiconductor Energy Laboratory Co., Ltd., Atsugi-shi (JP)

(21) Appl. No.: 14/054,081

(22) Filed: Oct. 15, 2013

(30) Foreign Application Priority Data
Oct. 17, 2012 (JP) 2012-230158
Nov. 30, 2012 (JP) 2012-263340

(51) Int. Cl. C23C 14/34

(52) U.S. Cl. CPC C23C 14/34
USPC 204/192.15

(57) ABSTRACT

A plasma space containing an ionized inert gas is formed in contact with a deposition surface and a surface of a sputtering target containing a polycrystalline oxide including a plurality of crystal grains with randomly oriented c-axes. A flat-plate-like sputtered particle is separated from a cleavage plane corresponding to a-b planes of the plurality of crystal grains by collision of the ionized inert gas with the surface of the sputtering target. The flat-plate-like sputtered particle is transferred to the deposition surface through the plasma space with its flat-plate-like shape substantially maintained. The flat-plate-like sputtered particle and another flat-plate-like sputtered particle charged with the same polarity repel each other and are deposited on the deposition surface so as to be adjacent to each other on a plane such that the c-axes are substantially perpendicular to the deposition surface.

### BACKGROUND OF THE INVENTION

1. Field of the Invention

The present invention relates to a sputtering target, a method for manufacturing a sputtering target, a method for using a sputtering target, a sputtering apparatus, a method for using a sputtering apparatus, an oxide film, a method for manufacturing an oxide film, a semiconductor device manufactured using an oxide film, and an electric device including a semiconductor device manufactured using an oxide film.

2. Description of the Related Art

Semiconductor elements, e.g., transistors manufactured using a semiconductor thin film which is formed over a substrate having an insulating surface such as a glass substrate (such transistors are also referred to as thin film transistors or TFTs for short) and diodes, are applied to a wide range of semiconductor devices such as integrated circuits (ICs) and image display devices (simply also referred to as display devices). A silicon-based semiconductor material is widely known as a material for a semiconductor thin film applicable to such a semiconductor element.

For example, a transistor with amorphous silicon can be formed over a larger glass substrate and therefore can be manufactured at low cost. However, it has low field-effect mobility. In contrast, a transistor with polycrystalline silicon has high field-effect mobility, but requires a crystallization process such as laser annealing and a large number of manufacturing steps and is not always suitable for a larger glass substrate.

Meanwhile, oxide semiconductors have attracted attention in recent years as novel semiconductor materials. Examples of oxide semiconductors include zinc oxide (ZnO), an In—Ga—Zn—O-based oxide semiconductor, and the like. Techniques are under development to manufacture a transistor which includes a semiconductor thin film formed using such an oxide semiconductor as a material for a channel formation region and to apply the transistor to ICs such as a CPU and a memory and semiconductor devices such as an active-matrix display device.

The use of an oxide semiconductor for a channel formation region makes it possible to manufacture a transistor which has both high field-effect mobility comparable to that obtained with polysilicon or microcrystalline silicon and uniform element characteristics comparable to those obtained with amorphous silicon. Since the transistor has high field-effect mobility, in the case where this is used in a display device for example, the transistor can have sufficient on-state current even when having a small area. Thus, an increase in aperture ratio of a pixel and/or a reduction of power consumption of a display device can be achieved. An oxide semiconductor film can be formed using a sputtering method and is thus suitable for manufacturing a semiconductor device over a large-area substrate. Manufacturing a semiconductor device over a large-area substrate can reduce the cost of manufacturing the semiconductor device. There is another advantage that capital investment can be reduced because part of production equipment for a transistor with an amorphous silicon film can be retrofitted and utilized.

In Non-Patent Document 1, it is reported that in the case of using a crystalline oxide semiconductor film for a channel formation region of a transistor, the electrical characteristics and reliability can be improved compared with the case of using an amorphous oxide semiconductor film.

Patent Document 1 discloses that a semiconductor element is manufactured using an oxide semiconductor such as zinc oxide or InGaO₃(ZnO)₅ and the semiconductor element is used to manufacture an integrated circuit or a display device. It is described that this oxide semiconductor film is formed using a sputtering method.

Patent Document 2 discloses a field-effect transistor which is manufactured using an amorphous oxide semiconductor containing In, Ga, and Zn and having an electron carrier concentration lower than 10¹⁸/cm³ as an active layer of the transistor. A sputtering method is considered to be the most suitable method for forming the oxide semiconductor film.

Patent Document 3 discloses that when a transistor is formed using an oxide semiconductor film of, particularly, an oxide material including crystals with c-axis alignment, which have hexagonal atomic arrangement when seen from the direction of the a-b planes, a surface, or an interface and which have a-axes or b-axes oriented in different directions on the a-b planes, the electrical characteristics of the transistor can be stabilized and a highly reliable semiconductor device can be manufactured. It is described that this oxide semiconductor film is formed using a sputtering method.

Oxide films including the above-described oxide semiconductor film, i.e., oxide films containing a metal element, are generally manufactured by a sputtering method using a sputtering target. It is widely known that a sputtering method is used to manufacture an electrode of a solar cell, a pixel electrode of a display device, or the like with a ZnO-based oxide film or the like as disclosed in Non-Patent Document 2.

A sputtering method (also referred to as a sputter method) is a technique for forming a film by depositing a target substance ejected from a sputtering target onto a substrate by applying a high DC voltage between the substrate and the sputtering target while introducing an inert gas such as an argon gas into a vacuum to ionize the inert gas and make the ionized inert gas collide with the target. At this time, a reactive gas such as oxygen or nitrogen may be introduced together with the inert gas, so that a film can be formed by reactive sputtering. Such a sputtering method can provide a film which has good adhesion to a substrate. In addition, the sputtering method can control the film thickness with high accuracy simply by controlling film formation time.

### REFERENCES

### Patent Documents

[Patent Document 1] Japanese Published Patent Application No. 2007-123861
[Patent Document 2] Japanese Published Patent Application No. 2006-165528
[Patent Document 3] United States Patent Application Publication No. 2012/0153364

### Non-Patent Documents

[Non-Patent Document 1] Shunpei Yamazaki, Jun Koyama, Yoshitaka Yamamoto and Kenji Okamoto, “Research, Development, and Application of Crystalline Oxide Semiconductor”, SID 2012 DIGEST, pp. 183-186
[Non-Patent Document 2] Nobuhiro Ogawa et al., “Study of ZAO Targets”, Journal of TOSOH Research, 1992, Vol. 36, No. 2, pp. 161-166

### SUMMARY OF THE INVENTION

In the case where an oxide film containing a metal element as described above is used for a channel formation region of a transistor, it is required for the oxide film to enable the transistor to exhibit favorable transistor characteristics and have high long-term reliability.

Although the oxide film containing a metal element has high controllability of the carrier density and can provide transistor characteristics with relative ease, it has the problem of being likely to become amorphous and having unstable properties. Therefore, it has been difficult to secure transistor reliability.

If a crystalline oxide film can be formed using a sputtering method, a conductive film with high conductivity, an insulating film with high withstand voltage, and the like can be expected to be formed and these films can be used in a variety of applications.

The above problem can be solved by using an oxide semiconductor film of an oxide material disclosed in Patent Document 3, i.e., an oxide material including crystals with c-axis alignment, which have hexagonal atomic arrangement when seen from the direction of the a-b planes, a surface, or an interface and which have a-axes or b-axes oriented in different directions on the a-b planes.

However, it is described in Non-Patent Document 2 that in order to increase the crystallinity of a ZnO-based transparent conductive film formed by a sputtering method, it is necessary to enhance c-axis alignment in a target used for sputtering. In the case where a target does not have c-axis alignment, it is difficult in principle to increase the crystallinity of a film, i.e., to manufacture an oxide semiconductor film including crystals with c-axis alignment, which have hexagonal atomic arrangement when seen from the direction of the a-b planes, a surface, or an interface and which have a-axes or b-axes oriented in different directions on the a-b planes.

Thus, a sputtering target with extremely high c-axis alignment should be manufactured in order to manufacture an oxide semiconductor film including crystals, with c-axis alignment, which have hexagonal atomic arrangement when seen from the direction of the a-b planes, a surface, or an interface and which have a-axes or b-axes oriented in different directions on the a-b planes, for obtaining a transistor exhibiting stable and favorable transistor characteristics as described above. In other words, it is ideal to manufacture a single-crystal sputtering target with c-axis alignment, but it is difficult to manufacture such a target with ease.

Therefore, it is an object of one embodiment of the present invention to provide a sputtering target with which it is possible to form a crystalline oxide film containing a metal element and having stable electrical characteristics or high reliability.

It is an object of one embodiment of the present invention to provide a method for manufacturing the sputtering target.

It is an object of one embodiment of the present invention to provide a sputtering apparatus with the sputtering target.

It is an object of one embodiment of the present invention to provide a method for using the sputtering apparatus with the sputtering target.

It is an object of one embodiment of the present invention to provide a crystalline oxide film containing a metal element and having stable electrical characteristics or high reliability.

It is an object of one embodiment of the present invention to provide a method for manufacturing the crystalline oxide film containing the metal element.

It is an object of one embodiment of the present invention to provide a semiconductor device including the crystalline oxide film containing the metal element.

Furthermore, it is an object of one embodiment of the present invention to provide an electric device including the semiconductor device.

One embodiment of the present invention can achieve at least one of the objects set forth above.

In view of the above, one embodiment of the present invention is a method for manufacturing an oxide film, in which a sputtering target containing a polycrystalline oxide including a plurality of crystal grains with randomly oriented c-axes is used, a flat-plate-like sputtered particle is separated from the plurality of crystal grains, and the sputtered particle is deposited on a deposition surface so as to be arranged such that the c-axis is substantially perpendicular to the deposition surface.

One embodiment of the present invention is a method for manufacturing an oxide film, in which a sputtering target containing a polycrystalline oxide including a plurality of crystal grains with randomly oriented c-axes is used, a plasma space containing an ionized inert gas is formed in contact with a surface of the sputtering target and a deposition surface, a flat-plate-like sputtered particle is separated from a cleavage plane corresponding to a-b planes of the plurality of crystal grains by collision of the ionized inert gas with the surface of the sputtering target, the flat-plate-like sputtered particle is transferred to the deposition surface through the plasma space with a flat-plate-like shape substantially maintained, the flat-plate-like sputtered particle and another flat-plate-like sputtered particle are charged with the same polarity, and the flat-plate-like sputtered particles charged with the same polarity repel each other and are deposited on the deposition surface so as to be adjacent to each other on a plane such that c-axes are substantially perpendicular to the deposition surface.

One embodiment of the present invention is a method for using a sputtering target, in which the sputtering target contains a polycrystalline oxide including a plurality of crystal grains with randomly oriented c-axes, and a plurality of flat-plate-like charged sputtered particles separated from the sputtering target are deposited on a deposition surface, repelling each other.

One embodiment of the present invention can provide a sputtering target with which it is possible to form a crystalline oxide film containing a metal element and having stable electrical characteristics or high reliability.

One embodiment of the present invention can provide a method for manufacturing the sputtering target.

One embodiment of the present invention can provide a sputtering apparatus with the sputtering target.

One embodiment of the present invention can provide a method for using the sputtering apparatus with the sputtering target.

One embodiment of the present invention can provide a crystalline oxide film containing a metal element and having stable electrical characteristics or high reliability.

One embodiment of the present invention can provide a method for manufacturing the crystalline oxide film containing the metal element.

One embodiment of the present invention can provide a semiconductor device including the crystalline oxide film containing the metal element.

One embodiment of the present invention can provide an electric device including the semiconductor device.

### BRIEF DESCRIPTION OF THE DRAWINGS

FIG. 1 is a schematic view illustrating the movement of a sputtered particle.

FIGS. 2A and 2B are enlarged views of a region of part of a sputtering target.

FIGS. 3A and 3B illustrate a crystal structure of an In—Ga—Zn oxide.

FIG. 4 illustrates a crystal structure of an In—Ga—Zn oxide.

FIGS. 5A and 5B illustrate a method for manufacturing a sputtering target.

FIG. 6 illustrates a film formation apparatus.

FIGS. 7A and 7B each illustrate a film formation apparatus.

FIGS. 8A and 8B each illustrate a film formation apparatus.

FIG. 9 illustrates a film formation apparatus.

FIGS. 10A to 10C each illustrate an oxide film.

FIGS. 11A to 11C are a top view and cross-sectional views of a transistor.

FIGS. 12A and 12B are each a cross-sectional view of a transistor.

FIGS. 13A to 13C are a top view and cross-sectional views of a transistor.

FIGS. 14A and 14B illustrate band structures of a stacked-layer oxide film.

FIGS. 15A and 15B illustrate band structures of a stacked-layer oxide film.

FIGS. 16A to 16C are each a cross-sectional view of a transistor.

FIGS. 17A to 17C are each a cross-sectional view of a transistor.

FIGS. 18A to 18E are cross-sectional views illustrating a method for manufacturing a transistor.

FIG. 19 is a circuit diagram of part of a pixel in a display module including an EL element.

FIGS. 20A to 20C are a top view and a cross-sectional view of a display module including an EL element and a cross-sectional view of a light-emitting layer.

FIGS. 21A and 21B are each a cross-sectional view of a display module including an EL element.

FIG. 22 is a circuit diagram of a pixel of a display module including a liquid crystal element.

FIGS. 23A to 23C are each a cross-sectional view of a display module including a liquid crystal element.

FIGS. 24A to 24C illustrate a display module including an FFS mode liquid crystal element.

FIGS. 25A and 25B are a circuit diagram and a cross-sectional view of an image sensor.

FIG. 26 illustrates a pixel region having a touch input function.

FIG. 27 is a cross-sectional view of a panel provided with a photosensor.

FIG. 28 is a circuit diagram of a semiconductor device.

FIGS. 29A to 29D are circuit diagrams, a cross-sectional view, and a diagram showing electrical characteristics of a semiconductor device.

FIGS. 30A to 30C are a circuit diagram, a diagram showing electrical characteristics, and a cross-sectional view of a semiconductor device.

FIGS. 31A to 31C are block diagrams illustrating a configuration of a CPU.

FIG. 32 is a block diagram illustrating a configuration of a microcomputer.

FIGS. 33A to 33C each illustrate a configuration of a nonvolatile memory element.

FIG. 34 illustrates a circuit configuration of a register.

FIG. 35 illustrates the operation of a microcomputer.

FIGS. 36A to 36F illustrate electric devices.

FIG. 37 is a reflection electron image of a sample.

FIGS. 38A and 38B are a crystal grain map and a histogram of crystal grain sizes.

FIGS. 39A and 39B show the results of XRD measurement.

FIG. 40 is a TEM image of an oxide film.

FIGS. 41A, 41B1, 41B2, 41C1, and 41C2 are diagrams for explaining discharge states in an AC sputtering method.

### DETAILED DESCRIPTION OF THE INVENTION

Embodiments of the present invention will be described in detail below with reference to the drawings. Note that the present invention is not limited to the description in these embodiments, and it is easily understood by those skilled in the art that modes and aspects of the present invention can be modified in various ways. Therefore, the present invention should not be construed as being limited to the description in the embodiments given below.

Note that in each drawing described in this specification, the size of each component, such as the thickness of a film, a layer, a substrate, or the like or the size of a region is exaggerated for clarity in some cases. Therefore, each component is not necessarily limited in size and not necessarily limited in size relative to another component.

Note that ordinal numbers such as “first” and “second” in this specification and the like are used for convenience and do not denote the order of steps, the stacking order of layers, and the like. In addition, the ordinal numbers in this specification and the like do not denote any particular names to define the invention.

Note that in the structures of the present invention described in this specification and the like, the same portions or portions having similar functions in different drawings are denoted by the same reference numerals, and description of such portions is not repeated. Further, the same hatch pattern is applied to parts having similar functions, and the parts are not especially denoted by reference numerals in some cases.

Note that the term “over” or “under” in this specification and the like does not necessarily mean that a component is placed “directly on and above” or “directly on and below” another component. For example, the expression “a gate electrode over a gate insulating layer” does not exclude the case where a component is placed between the gate insulating layer and the gate electrode.

In addition, the term such as “electrode” or “wiring” in this specification and the like does not limit a function of a component. For example, an “electrode” can be used as part of a “wiring”, and the “wiring” can be used as part of the “electrode”. Furthermore, the term “electrode” or “wiring” can include the case where a plurality of “electrodes” or “wirings” are formed in an integrated manner.

Functions of a “source” and a “drain” are sometimes interchanged with each other when a transistor of opposite polarity is used or when the direction of current flowing is changed in circuit operation, for example. Therefore, the terms “source” and “drain” can be used to denote the drain and the source, respectively, in this specification and the like.

Note that the term “electrically connected” in this specification and the like includes the case where components are connected through an “object having any electric function”. There is no particular limitation on an object having any electric function as long as electric signals can be transmitted and received between components that are connected through the object.

Examples of an “object having any electric function” include a switching element such as a transistor, a resistor, an inductor, a capacitor, and an element with a variety of functions, as well as an electrode and a wiring.

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “perpendicular” indicates that the angle formed between two straight lines is greater than or equal to 80° and less than or equal to 100°, and accordingly includes the case where the angle is greater than or equal to 85° and less than or equal to 95°.

### 1. First Embodiment

### Sputtering Method and Mechanism Thereof

In this embodiment, a method for forming a film by sputtering in one embodiment of the present invention and a mechanism thereof will be described.

### [1.1. Film Formation Conditions or Environment]

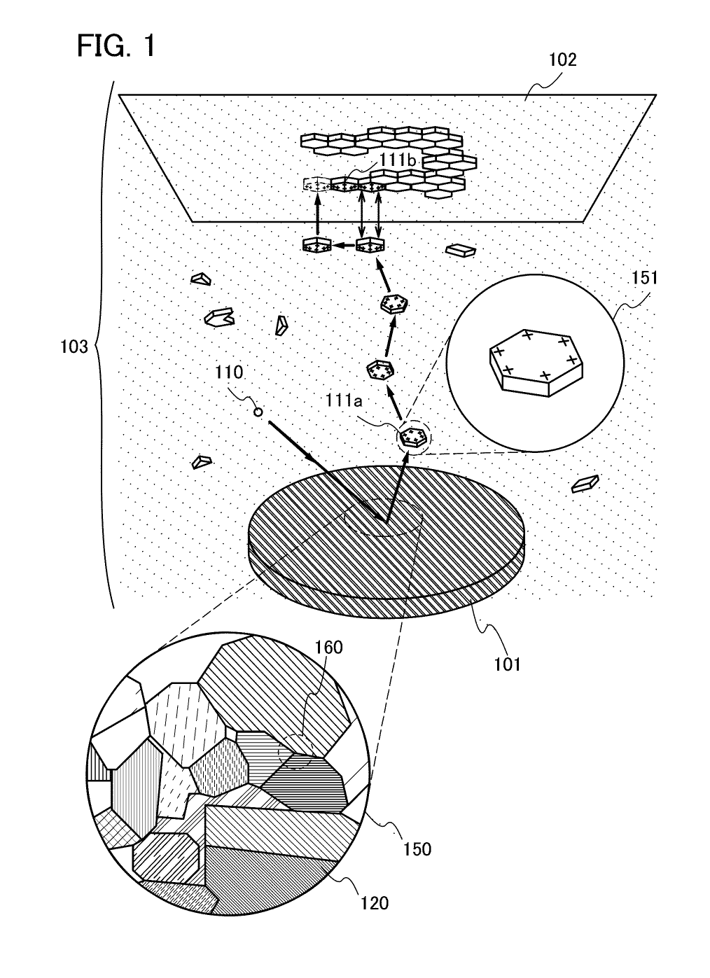

FIG. 1 is a schematic diagram illustrating how an oxide film is formed on a deposition surface 102 using a sputtering target 101.

First, the sputtering target 101 illustrated in FIG. 1 and used for the formation of the oxide film will be described.

As illustrated in an enlarged portion 150 of part of the sputtering target 101, the sputtering target 101 contains a polycrystalline oxide including a plurality of crystal grains 120. For the sputtering target 101, a compound containing indium (In), gallium (Ga), zinc (Zn), and oxygen (O) can be used as a material, for example.

Although the sputtering target 101 in FIG. 1 has a circular shape, the shape is not limited to the circular shape and may be a rectangular shape or another shape.

The plurality of crystal grains 120 may have different grain sizes and different shapes as illustrated in FIG. 1.

The c-axes of the plurality of crystal grains 120 are oriented randomly. In addition, each of the plurality of crystal grains 120 has a crystal structure in the form of a hexagonal prism. Note that in the crystal structure in the form of a hexagonal prism, a plane parallel to a hexagonal plane is the a-b plane, and a direction perpendicular to the hexagonal plane is the c-axis direction, unless otherwise specified. The orientation of the plurality of crystal grains can be measured by electron backscatter diffraction (EBSD).

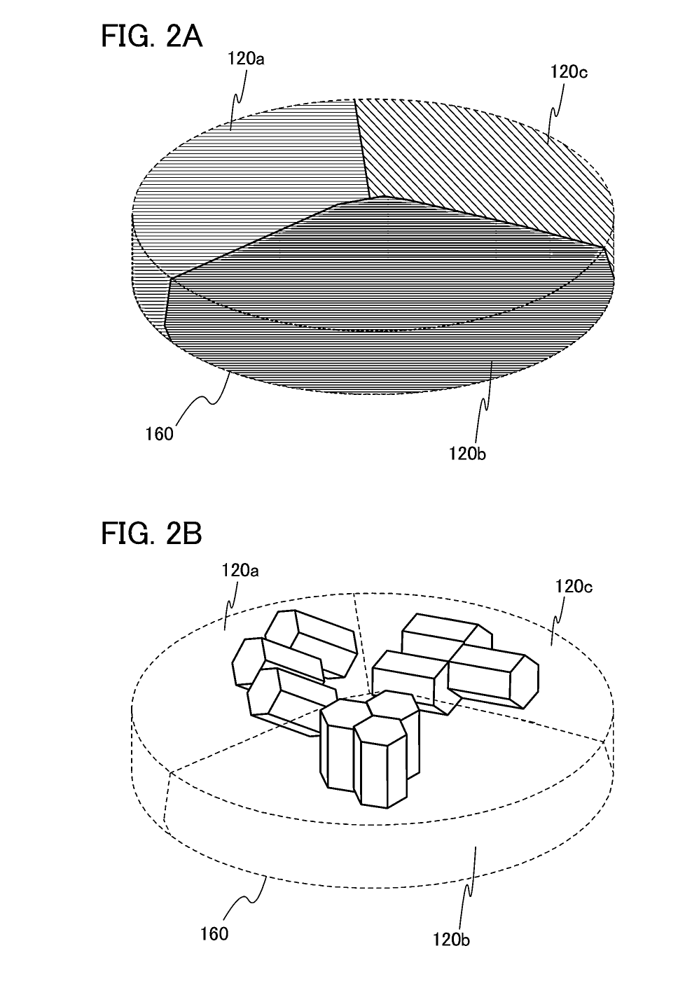

Furthermore, an enlarged view of a region 160 in the enlarged portion 150 in FIG. 1 is illustrated in FIG. 2A.

FIG. 2A illustrates part of a crystal grain 120a, a crystal grain 120b, and a crystal grain 120c of the plurality of crystal grains 120.

Furthermore, in FIG. 2B, the crystal grain 120a, the crystal grain 120b, and the crystal grain 120c in FIG. 2A are indicated with dotted lines.

As illustrated in FIG. 2B, each of the crystal grains 120a to 120c has a crystal structure in the form of a hexagonal prism. In addition, the c-axes of the crystal grains 120a to 120c each having the crystal structure in the form of a hexagonal prism are oriented randomly.

As described above, the sputtering target 101 in one embodiment of the present invention has a structure in which the c-axes of the plurality of crystal grains 120 are oriented randomly.

In the case where a material forming the deposition surface 102 has a crystal structure, a mismatch occurs between the lattice constant of the deposition surface 102 and the lattice constant of a sputtered particle deposited on the deposition surface 102, and lattice distortion is generated. In addition, in the case where the material forming the deposition surface 102 has a crystal structure, similar distortion is generated due to internal stress in the crystal structure. Therefore, in such a case, the crystallinity of an oxide film formed by deposition of sputtered particles might be lowered. Furthermore, when the deposition surface 102 has minute surface unevenness, the crystallinity of an oxide film to be formed might be lowered.

Therefore, in order to form an oxide film having high crystallinity, a surface of a material having an amorphous structure is suitable for the deposition surface 102 where sputtered particles are deposited. In the case of the material having an amorphous structure, there is no or little internal stress in a particular direction, and the generation of distortion resulting from a crystal structure is suppressed. In addition, it is effective to increase the planarity of the deposition surface 102.

As such a material having an amorphous structure, an insulating film such as a silicon oxide film, a silicon oxynitride film, a silicon nitride oxide film, or a silicon nitride film having an amorphous structure, an oxide film having an amorphous structure, or the like may be used, for example.

In the case where a multilayer film of stacked oxide films in one embodiment of the present invention, which is described later, is used in a transistor, it is preferable to use an amorphous oxide film as a layer below an oxide film where a channel is formed, in order to increase the crystallinity of the oxide film.

In addition, it is preferable that there be no adsorbed water on the deposition surface 102, in order to improve the film properties of an oxide film to be formed. Thus, the deposition surface 102 may be subjected to treatment for removing adsorbed water, for example. Adsorbed water can be removed or reduced by performing heat treatment of a substrate having the deposition surface 102 at a temperature of 100° C. or higher, for example. Note that the deposition surface 102 of the substrate is not limited to a surface of the substrate itself, and includes an outermost exposed surface of a film or a structure formed over the substrate.

Furthermore, it is preferable that the deposition surface 102 include an insulating surface, in order to prevent an electric charge carried by a deposited sputtered particle from being easily lost.

Next, it is described how an oxide film is formed by sputtering.

As illustrated in FIG. 1, a plasma space 103 containing an ionized inert gas is formed in contact with a surface of the sputtering target 101 and the deposition surface 102. Since the plasma space 103 is formed in contact with the deposition surface 102, a sputtered particle can be efficiently moved to the deposition surface 102.

Alternatively, a magnetron may be used in a film formation apparatus so that the plasma space 103 in the vicinity of the sputtering target 101 can be densified by a magnetic field. In a film formation apparatus using magnetron sputtering, a magnet assembly is located behind a sputtering target so that a magnetic field can be formed in front of the sputtering target, for example. In sputtering of the sputtering target, the magnetic field captures an ionized electron or a secondary electron generated by sputtering. The thus captured electron has an increased probability of collision with an inert gas such as a rare gas in a film formation chamber, thereby increasing the plasma density. Accordingly, the rate of film formation can be increased without a significant increase in temperature of the deposition surface, for example.

As the ionized inert gas, a gas containing oxygen (O), a gas containing a rare gas element, or a gas containing oxygen and a rare gas element can be used, for example. As the rare gas element, argon (Ar) or the like is preferably used.

### [1.2. Separation of Sputtered Particle]

As illustrated in FIG. 1, an ion 110 in the ionized inert gas described above is made to collide with the sputtering target 101, whereby a flat-plate-like sputtered particle 111a is separated from a cleavage plane corresponding to the a-b planes of the crystal grains. Since the sputtered particle 111a is separated from the cleavage plane of the crystal grains 120 each having the crystal structure in the form of a hexagonal prism, the sputtered particle 111a has a flat-plate-like (also referred to as pellet-like) shape. The cleavage plane here refers to a portion with weak crystal bonding (or a plane where cleavage occurs or a plane where cleavage is likely to occur). Flat-plate-like sputtered particles 111a are separated from a cleavage plane corresponding to the a-b planes of a plurality of crystal grains, at the same time or at different timings. Note that in FIG. 1, the sizes of the ion 110 and the sputtered particle 111a are schematically illustrated for convenience of explanation and differ from their actual sizes or scales.

As the ion 110, a cation of oxygen or a cation of a rare gas element can be used, for example. With the use of a cation of oxygen, for example, it is possible to reduce plasma damage to the surface of the sputtering target 101 during film formation. Accordingly, it is possible to prevent the surface of the sputtering target 101 from having lower crystallinity or becoming amorphous by collision of the ion 110 with the surface of the sputtering target 101.

As the cation of a rare gas element, an argon ion (Ar⁺) can be used, for example.

Although one sputtered particle 111a is separated by collision of one ion 110 in FIG. 1 for convenience of explanation, there is a case where one sputtered particle 111a is separated by collision of a plurality of ions 110 with the surface of the sputtering target 101 at the same time or at different timings. There is also a case where a plurality of sputtered particles 111a are separated by collision of one ion 110 with the surface of the sputtering target 101. The number of separated sputtered particles 111a with respect to the number of ions 110 colliding with the surface of the sputtering target 101 changes depending on the power of a sputtering apparatus, for example.

Here, the separated sputtered particle 111a is preferably charged with positive or negative polarity. At this time, a pair of hexagonal surfaces of the sputtered particle 111a is preferably charged. Note that a case is described in this embodiment as one example in which the sputtered particle 111a is positively charged, but the present invention is not limited to this example and there is also a case in which the sputtered particle 111a is negatively charged. In addition, as indicated in an enlarged portion 151, the sputtered particle 111a having a hexagonal shape may be charged along the sides of the hexagon. When the sputtered particle 111a is charged along the sides of the hexagon, charges on the opposite sides repel each other, the deformation of the sputtered particle 111a flying in the plasma space 103 can be reduced, and the sputtered particle 111a can substantially maintain its flat-plate-like shape. Furthermore, there is a case where the charged sputtered particle 111a is neutralized with plasma having the polarity opposite to that of the charge of the sputtered particle 111a and is then charged again.

In the case where a plurality of sputtered particles 111a are separated, it is preferable that the plurality of sputtered particles 111a be all charged with the same polarity.

There is no limitation on the timing when the sputtered particle 111a is charged. For example, there are cases where the sputtered particle 111a is charged at the time of collision of the ion 110, where the sputtered particle 111a is charged by being exposed to plasma in the plasma space 103, and where the sputtered particle 111a is charged by bonding of the ion 110 to a side surface, the upper surface, or the lower surface of the flat-plate-like sputtered particle 111a.

### [1.3. Flight of Sputtered Particle]

As illustrated in FIG. 1, the separated sputtered particle 111a is transferred to the deposition surface 102 through the plasma space 103 with its flat-plate-like shape substantially maintained. At this time, the sputtered particle 111a is preferably kept charged. In the case where the sputtered particle 111a is charged, the sputtered particle 111a maintains its shape while in flight, owing to the charge distribution over the surface of the sputtered particle 111a. Therefore, the sputtered particle 111a can move like a kite between the surface of the sputtering target 101 and the deposition surface 102 with its flat-plate-like shape substantially maintained and can reach the deposition surface 102 with its flat-plate-like shape substantially maintained.

Note that in FIG. 1, as one example, the deposition surface 102 is positioned above the sputtering target 101 and the sputtered particle 111a moves upward. However, there is no limitation on the positional relationship between the sputtering target 101 and the deposition surface 102. For example, the deposition surface 102 may be positioned below the sputtering target 101 and the sputtered particle 111a may be moved downward from the sputtering target 101 to the deposition surface 102. Alternatively, the sputtering target 101 and the deposition surface 102 may be set so as to be vertical and face each other and the sputtered particle 111a may be moved from the sputtered target 101 to the deposition surface 102.

The sputtered particle 111a reaching the deposition surface 102 is deposited on the deposition surface 102 like a hang glider such that the a-b plane is substantially parallel to the deposition surface 102. The sputtered particle 111a separated in the above manner has high crystallinity because it is formed by separating part of the crystal grains 120. Therefore, by arrival of the sputtered particle 111a at the deposition surface, an oxide film with high crystallinity can be formed.

### [1.4. Deposition of Sputtered Particle, Formation of Oxide Film]

The flat-plate-like sputtered particle 111a is highly likely to adhere to the deposition surface so that the cleavage plane and the deposition surface 102 become parallel to each other. In the case where the separated sputtered particle 111a is charged as illustrated in FIG. 1, the separated sputtered particle 111a repels a sputtered particle 111b which has already been deposited on the deposition surface 102, whereby the sputtered particle 111a moves to and is deposited on a region where the sputtered particle 111b is not present. Furthermore, a sputtered particle may be deposited on a region where a plurality of sputtered particles 111a are present, so as to be stacked thereon. At this time, the charges carried by the deposited sputtered particles 111a may be lost.

On the other hand, in the case where the sputtered particles 111a are not charged, the sputtered particles 111a are randomly deposited on the deposition surface 102. Therefore, the sputtered particles 111a are disorderly deposited on regions including a region where another sputtered particle has already been deposited. Thus, in the case where the sputtered particles 111a are not charged, an oxide film obtained by deposition does not have uniform thickness and has disordered crystal orientation.

When the sputtered particle 111a is deposited on the deposition surface 102 so as to be adjacent to the sputtered particle 111b as described above, it is possible to form an oxide film where no grain boundary can be found even when observed with a transmission electron microscope (also referred to as TEM), for example. In addition, the sputtered particle 111a and the sputtered particle 111b are deposited such that the c-axes are substantially perpendicular to the deposition surface 102. Therefore, crystal parts in a formed oxide film are each oriented in one crystal axis direction. For example, in the case where the cleavage plane of crystal grains is parallel to the a-b planes, crystal parts of the oxide film have c-axis alignment. In other words, the normal vector of the deposition surface is parallel to the c-axis of each crystal part included in the oxide film. However, the a-axis is freely rotatable around the c-axis, and therefore, a plurality of crystal parts included in the oxide film have non-uniform a-axis directions.

In addition, since sputtered particles are orderly arranged on the deposition surface 102 through such a sputtering process, an oxide film formed on the deposition surface 102 has an extremely flat upper surface. The flatness of the upper surface of the oxide film contributes to improvement of electrical characteristics of a transistor manufactured using the oxide film for a channel formation region.

Note that the deposition surface 102 preferably has an insulating surface. Alternatively, the substrate having the deposition surface 102 is preferably in an electrically floating state in a film formation apparatus. This can prevent a charge carried by a sputtered particle deposited on the deposition surface 102 from being easily lost. Note that in the case where the rate of deposition of a sputtered particle is lower than the rate of charge loss, the deposition surface 102 may have conductivity.

In the above-described manner, a plurality of flat-plate-like sputtered particles charged with the same polarity repel each other at the deposition surface 102, whereby a separated sputtered particle moves to and is deposited on a region where another sputtered particle is not present. In addition, the plurality of flat-plate-like sputtered particles are deposited so as to be adjacent to each other on a plane and such that the c-axes are substantially perpendicular to the deposition surface.

The above is the description of the method for forming a film by sputtering in one embodiment of the present invention and the mechanism thereof.

In this embodiment, as described with reference to FIG. 1 and FIGS. 2A and 2B, an oxide film with high crystallinity and with a c-axis arranged so as to be substantially perpendicular to a deposition surface can be formed using a sputtering target containing a polycrystalline oxide including a plurality of crystal grains with randomly oriented c-axes.

This embodiment can be implemented in appropriate combinations with any of the other embodiments.

### 2. Second Embodiment

### Sputtering Target

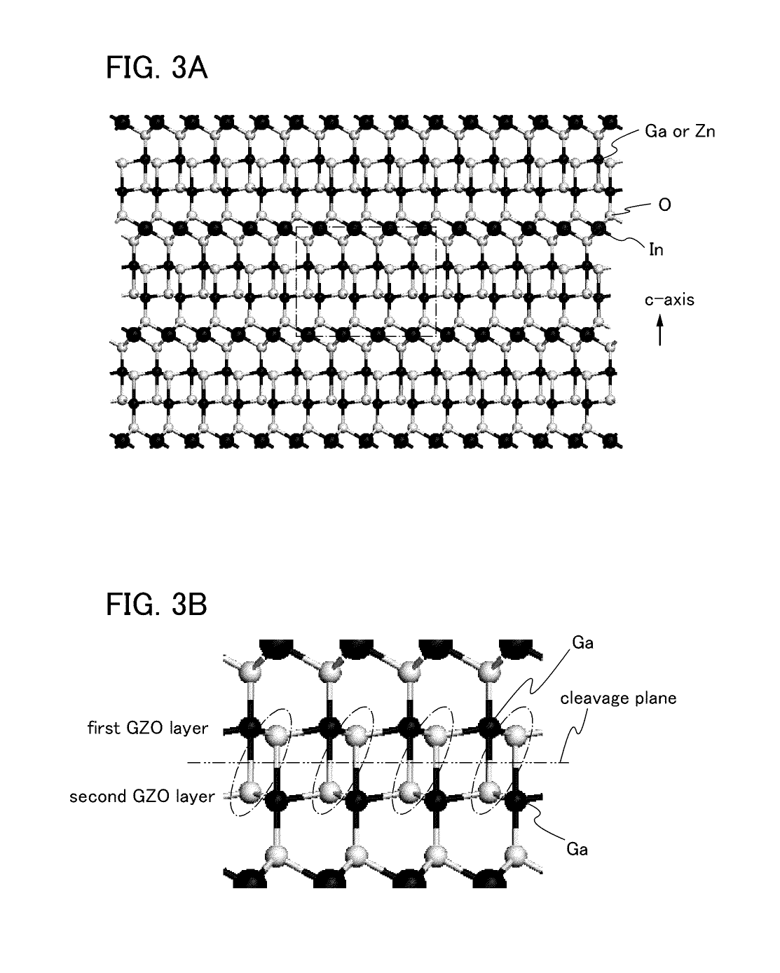

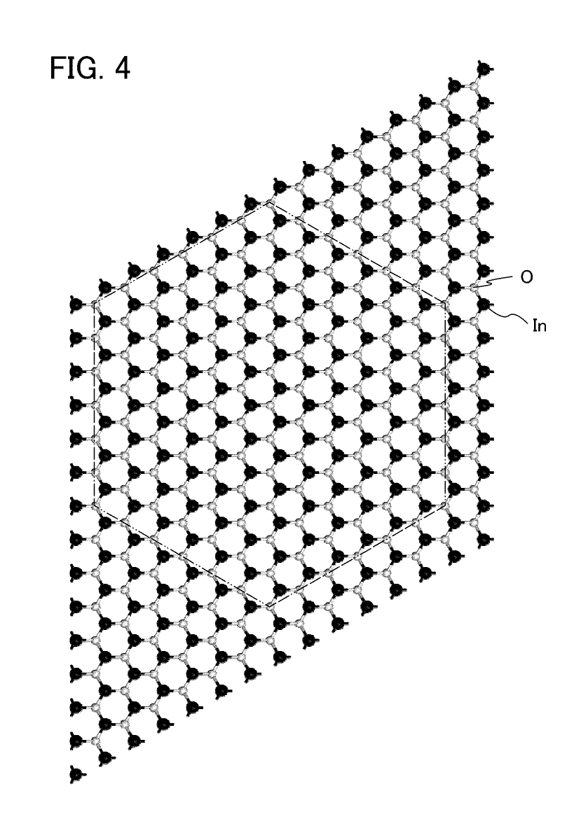

In this embodiment, a sputtering target in one embodiment of the present invention will be described with reference to FIGS. 3A and 3B and FIG. 4.

### [2.1. Sputtering Target]

A sputtering target in one embodiment of the present invention contains a polycrystalline oxide including a plurality of crystal grains with randomly oriented c-axes.

The plurality of crystal grains included in the sputtering target have a cleavage plane. The cleavage plane is, for example, a plane parallel to the a-b planes.

In the case where the plurality of crystal grains included in the sputtering target have a hexagonal crystal structure, a flat-plate-like sputtered particle separated in sputtering has a crystal structure in the form of a hexagonal prism having substantially regular hexagonal upper and lower surfaces with an interior angle of 120°.

The sputtered particle is ideally single crystal, but may be partly amorphous due to the effect of collision of an ion.

As the polycrystalline oxide contained in the sputtering target, an oxide containing In, M (M is Ga, Sn, Al, La, Ce, Pr, Nd, Sm, Eu, Gd, Tb, Dy, Ho, Er, Tm, Yb, or Lu), and Zn or the like can be used. The oxide containing In, m, and Zn is also referred to as an In-M-Zn oxide.

For example, in the In-M-Zn oxide, the cleavage plane is likely to be a plane parallel to the a-b plane where M and Zn are mixed.

Note that the plurality of crystal grains preferably have an average grain size of 3 μm or less, more preferably 2.5 μm or less, further preferably 2 μm or less.

Alternatively, the sputtering target contains a polycrystalline oxide including a plurality of crystal grains, of which 8% or more, preferably 15% or more, more preferably 25% or more, have a gain size of 0.4 μm to 1 μm.

When the plurality of crystal grains have a small gain size, a sputtered particle is separated from the cleavage plane by collision of an ion with the sputtering target. The separated sputtered particle has a flat-plate-like shape with upper and lower surfaces parallel to the cleavage plane. In addition, when the plurality of crystal grains have a small gain size, crystal distortion occurs and separation from the cleavage plane becomes easy.

Note that the grain size of the plurality of crystal grains can be measured by EBSD, for example. The grain size of a crystal grain here is calculated from a measured cross-sectional area of one crystal grain selected from a crystal grain map obtained through EBSD, assuming that the cross section of the crystal grain is a circle. Specifically, when the cross-sectional area of the crystal grain is defined as S and the radius of the crystal grain is defined as r, the radius r is calculated from the relation S=πr² and the grain size is obtained by doubling the radius r.

Furthermore, the sputtering target preferably has a relative density higher than or equal to 90%, more preferably higher than or equal to 95%, still more preferably higher than or equal to 99%.

FIG. 3A illustrates an example of a crystal structure of an In—Ga—Zn oxide seen from a direction parallel to the a-b plane, as an example of the crystal grains included in the sputtering target. As illustrated in FIG. 3A, in the crystal structure of the In—Ga—Zn oxide, layers including indium and layers including gallium or zinc and oxygen are stacked in the c-axis direction.

FIG. 3B is an enlarged view of a portion surrounded by a long dashed short dashed line in FIG. 3A. For example, in a crystal grain included in the In—Ga—Zn oxide, a plane between a first GZO layer including gallium atoms, zinc atoms, and oxygen atoms and a second GZO layer including gallium atoms, zinc atoms, and oxygen atoms illustrated in FIG. 3B corresponds to a cleavage plane. Thus, the sputtering target is cleaved along a plane parallel to the a-b plane, and a sputtered particle of the In—Ga—Zn oxide has a flat-plate-like shape with a plane parallel to the a-b plane. Even when the c-axes of the plurality of crystal grains of the sputtering target are not aligned, sputtered particles having the same shape with planes parallel to the a-b planes can be separated from the plurality of crystal grains. Therefore, it is not necessarily needed to align the c-axes of the plurality of crystal grains of the sputtering target.

FIG. 4 illustrates an example of a crystal structure of an In—Ga—Zn oxide seen in a direction perpendicular to the a-b plane of a crystal. Note that FIG. 4 selectively illustrates only a layer including indium atoms and oxygen atoms.

The In—Ga—Zn oxide has weak bonds between indium atoms and oxygen atoms. In other words, when the bonds are broken, oxygen atoms are detached and vacancies of oxygen atoms (also referred to as oxygen vacancies) are generated continuously as indicated in FIG. 4 with a long dashed double-short dashed line. In FIG. 4, a regular hexagon can be drawn by connecting the oxygen vacancies. Thus, it can be seen that a crystal of an In—Ga—Zn oxide has a plurality of planes perpendicular to the a-b plane, which are generated by the break of the bonds between indium atoms and oxygen atoms.

Since the crystal of the In—Ga—Zn oxide is a hexagonal crystal, a flat-plate-like sputtered particle is likely to be in the form of a hexagonal prism having regular hexagonal surfaces with an interior angle of 120°. However, the flat-plate-like sputtered particle is not limited to that which is in the form of a hexagonal prism, and may be in the form of a triangular prism having regular triangular planes with an interior angle of 60°, or other polygonal prisms.

### [2.2. Method for Manufacturing Sputtering Target]

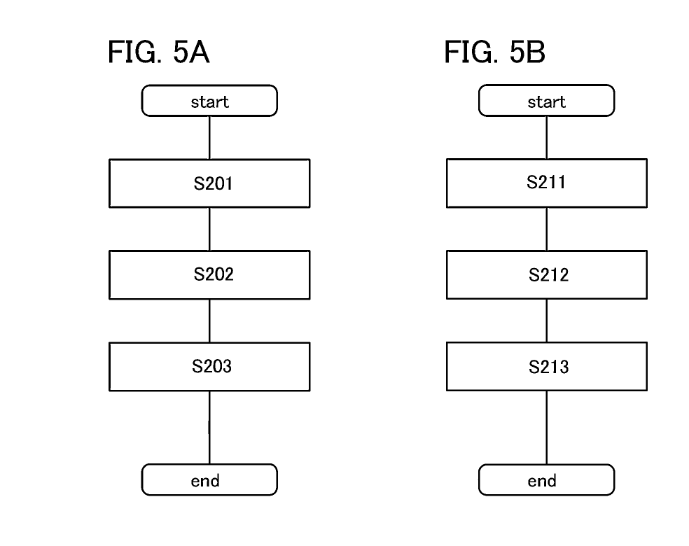

A method for manufacturing the above-described sputtering target will be described with reference to FIGS. 5A and 5B.

In FIG. 5A, an oxide powder containing a plurality of metal elements, which is used for the sputtering target, is manufactured. First, an oxide powder is weighed in a step S201.

A case is described here in which an oxide powder containing In, m, and Zn (also referred to as an In-M-Zn oxide powder) is manufactured as the oxide powder containing a plurality of metal elements. Specifically, an InO_{X} oxide powder, an MO_{Y} oxide powder, and a ZnO_{Z} oxide powder are prepared as raw materials. Note that X, Y, and Z are each a given positive number; for example, X, Y, and Z are 1.5, 1.5, and 1, respectively. It is needless to say that the above oxide powders are an example, and oxide powders can be selected as appropriate in order to obtain a desired composition. Note that M is Ga, Sn, Al, La, Ce, Pr, Nd, Sm, Eu, Gd, Tb, Dy, Ho, Er, Tm, Yb, or Lu. Although the case where three kinds of oxide powders are used is shown as an example in this embodiment, one embodiment of the present invention is not limited thereto. For example, this embodiment may be applied to the case where four or more kinds of oxide powders are used or the case where one or two kinds of oxide powders are used.

Next, the InO_{X} oxide powder, the MO_{Y} oxide powder, and the ZnO_{Z} oxide powder are mixed at a predetermined molar ratio.

The predetermined molar ratio of the InO_{X} oxide powder to the MO_{Y} oxide powder and the ZnO_{Z} oxide powder is, for example, 2:2:1, 8:4:3, 3:1:1, 1:1:1, 1:3:2, 4:2:3, 1:1:2, 3:1:4, or 3:1:2. At such a molar ratio, a sputtering target containing a polycrystalline oxide with high crystallinity can be easily obtained later.

Next, in a step S202, an In-M-Zn oxide is obtained by performing first baking on the InO_{X} oxide powder, the MO_{Y} oxide powder, and the ZnO_{Z} oxide powder that are mixed at the predetermined molar ratio.

Note that the first baking is performed in an inert atmosphere, an oxidation atmosphere, or a reduced-pressure atmosphere at a temperature higher than or equal to 400° C. and lower than or equal to 1700° C., preferably higher than or equal to 900° C. and lower than or equal to 1500° C. The first baking is performed for longer than or equal to 3 minutes and shorter than or equal to 24 hours, preferably longer than or equal to 30 minutes and shorter than or equal to 17 hours, more preferably longer than or equal to 30 minutes and shorter than or equal to 5 hours, for example. By performing the first baking under the above conditions, secondary reactions other than the main reaction can be reduced, and the concentration of impurities contained in the In-M-Zn oxide powder can be reduced. Accordingly, the crystallinity of the In-M-Zn oxide powder can be increased.

The first baking may be performed plural times at different temperatures and/or in different atmospheres. For example, the In-M-Zn oxide powder may be first held at a first temperature in a first atmosphere and then at a second temperature in a second atmosphere. Specifically, it is preferable that the first atmosphere be an inert atmosphere or a reduced-pressure atmosphere and the second atmosphere be an oxidation atmosphere. This is because oxygen vacancies might be generated in the In-M-Zn oxide when impurities contained in the In-M-Zn oxide powder are reduced in the first atmosphere, and thus it is preferable that oxygen vacancies in the In-M-Zn oxide be reduced in the second atmosphere. The concentration of impurities contained in the In-M-Zn oxide is decreased and oxygen vacancies are reduced, whereby the crystallinity of the In-M-Zn oxide powder can be increased.

Then, in a step S203, the In-M-Zn oxide is ground to obtain an In-M-Zn oxide powder.

The In-M-Zn oxide includes many surface structures which are parallel to the a-b plane. Thus, the resulting In-M-Zn oxide powder includes many flat-plate-like crystal grains having upper and lower surfaces parallel to the a-b plane. In addition, a crystal of the In-M-Zn oxide is likely to be a hexagonal crystal; thus, the above flat-plate-like crystal grain is likely to be in the form of a hexagonal prism having a substantially regular hexagonal plane with an interior angle of 120°.

In the above manner, the In-M-Zn oxide powder can be obtained.

Next, FIG. 5B shows a method for manufacturing a sputtering target using the In-M-Zn oxide powder obtained as shown in the flow chart in FIG. 5A.

In a step S211, the In-M-Zn oxide powder is spread over a mold and molded. Note that in the step S211, the In-M-Zn oxide powder may be mixed with water, a dispersant, and a binder to obtain a slurry, and the slurry may be molded. Then, after suction, the molded body is subjected to drying treatment. The drying treatment is preferably natural drying because the molded body is less likely to be cracked. After that, the molded body is subjected to heat treatment at a temperature higher than or equal to 300° C. and lower than or equal to 700° C., so that residual moisture and the like which cannot be taken out by natural drying are removed.

Note that the above mold may be made of a metal or an oxide and has a rectangular or round upper shape.

Next, in a step S212, second baking is performed on the In-M-Zn oxide powder. After that, in a step S213, first pressure treatment is performed on the In-M-Zn oxide powder which has been subjected to the second baking, whereby a plate-like In-M-Zn oxide is obtained. The second baking is performed using conditions and a method which are similar to those for the first baking. The crystallinity of the In-M-Zn oxide can be increased by performing the second baking.

Note that the first pressure treatment may be performed in any manner as long as the In-M-Zn oxide powder can be compacted. For example, a weight which is made of the same kind of material as the mold can be used. Alternatively, the In-M-Zn oxide powder may be compacted under high pressure using compressed air or the like. Besides, the first pressure treatment can be performed using a known technique. Note that the first pressure treatment may be performed at the same time as the second baking.

Planarization treatment may be performed after the first pressure treatment. As the planarization treatment, chemical mechanical polishing (CMP) treatment or the like can be employed.

The plate-like In-M-Zn oxide obtained in this manner is a polycrystalline oxide with high crystallinity.

Next, the thickness of the plate-like In-M-Zn oxide is checked. In the case where the thickness of the plate-like In-M-Zn oxide is smaller than a desired thickness, the process returns to the step S211, and an In-M-Zn oxide powder is spread over the plate-like In-M-Zn oxide and molded.

Note that the above steps may be repeated n times (n is a natural number). In that case, baking is performed again on the plate-like In-M-Zn oxide and the In-M-Zn oxide powder over the plate-like In-M-Zn oxide using conditions and a method which are similar to those for the second baking. Then, pressure treatment is performed on the plate-like In-M-Zn oxide and the In-M-Zn oxide powder over the plate-like In-M-Zn oxide which have been subjected to the baking, using conditions and a method which are similar to those for the above-described pressure treatment, whereby a plate-like In-M-Zn oxide whose thickness is increased by the thickness of the In-M-Zn oxide powder is obtained. The plate-like In-M-Zn oxide is obtained through crystal growth using the plate-like In-M-Zn oxide as a seed crystal; therefore, the plate-like In-M-Zn oxide is a polycrystalline oxide with high crystallinity.

By repeating these steps of increasing the thickness of a plate-like In-M-Zn oxide n times, the plate-like In-M-Zn oxide having a thickness of, for example, larger than or equal to 2 mm and smaller than or equal to 20 mm, preferably larger than or equal to 3 mm and smaller than or equal to 20 mm can be obtained. The plate-like In-M-Zn oxide is used as a sputtering target.

Note that planarization treatment may be performed after the plate-like In-M-Zn oxide is formed.

Note that further baking may be performed on the obtained sputtering target. The baking here is performed using conditions and a method which are similar to those for the first baking. By the baking, a sputtering target containing a polycrystalline oxide with further high crystallinity can be obtained.

In the above-described manner, it is possible to manufacture a sputtering target containing a polycrystalline oxide including a plurality of crystal grains and having a cleavage plane parallel to the a-b planes.

Note that when the above manufacturing method is employed, the sputtering target can have high density. When the density of the sputtering target is increased, the density of an oxide film to be formed can also be increased. Specifically, the sputtering target can have a relative density higher than or equal to 90%, preferably higher than or equal to 95%, more preferably higher than or equal to 99%.

In addition, the oxide film described in the first embodiment can be formed using the sputtering target of this embodiment. The thus formed oxide film has a c-axis arranged so as to be substantially perpendicular to a deposition surface.

This embodiment can be implemented in appropriate combinations with any of the other embodiments.

### 3. Third Embodiment

### Film Formation Apparatus

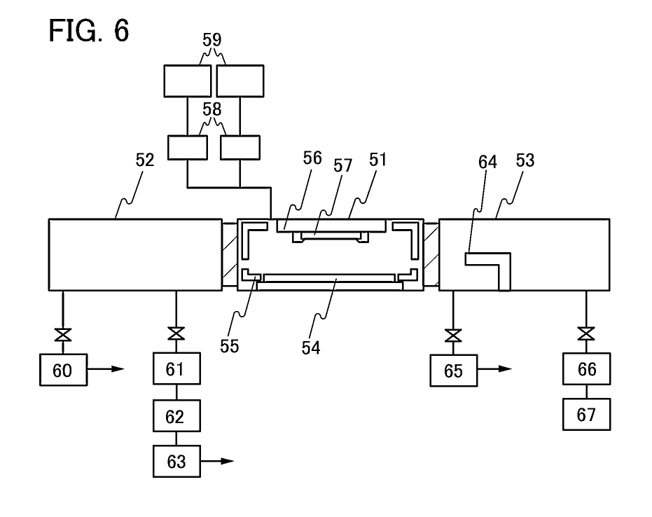

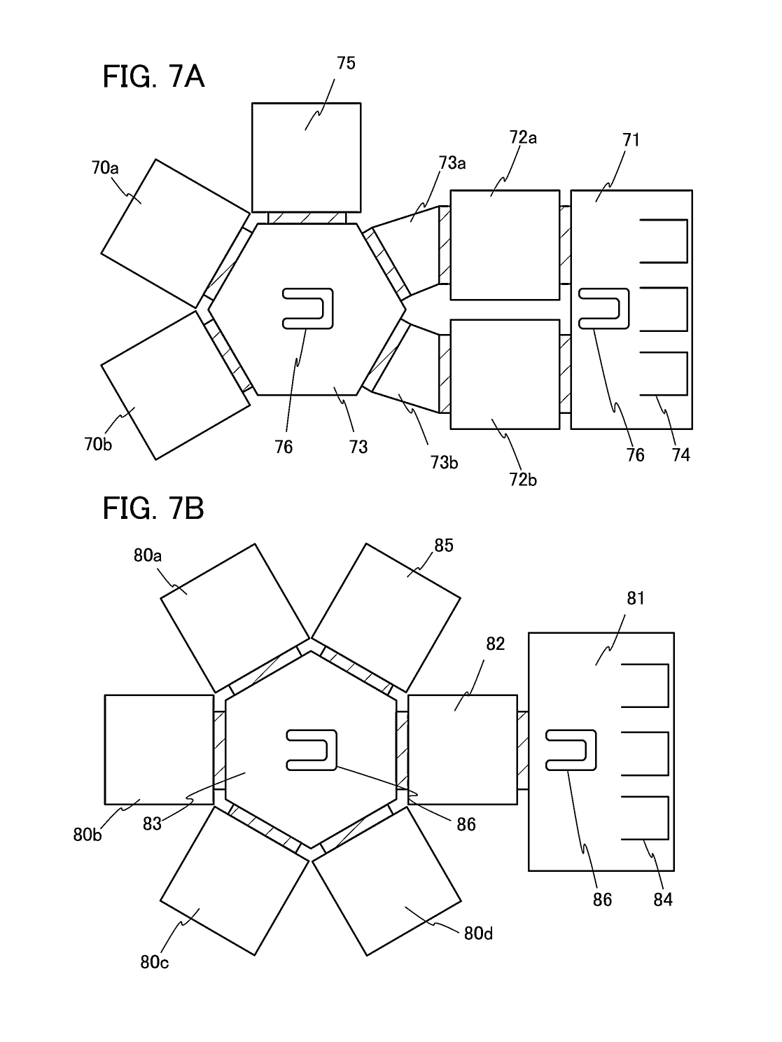

In this embodiment, a film formation apparatus in one embodiment of the present invention will be described with reference to FIG. 6, FIGS. 7A and 7B, FIGS. 8A and 8B, and FIG. 9.

Note that the film formation apparatus described below includes at least a film formation chamber (a sputtering chamber) where film formation is performed by a sputtering method. The sputtering method here is classified according to the method for generating plasma. A sputtering method using a direct-current (DC) power source is referred to as a direct-current sputtering method; a sputtering method using an alternate-current (AC) power source is referred to as an alternate-current sputtering method; and a sputtering method using a high-frequency (RF) power source is referred to as a high-frequency sputtering method. Among these methods, the direct-current sputtering method is industrially superior in terms of productivity and manufacturing cost because it can be implemented with an inexpensive power supply system and can form a film at high speed. For the film formation apparatus of one embodiment of the present invention, any of these methods, either alone or in combination, can be employed.

The film formation apparatus illustrated in FIG. 6 includes a film formation chamber 51, a secondary film formation chamber 52, and a transfer chamber 53.

The film formation chamber 51 is connected to the transfer chamber 53 and the secondary film formation chamber 52. Note that gate valves (indicated by oblique hatching in the diagram) are provided in connecting portions between the chambers so that each chamber can be independently kept in a vacuum state.

The film formation chamber 51 includes a sputtering target 54, a deposition shield 55, and a substrate stage 56.

The sputtering target 54 corresponds to the sputtering target 101 illustrated in FIG. 1. Note that a direct-current voltage, an alternate-current voltage, or a high-frequency voltage may be applied to the sputtering target 54. Among these voltages, a direct-current voltage is preferably used in order to form a CAAC-OS film described below.

The deposition shield 55 has a function of preventing sputtered particles separated from the sputtering target 54 from being deposited on a region where deposition is not necessary.

The substrate stage 56 is provided with a substrate 57. One surface of the substrate 57 corresponds to the deposition surface 102 illustrated in FIG. 1. Note that the substrate stage 56 may be provided with a substrate holding mechanism for holding the substrate 57, a back side heater for heating the substrate 57 from the back side, or the like. Note that the substrate stage may be in a floating state. Alternatively, the substrate stage 56 may be set at a ground potential.

The film formation chamber 51 is connected to refiners 59 via mass flow controllers 58. The number of the refiners 59 and that of the mass flow controllers 58 each correspond to the number of kinds of gases. FIG. 6 illustrates the case where the number is two as an example.

As a gas introduced into the film formation chamber 51 or the like, a gas whose dew point is −80° C. or lower, preferably −100° C. or lower, more preferably −120° C. or lower, is used. The use of an oxygen gas, a rare gas (such as an argon gas), or the like with low dew point can reduce the entry of moisture during film formation.

The secondary film formation chamber 52 has a function of preventing the entry of an exhaust gas to the film formation chamber 51.

The secondary film formation chamber 52 is connected to a vacuum pump 60 via a valve and is also connected to a vacuum pump 63 via a valve, an adaptive pressure control 61 (also referred to as APC), and a turbo molecular pump 62.

It is known that the turbo molecular pump is capable of stably removing a large-sized molecule by rotating an inner turbine at high speed, needs low frequency of maintenance, and thus enables high productivity, whereas it has a low capability in removing hydrogen and water. Hence, the use in combination with a cryopump having a high capability in removing a molecule having a relatively high melting point, such as water, or a sputter ion pump having a high capability in removing a highly reactive molecule is effective.

A cryopump is an oil-free pump in which an extremely cold surface is provided utilizing heat absorption at the time of expansion of a He gas and a residual gas is condensed and trapped. The trapped gas is regularly expelled and the pump is regenerated.

In the transfer chamber 53, a substrate transfer robot 64 is provided, which is capable of transferring substrates between the film formation chamber 51 and a load/unload lock chamber.

The transfer chamber 53 is connected to a vacuum pump 65 via a valve and is also connected to a cryopump 67 via a valve and an adaptive pressure control 66.

Note that the vacuum pumps 60, 63, and 65 can each be a pump in which a dry pump and a mechanical booster pump are connected in series, for example. It is preferable that impurities such as silicon and carbon do not enter the film formation chamber 51 from the gas evacuation side.

FIG. 7A is a schematic top view of a multi-chamber film formation apparatus. The film formation apparatus illustrated in FIG. 7A has an air-atmosphere-side substrate supply chamber 71 provided with three cassette ports 74 for storing substrates, a load lock chamber 72a, an unload lock chamber 72b, a transfer chamber 73, a transfer chamber 73a, a transfer chamber 73b, a substrate heating chamber 75, a film formation chamber 70a, and a film formation chamber 70b. The air-atmosphere-side substrate supply chamber 71 is connected to the load lock chamber 72a and the unload lock chamber 72b. The load lock chamber 72a and the unload lock chamber 72b are connected to the transfer chamber 73 via the transfer chamber 73a and the transfer chamber 73b. The substrate heating chamber 75, the film formation chamber 70a, and the film formation chamber 70b are each connected only to the transfer chamber 73.

Note that gate valves (indicated by oblique hatching in the diagram) are provided in connecting portions between the chambers so that each chamber excluding the air-atmosphere-side substrate supply chamber 71 can be independently kept in a vacuum state. In each of the air-atmosphere-side substrate supply chamber 71 and the transfer chamber 73, at least one substrate transfer robot 76 is provided, which is capable of transferring substrates. Note that it is preferable that the substrate heating chamber 75 also serve as a plasma treatment chamber. In a single wafer multi-chamber film formation apparatus, substrates can be transferred without being exposed to the air between treatments, and adsorption of impurities to substrates can be suppressed. In addition, the order of film formation, heat treatment, or the like can be freely determined Note that the number of transfer chambers, the number of film formation chambers, the number of load lock chambers, the number of unload lock chamber, and the number of substrate heating chambers are not limited to the above, and can be determined as appropriate depending on the space for installation or the process.

FIG. 7B illustrates a multi-chamber film formation apparatus having a structure different from that in FIG. 7A. The film formation apparatus illustrated in FIG. 7B has an air-atmosphere-side substrate supply chamber 81 provided with cassette ports 84, a load/unload lock chamber 82, a transfer chamber 83, a substrate heating chamber 85, a film formation chamber 80a, a film formation chamber 80b, a film formation chamber 80c, and a film formation chamber 80d. The air-atmosphere-side substrate supply chamber 81, the substrate heating chamber 85, the film formation chamber 80a, the film formation chamber 80b, the film formation chamber 80c, and the film formation chamber 80d are connected to each other via the transfer chamber 83.

Note that gate valves (indicated by oblique hatching in the diagram) are provided in connecting portions between the chambers so that each chamber excluding the air-atmosphere-side substrate supply chamber 81 can be independently kept in a vacuum state. In each of the air-atmosphere-side substrate supply chamber 81 and the transfer chamber 83, at least one substrate transfer robot 86 is provided, which is capable of transferring substrates.

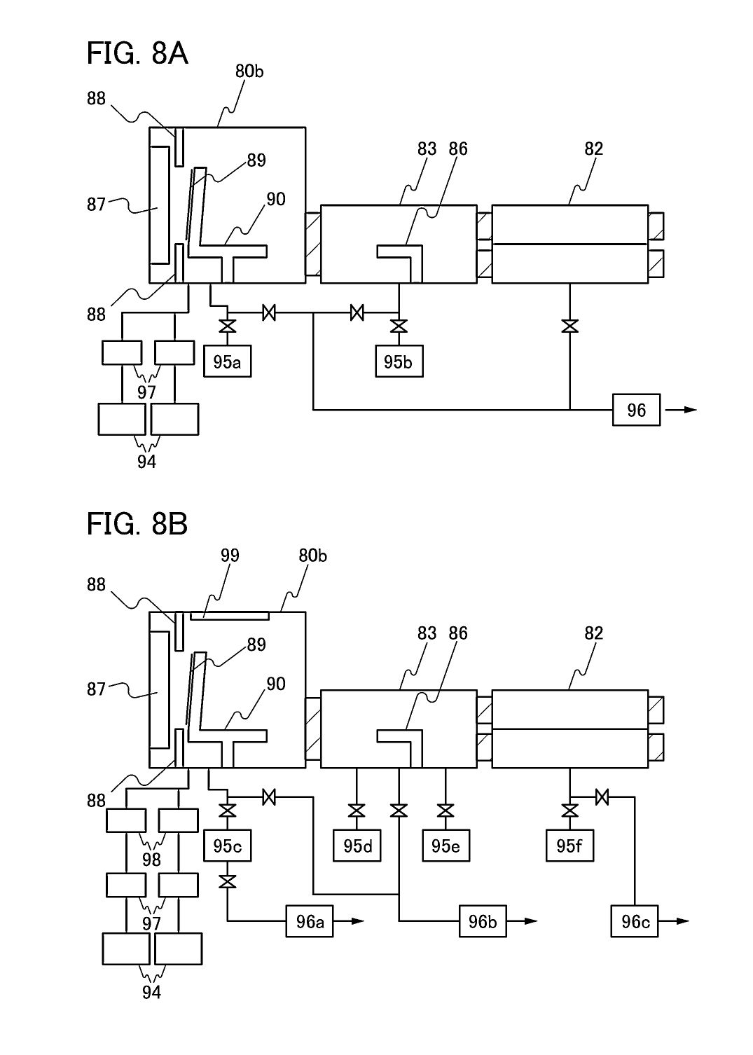

The details of the film formation chamber (sputtering chamber) illustrated in FIG. 7B will be described with reference to FIGS. 8A and 8B. The film formation chamber 80b illustrated in FIG. 8A includes a sputtering target 87, a deposition shield 88, and a substrate stage 90.

The sputtering target 87 corresponds to the sputtering target 101 illustrated in FIG. 1.

The deposition shield 88 has a function of preventing sputtered particles separated from the sputtering target 87 from being deposited on a region where deposition is not necessary.

The substrate stage 90 is provided with a substrate 89. One surface of the substrate 89 corresponds to the deposition surface 102 illustrated in FIG. 1. Note that the substrate stage 90 may be provided with a substrate holding mechanism for holding the substrate 89, a back side heater for heating the substrate 89 from the back side, or the like.

The film formation chamber 80b illustrated in FIG. 8A is connected to the transfer chamber 83 via the gate valve, and the transfer chamber 83 is connected to the load/unload lock chamber 82 via the gate valve. In the transfer chamber 83, the substrate transfer robot 86 is provided, which is capable of transferring substrates between the film formation chamber 80b and the load/unload lock chamber 82. The load/unload lock chamber 82 is divided into upper and lower portions within one vacuum chamber, one of which can be used as a load chamber and the other can be used as an unload chamber. Such a structure is preferable because the installation area of the film formation apparatus can be decreased.

The film formation chamber 80b illustrated in FIG. 8A is connected to refiners 94 via mass flow controllers 97. The number of the refiners 94 and that of the mass flow controllers 97 each correspond to the number of kinds of gases. FIG. 8A illustrates the case where the number is two as an example.

As a gas introduced into the film formation chamber 80b or the like, a gas whose dew point is −40° C. or lower, preferably −80° C. or lower, more preferably −100° C. or lower, is used. The use of an oxygen gas, a rare gas (such as an argon gas), or the like with low dew point can reduce the entry of moisture during film formation.

The film formation chamber 80b illustrated in FIG. 8A is connected to a cryopump 95a via a gate valve; the transfer chamber 83 is connected to a cryopump 95b via a gate valve; and the load/unload lock chamber 82 is connected to a vacuum pump 96 via a gate valve. Note that the load lock chamber and the unload lock chamber of the load/unload lock chamber 82 may be connected to separate vacuum pumps. The film formation chamber 80b and the transfer chamber 83 are connected to the vacuum pump 96 via respective valves.

Note that the vacuum pump 96 can be a pump in which a dry pump and a mechanical booster pump are connected in series, for example. With such a structure, the film formation chamber 80b and the transfer chamber 83 are evacuated from the atmospheric pressure to a low vacuum (about 0.1 Pa to 10 Pa) by using the vacuum pump 96 and then evacuated from the low vacuum to a high vacuum (1×10⁻⁴ Pa to 5×10⁻⁷ Pa) by switching between the valves and using the cryopump 95a or the cryopump 95b. At this time, it is preferable that impurities such as silicon and carbon do not enter the film formation chamber 80b from the gas evacuation side.

Next, an embodiment different from that in FIG. 8A will be described with reference to FIG. 8B as an example of the film formation chamber illustrated in FIG. 7B.

The film formation chamber 80b illustrated in FIG. 8B is connected to the transfer chamber 83 via the gate valve, and the transfer chamber 83 is connected to the load/unload lock chamber 82 via the gate valve.

The film formation chamber 80b in FIG. 8B is connected to mass flow controllers 97 via gas heating mechanisms 98, and the gas heating mechanisms 98 are connected to refiners 94 via the mass flow controllers 97. With the gas heating mechanisms 98, gases to be introduced into the film formation chamber 80b can be heated to a temperature higher than or equal to 40° C. and lower than or equal to 400° C., preferably higher than or equal to 50° C. and lower than or equal to 500° C. The number of the gas heating mechanisms 98, that of the refiners 94, and that of the mass flow controllers 97 each correspond to the number of kinds of gases. FIG. 8B illustrates the case where the number is two as an example.

The film formation chamber 80b in FIG. 8B is connected to a turbo molecular pump 95c and a vacuum pump 96b via valves. Note that for the turbo molecular pump 95c, a vacuum pump 96a is provided as an auxiliary pump via a valve. The vacuum pump 96a and the vacuum pump 96b may have a structure similar to that of the vacuum pump 96.

In addition, the film formation chamber 80b in FIG. 8B is provided with a cryotrap 99.

It is known that the turbo molecular pump 95c is capable of stably removing a large-sized molecule (atom), needs low frequency of maintenance, and thus enables high productivity, whereas it has a low capability in removing hydrogen and water. Hence, the cryotrap 99 having a high capability in removing a molecule (atom) having a relatively high melting point, such as water, is connected to the film formation chamber 80b. The temperature of a refrigerator of the cryotrap 99 is 100 K or lower, preferably 80 K or lower. In the case where the cryotrap 99 includes a plurality of refrigerators, it is preferable to set the temperatures of the refrigerators at different temperatures because efficient evacuation is possible. For example, the temperatures of a first-stage refrigerator and a second-stage refrigerator may be set to 100 K or lower and 20 K or lower, respectively.

The transfer chamber 83 in FIG. 8B is connected to the vacuum pump 96b, a cryopump 95d, and a cryopump 95e via respective valves. In the case where there is one cryopump, evacuation cannot be performed while the cryopump is in regeneration; however, in the case where there are two or more cryopumps which are connected in parallel, even when one of the cryopumps is in regeneration, evacuation can be performed using any of the other cryopumps. Note that regeneration of a cryopump refers to treatment for discharging molecules (atoms) trapped in the cryopump. When molecules (atoms) are trapped too much in a cryopump, the evacuation capability of the cryopump is lowered; therefore, regeneration is performed regularly.

The load/unload lock chamber 82 in FIG. 8B is connected to a cryopump 95f and a vacuum pump 96c via respective valves. Note that the vacuum pump 96c can have a structure similar to that of the vacuum pump 96.

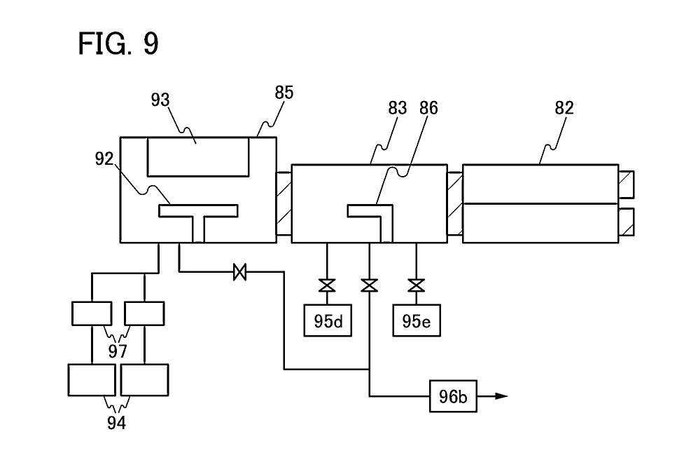

Next, the details of the substrate heating chamber 85 illustrated in FIG. 7B will be described with reference to FIG. 9.

The substrate heating chamber 85 illustrated in FIG. 9 is connected to the transfer chamber 83 via the gate valve. Note that the transfer chamber 83 is connected to the load/unload lock chamber 82 via the gate valve. Note that a gas evacuation system for the load/unload lock chamber 82 can have a structure similar to that in FIG. 8A or 8B.

The substrate heating chamber 85 in FIG. 9 is connected to refiners 94 via mass flow controllers 97. Note that the number of the refiners 94 and that of the mass flow controllers 97 each correspond to the number of kinds of gases. FIG. 9 illustrates the case where the number is two as an example. The substrate heating chamber 85 is connected to the vacuum pump 96b via a valve. Note that it is preferable that impurities such as silicon and carbon do not enter the film formation chamber 80b from the gas evacuation side.

The substrate heating chamber 85 is provided with a substrate stage 92. Note that the substrate heating chamber 85 may be provided with a substrate stage on which a plurality of substrates can be set. In addition, the substrate heating chamber 85 is provided with a heating mechanism 93. The heating mechanism 93 may be a heating mechanism which uses a resistance heater or the like for heating. Alternatively, it may be a heating mechanism which uses heat conduction or heat radiation from a medium such as a heated gas for heating. For example, rapid thermal annealing (RTA), such as gas rapid thermal annealing (GRTA) or lamp rapid thermal annealing (LRTA), can be used. In LRTA, an object is heated by radiation of light (an electromagnetic wave) emitted from a lamp, such as a halogen lamp, a metal halide lamp, a xenon arc lamp, a carbon arc lamp, a high-pressure sodium lamp, or a high-pressure mercury lamp. In GRTA, heat treatment is performed using a high-temperature gas. As the gas, an inert gas is used.

Note that the back pressure of each of the film formation chamber 80b and the substrate heating chamber 85 is 1×10⁻⁴ Pa or less, preferably 3×10⁻⁵ Pa or less, more preferably 1×10⁻⁵ Pa or less.

In each of the film formation chamber 80b and the substrate heating chamber 85, the partial pressure of a gas molecule (atom) having a mass-to-charge ratio (m/z) of 18 is 3×10⁻⁵ Pa or less, preferably 1×10⁻⁵ Pa or less, more preferably 3×10⁻⁶ Pa or less.

In each of the film formation chamber 80b and the substrate heating chamber 85, the partial pressure of a gas molecule (atom) having a mass-to-charge ratio (m/z) of 28 is 3×10⁻⁵ Pa or less, preferably 1×10⁻⁵ Pa or less, more preferably 3×10⁻⁶ Pa or less.

In each of the film formation chamber 80b and the substrate heating chamber 85, the partial pressure of a gas molecule (atom) having a mass-to-charge ratio (m/z) of 44 is 3×10⁻⁵ Pa or less, preferably 1×10⁻⁵ Pa or less, more preferably 3×10⁻⁶ Pa or less.

Note that in each of the film formation chamber 80b and the substrate heating chamber 85, the leakage rate is 3×10⁻⁶ Pa·m³/s or less, preferably 1×10⁻⁶ Pa·m³/s or less.

In each of the film formation chamber 80b and the substrate heating chamber 85, the leakage rate of a gas molecule (atom) having a mass-to-charge ratio (m/z) of 18 is 1×10⁻⁷ Pa·m³/s or less, preferably 3×10⁻⁸ Pa·m³/s or less.

In each of the film formation chamber 80b and the substrate heating chamber 85, the leakage rate of a gas molecule (atom) having a mass-to-charge ratio (m/z) of 28 is 1×10⁻⁵ Pa·m³/s or less, preferably 1×10⁻⁶ Pa·m³/s or less.

In each of the film formation chamber 80b and the substrate heating chamber 85, the leakage rate of a gas molecule (atom) having a mass-to-charge ratio (m/z) of 44 is 3×10⁻⁶ Pa·m³/s or less, preferably 1×10⁻⁶ Pa·m³/s or less.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc., can be used. Note that a leakage rate can be derived from the total pressure and partial pressure measured using the mass analyzer.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or due to released gas from an internal member. Measures need to be taken from both aspects of external leakage and internal leakage in order that the leakage rate be lower than or equal to the above value.

For example, an open/close portion of the film formation chamber is preferably sealed with a metal gasket. For the metal gasket, a metal covered with iron fluoride, aluminum oxide, or chromium oxide is preferably used. The metal gasket achieves higher adhesion than an O-ring, and can reduce the external leakage. Further, by use of a metal covered with iron fluoride, aluminum oxide, chromium oxide, or the like which is in the passive state, the release of gas containing impurities released from the metal gasket is suppressed, so that the internal leakage can be reduced.

For a member of the film formation apparatus, aluminum, chromium, titanium, zirconium, nickel, or vanadium, which releases a smaller amount of gas containing impurities, is used. Alternatively, an alloy containing iron, chromium, nickel, and the like and covered with the above member may be used. The alloy containing iron, chromium, nickel, and the like is rigid, resistant to heat, and suitable for processing. Here, when surface unevenness of the member is decreased by polishing or the like to reduce the surface area, the released gas can be reduced.

Alternatively, the above-mentioned member of the film formation apparatus may be covered with iron fluoride, aluminum oxide, chromium oxide, or the like.

The member of the film formation apparatus is preferably formed using only a metal when possible. For example, in the case where a viewing window formed using quartz or the like is provided, a surface thereof is preferably covered thinly with iron fluoride, aluminum oxide, chromium oxide, or the like to suppress the release of gas.

In the case where the refiner for a film formation gas is provided before the film formation chamber, the length of a pipe between the refiner and the film formation chamber is 10 m or less, preferably 5 m or less, more preferably 1 m or less. When the length of the pipe is 10 m or less, 5 m or less, or 1 m or less, the effect of the release of gas from the pipe can be reduced accordingly.

As the pipe for the film formation gas, a metal pipe the inside of which is covered with iron fluoride, aluminum oxide, chromium oxide, or the like is preferably used. With the above pipe, the amount of released gas containing impurities is small and the entry of impurities to the film formation gas can be reduced as compared with a SUS316L-EP pipe, for example. Further, a high-performance ultra-compact metal gasket joint (UPG joint) is preferably used as a joint of the pipe. A structure where the pipe is entirely formed using a metal is preferable because the effect of the release of gas or the external leakage can be reduced as compared with a structure where a resin or the like is used.

When existing in the film formation chamber, an adsorbate does not affect the pressure in the film formation chamber; however, the adsorbate causes the release of gas at the time of evacuation of the film formation chamber. Therefore, although there is no correlation between the leakage rate and the evacuation rate, it is important that the adsorbate present in the film formation chamber be desorbed as much as possible and evacuation be performed in advance with the use of a pump with high evacuation capability. Note that the film formation chamber may be subjected to baking for promotion of desorption of the adsorbate. By the baking, the rate of desorption of the adsorbate can be increased about tenfold. The baking may be performed at a temperature higher than or equal to 400° C. and lower than or equal to 450° C. At this time, when the adsorbate is removed while an inert gas is introduced into the film formation chamber, the rate of desorption of water or the like, which is difficult to desorb simply by evacuation, can be further increased. Note that when the inert gas to be introduced is heated to substantially the same temperature as the baking temperature, the rate of desorption of the adsorbate can be further increased. Here, a rare gas is preferably used as the inert gas. Depending on the kind of a film to be formed, oxygen or the like may be used instead of the inert gas. For example, in the case of forming an oxide semiconductor layer, oxygen which is the main component is preferably used in some cases.

Alternatively, treatment for evacuating the film formation chamber is preferably performed a certain period of time after a heated oxygen gas, a heated inert gas such as a heated rare gas, or the like is introduced to increase pressure in the film formation chamber. The introduction of the heated gas can cause the adsorbate to be desorbed in the film formation chamber, and the impurities present in the film formation chamber can be reduced. Note that a positive effect can be achieved when this treatment is repeated 2 to 30 times inclusive, preferably 5 to 15 times inclusive. Specifically, an inert gas, oxygen, or the like at a temperature in the range of 40° C. to 400° C., preferably 50° C. to 500° C. is introduced into the film formation chamber so that the pressure therein is kept at 0.1 Pa to 10 kPa inclusive, preferably 1 Pa to 1 kPa inclusive, more preferably 5 Pa to 100 Pa inclusive for 1 minute to 300 minutes inclusive, preferably 5 minutes to 120 minutes inclusive. After that, the film formation chamber is evacuated for 5 minutes to 300 minutes inclusive, preferably 10 minutes to 120 minutes inclusive.

The rate of desorption of the adsorbate can be further increased also by dummy film formation. The dummy film formation refers to film formation on a dummy substrate by a sputtering method or the like, in which a film is deposited on the dummy substrate and the inner wall of a film formation chamber so that impurities in the film formation chamber and an adsorbate on the inner wall of the film formation chamber are confined in the film. As the dummy substrate, a substrate which releases a smaller amount of gas is preferably used, and for example, a substrate similar to a substrate 700 which is described later may be used. By performing dummy film formation, the concentration of impurities in a film to be formed later can be reduced. Note that the dummy film formation may be performed at the same time as the baking.

In the case where the oxide film described in the first embodiment is formed using the above-described film formation apparatus, the surface temperature of the sputtering target is preferably set to be lower than or equal to 100° C., more preferably lower than or equal to 50° C., still more preferably about room temperature. In a film formation apparatus for a large substrate, a sputtering target having a large area is often used. However, it is difficult to form a sputtering target for a large substrate without a juncture. In fact, although a plurality of sputtering targets are arranged to obtain a large size so that there is as little space as possible therebetween, a slight space is inevitably generated. When the surface temperature of the sputtering target increases, in some cases, Zn or the like is volatilized from such a slight space, and the space might expand gradually. When the space expands, a metal of a backing plate or a metal used for adhesion might be sputtered and cause an increase in impurity concentration. Thus, it is preferable that the sputtering target be cooled sufficiently.

Specifically, for the backing plate, a metal having high conductivity and a high heat dissipation property (specifically Cu) is used. The sputtering target can be cooled efficiently by making a sufficient amount of cooling water flow through a water channel which is formed in the backing plate. Here, the sufficient amount of cooling water, which depends on the size of the sputtering target, may be set to be greater than or equal to 3 L/min, greater than or equal to 5 L/min, or greater than or equal to 10 L/min in the case of, for example, a target which has the shape of a circle and has a diameter of 300

The oxide film is preferably formed at a substrate heating temperature of 100° C. to 600° C., more preferably 150° C. to 550° C., further preferably 200° C. to 550° C., still more preferably 200° C. to 500° C., yet still more preferably 150° C. to 450° C. The thickness of the oxide film is more than or equal to 1 nm and less than or equal to 40 nm, preferably more than or equal to 3 nm and less than or equal to 20 nm. As the substrate heating temperature at the time of film formation becomes higher, the concentration of impurities in the obtained oxide film becomes lower. Further, migration of sputtered particles on a deposition surface is likely to occur; therefore, the atomic arrangement in the oxide film is ordered and the density thereof can be increased. Furthermore, when an oxygen atmosphere is employed for the film formation, plasma damage is alleviated and an unnecessary atom such as a rare gas atom is not contained in the oxide film, so that the oxide film is likely to have high crystallinity. Note that a mixed atmosphere of an oxygen gas and a rare gas may be used. In that case, the percentage of the oxygen gas is higher than or equal to 30 vol. %, preferably higher than or equal to 50 vol. %, more preferably higher than or equal to 80 vol. %, still more preferably 100 vol. %.

Note that in the case where the sputtering target contains Zn, plasma damage is alleviated by the film formation in an oxygen gas atmosphere; thus, an oxide film in which Zn is unlikely to be volatilized can be obtained.

The oxide film is formed with a film formation pressure of less than or equal to 0.8 Pa, preferably less than or equal to 0.4 Pa, and a distance of less than or equal to 40 mm, preferably less than or equal to 25 mm, between the sputtering target and a substrate. When the oxide film is formed under such a condition, the frequency of the collision of a sputtered particle and another sputtered particle, a gas molecule, or an ion can be reduced. That is, depending on the film formation pressure, the distance between the sputtering target and the substrate is made shorter than the mean free path of a sputtered particle, a gas molecule, or an ion, so that the entry of impurities to the oxide film can be reduced. Note that at this time, the plasma space 103 is preferably formed as far as the deposition surface 102.

As the diameter of a molecule (atom) becomes larger, the mean free path becomes shorter and the crystallinity is lowered due to the large diameter of the molecule (atom) when the molecule (atom) enters the oxide film. For this reason, it can be said that, for example, a molecule (atom) with a diameter larger than or equal to that of an Ar atom is likely to serve as an impurity.

Furthermore, heat treatment may be performed using the film formation apparatus. The heat treatment is performed in a reduced-pressure atmosphere, an inert atmosphere, or an oxidation atmosphere. By the heat treatment, the concentration of impurities in the oxide film can be reduced.

The heat treatment is preferably performed in such a manner that heat treatment in a reduced-pressure atmosphere or an inert gas atmosphere is performed, the atmosphere is the changed to an oxidization atmosphere while the temperature is kept, and heat treatment is further performed. When the heat treatment is performed in a reduced-pressure atmosphere or an inert atmosphere, the concentration of impurities in the oxide film can be reduced; however, oxygen vacancies are generated at the same time. By the heat treatment in an oxidation atmosphere, the generated oxygen vacancies can be reduced.

When an oxide film is formed with the use of the above film formation apparatus, the entry of impurities to the oxide film can be suppressed. In addition, the oxide film can have high crystallinity.

This embodiment can be implemented in appropriate combinations with any of the other embodiments.

### 4. Fourth Embodiment

### Oxide Film

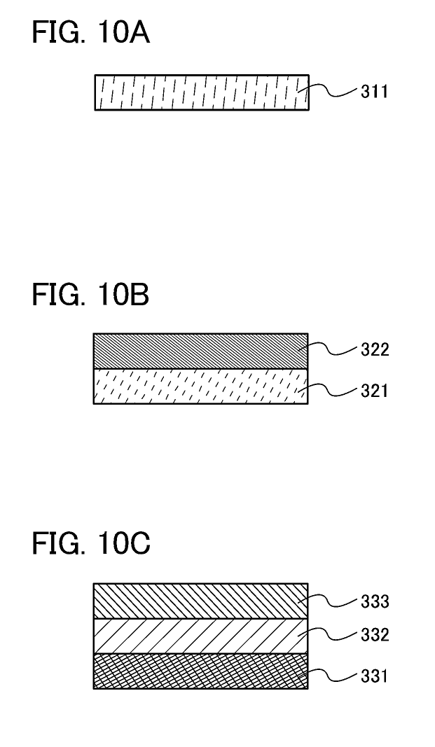

In this embodiment, an oxide film manufactured by a sputtering method in one embodiment of the present invention will be described with reference to FIGS. 10A to 10C.

### [4.1. Oxide Film]

An oxide film 311 illustrated in FIG. 10A is a single-layer film.

The oxide film 311 is, for example, an In-based metal oxide, a Zn-based metal oxide, an InZn-based metal oxide, an InGa—Zn-based metal oxide, or the like.

Alternatively, a metal oxide containing another metal element instead of part or all of Ga in the InGa—Zn-based metal oxide may be used. As the metal element contained instead of part or all of Ga, a metal element that is capable of combining with more oxygen atoms than gallium can be used, for example, and specifically one or more of zirconium, germanium, and tin can be used, for instance. Alternatively, as the metal element, one or more elements of lanthanum, cerium, praseodymium, neodymium, samarium, europium, gadolinium, terbium, dysprosium, holmium, erbium, thulium, ytterbium, and lutetium may be used. These metal elements each have a function as a stabilizer. Note that the amount of the metal element is the amount at which the metal oxide can serve as a semiconductor. When a metal element that is capable of combining with more oxygen atoms than gallium is used and oxygen is supplied to a metal oxide, oxygen defects in the metal oxide can be reduced.

For the oxide film, a material represented by the chemical formula InₓM_{y}O₃(ZnO)ₘ (x, y, m>0, m is not an integer) may be used, for example. Note that M represents one or more elements of gallium, zirconium, germanium, tin, lanthanum, cerium, praseodymium, neodymium, samarium, europium, gadolinium, terbium, dysprosium, holmium, erbium, thulium, ytterbium, and lutetium. For example, M may be gallium and an InGa—Zn-based oxide with an atomic ratio of In:Ga:Zn=1:1:1, 2:2:1, 1:3:2, or 3:1:2 or an oxide whose composition is in the neighborhood of any of the above compositions may be used.

Furthermore, the oxide film 311 has a c-axis arranged so as to be substantially perpendicular to a deposition surface.

### [4.1.1. CAAC-OS]

It is preferable that the oxide film 311 include a plurality of crystal parts, and in each of the crystal parts, a c-axis be aligned in a direction parallel to a normal vector of a surface where the oxide film is formed or a normal vector of a surface of the oxide film. Note that, among crystal parts, the directions of the a-axis and the b-axis of one crystal part may be different from those of another crystal part. An example of such an oxide film is a c-axis aligned crystalline oxide semiconductor (CAAC-OS) film.

The CAAC-OS film is one of oxide semiconductor films including a plurality of crystal parts, and most of the crystal parts each fit inside a cube whose one side is less than 100 nm Thus, there is a case where a crystal part included in the CAAC-OS film fits inside a cube whose one side is less than 10 nm, less than 5 nm, or less than 3 nm The density of defect states of the CAAC-OS film is lower than that of the microcrystalline oxide semiconductor film. The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface where the CAAC-OS film is formed (hereinafter, a surface where the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (planar TEM image), metal atoms are arranged in a triangular or hexagonal configuration in the crystal parts. However, there is no regularity of arrangement of metal atoms between different crystal parts.

From the results of the cross-sectional TEM image and the planar TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface of the CAAC-OS film. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ do not appear at around 36°.

In a transistor using the CAAC-OS film, change in electrical characteristics due to irradiation with visible light or ultraviolet light is small. Thus, the transistor has high reliability.

### [4.1.2. Preferable Conditions for Forming CAAC-OS]

For the formation of CAAC-OS, the following conditions are preferably used.

For example, when CAAC-OS is formed with the concentration of impurities reduced, the crystal state of the oxide semiconductor can be prevented from being broken by impurities. For example, impurities (e.g., hydrogen, water, carbon dioxide, and nitrogen) existing in a film formation chamber of a sputtering apparatus are preferably reduced. In addition, impurities in a film formation gas are preferably reduced. For example, a film formation gas whose dew point is −80° C. or lower, preferably −120° C. or lower, is preferably used as a film formation gas.

The substrate temperature at the time of film formation is preferably high. At a high substrate temperature, when a flat-plate-like sputtered particle arrives at a substrate, migration of the sputtered particle occurs and the flat surface of the sputtered particle can be attached to the substrate. For example, CAAC-OS can be formed when an oxide semiconductor film is formed at a substrate heating temperature of 100° C. to 600° C., preferably 200° C. to 500° C., more preferably 150° C. to 450° C.

Furthermore, it is preferable that the proportion of oxygen in the film formation gas be increased and the power be optimized in order to reduce plasma damage at the time of the film formation. For example, the proportion of oxygen in the film formation gas is preferably 30 vol. % or higher, more preferably 100 vol. %.

In the case where an InGa—Zn—O compound target is used as a sputtering target, an InGa—Zn—O compound target is preferably used which is formed by mixing an InOₙ powder, a GaO_{y} powder, and a ZnO_{z} powder at a molar ratio of 2:2:1, 8:4:3, 3:1:1, 1:1:1, 4:2:3, or 3:1:2, for example, where x, y, and z are each a given positive number.

In the case where the oxide film is formed by sputtering, when heat treatment is performed in addition to the substrate heating in the film formation, the concentration of impurities in the oxide film can be reduced.

The concentration of hydrogen in the oxide film manufactured by a sputtering method in one embodiment of the present invention, which is measured by secondary ion mass spectrometry (SIMS), can be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

The concentration of nitrogen in the oxide film manufactured by a sputtering method in one embodiment of the present invention, which is measured by SIMS, can be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of carbon in the oxide film manufactured by a sputtering method in one embodiment of the present invention, which is measured by SIMS, can be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of silicon in the oxide film manufactured by a sputtering method in one embodiment of the present invention, which is measured by SIMS, can be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The amount of each of the following gases released from the oxide film manufactured by a sputtering method in one embodiment of the present invention is 1×10¹⁹/cm³ or less, preferably 1×10¹⁸/cm³ or less, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

### [4.2. Stacked-Layer Film (Multilayer Film) of Oxide Films]

As illustrated in FIGS. 10B and 10C, a stacked-layer film (also referred to as a multilayer film) of a plurality of oxide films may be formed.

A stacked-layer film illustrated in FIG. 10B includes an oxide film 321 and an oxide film 322.

As the oxide film 321 and the oxide film 322, the same films as the oxide film 311 can be used, for example. The oxide film 321 and the oxide film 322 can be formed by successively forming the same films as the oxide film 311, for example.

The oxide film 321 and the oxide film 322 may be different oxide films. For example, one of the oxide films 321 and 322 may be an oxide film which is CAAC-OS, and the other may be a film which is not CAAC-OS and is formed with a material that can be used for the oxide film 311. At this time, the other of the oxide films 321 and 322 may be amorphous, polycrystalline, or microcrystalline.

A stacked-layer film illustrated in FIG. 10C includes an oxide film 331, an oxide film 332, and an oxide film 333.

As the oxide films 331 to 333, the same films as the oxide film 311 can be used, for example. The oxide films 331 to 333 can be formed by successively forming the same films as the oxide film 311, for example.

Two or more of the oxide films 331 to 333 may be different oxide films. For example, the oxide film 331 may be a film which is not CAAC-OS and is formed with a material that can be used for the oxide film 311; the oxide film 332 may be an oxide film which is CAAC-OS; and the oxide film 333 may be an oxide film which is CAAC-OS. At this time, the oxide film 331 may be amorphous, polycrystalline, or microcrystalline.

Note that FIGS. 10A to 10C illustrate single-layer, two-layer, and three-layer oxide films; however, the present invention is not limited thereto and four or more oxide films may be stacked.

As described with reference to FIGS. 10A to 10C, c-axes in an oxide film can be arranged so as to be substantially perpendicular to a deposition surface by a sputtering method in one embodiment of the present invention. Since the oxide film has few defects and is dense, a highly reliable transistor can be manufactured using the oxide film, for example.

This embodiment can be implemented in appropriate combinations with any of the other embodiments.

### 5. Fifth Embodiment

### Structure of Transistor

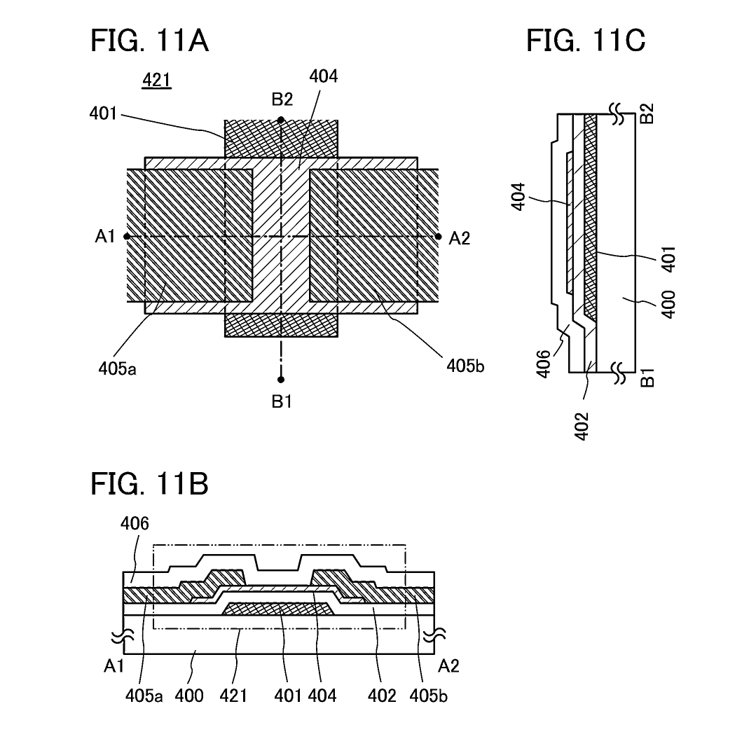

In this embodiment, structures of transistors manufactured using the oxide film and a method for manufacturing the transistor will be described with reference to FIGS. 11A to 11C, FIGS. 12A and 12B, FIGS. 13A to 13C, FIGS. 14A and 14B, FIGS. 15A and 15B, FIGS. 16A to 16C, and FIGS. 17A to 17C.

Note that the structure of a transistor is not particularly limited and can be a given structure. As the structure of a transistor, a staggered type or a planar type having a bottom gate structure which is described below can be employed. A transistor may have a single-gate structure in which one channel formation region is formed or a multi-gate structure such as a double-gate structure in which two channel formation regions are formed or a triple-gate structure in which three channel formation regions are formed. In addition, a transistor may have a structure in which two gate electrodes are provided above and below a channel formation region with gate insulating films provided therebetween (in this specification, this structure is referred to as a dual-gate structure).

### [5.1. Transistor Manufactured Using Single-Layer Oxide Film]

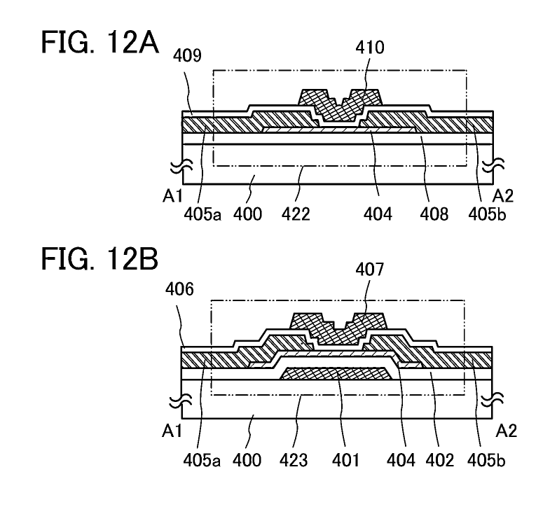

First, a transistor manufactured using a single-layer oxide film will be described with reference to FIGS. 11A to 11C and FIGS. 12A and 12B. As the single-layer oxide film here, the oxide film described in the above embodiment can be used.

### [5.1.1. Bottom-Gate Transistor]

FIGS. 11A to 11C illustrate a structural example of a transistor 421 having a bottom-gate top-contact structure, which is one kind of bottom-gate transistor. FIG. 11A is a plan view of the transistor 421. FIG. 11B is a cross-sectional view taken along the long dashed short dashed line A1-A2 in FIG. 11A. FIG. 11C is a cross-sectional view taken along the long dashed short dashed line B1-B2 in FIG. 11A.

The transistor 421 includes a gate electrode 401 provided over a substrate 400 having an insulating surface, a gate insulating film 402 provided over the gate electrode 401, an oxide film 404 overlapping with the gate electrode 401 with the gate insulating film 402 provided therebetween, and a source electrode 405a and a drain electrode 405b provided in contact with the oxide film 404. In addition, an insulating film 406 is provided so as to cover the source electrode 405a and the drain electrode 405b and be in contact with the oxide film 404.

In FIG. 11A, a channel length refers to the distance between the source electrode 405a and the drain electrode 405b in a region overlapping with the gate electrode 401. A channel formation region refers to a region of the oxide film 404 which overlaps with the gate electrode 401 and is sandwiched between the source electrode 405a and the drain electrode 405b. A channel refers to a main path through which current flows in the channel formation region.

In this embodiment, the oxide film 404 is a semiconductor film, and a channel of the transistor is formed in the oxide film 404. The oxide film 404 has a thickness of 1 nm to 50 nm, preferably 5 nm to 20 nm.

The oxide film 404 may be in a non-single-crystal state, for example. The non-single-crystal state is, for example, structured by at least one of c-axis aligned crystal (CAAC), polycrystal, microcrystal, and an amorphous part. Among c-axis aligned crystal (CAAC), polycrystal, microcrystal, and an amorphous part, the amorphous part has the highest density of defect states, whereas CAAC has the lowest density of defect states.

The oxide film 404 may include a CAAC-OS. In the CAAC-OS, for example, c-axes are aligned, and a-axes and/or b-axes are not macroscopically aligned.

For example, the oxide film 404 may include microcrystal. A microcrystalline oxide film, for example, includes a microcrystal of greater than or equal to 1 nm and less than 10 nm.

For example, the oxide film 404 may include an amorphous part. An amorphous oxide film, for example, has disordered atomic arrangement and no crystalline component. Alternatively, an amorphous oxide semiconductor film is, for example, absolutely amorphous and has no crystal part.

Note that the oxide film 404 may be a mixed film including any of a CAAC-OS, a microcrystalline oxide semiconductor, and an amorphous oxide semiconductor. The mixed film, for example, includes a region of an amorphous oxide semiconductor, a region of a microcrystalline oxide semiconductor, and a region of a CAAC-OS. Further, the mixed film may have a layered structure including a region of an amorphous oxide semiconductor, a region of a microcrystalline oxide semiconductor, and a region of a CAAC-OS, for example.

Note that the oxide film 404 may be in a single-crystal state, for example.

An amorphous oxide film can have a flat surface with relative ease. Thus, in a transistor manufactured using an amorphous oxide film as the oxide film 404, interface scattering at the interface between the oxide film and the gate insulating film can be reduced and therefore relatively high field-effect mobility can be obtained with relative ease.

In a crystalline oxide film, defects in the bulk can be further reduced. Thus, when the surface flatness of the crystalline oxide film is improved, field-effect mobility higher than or equal to that of a transistor manufactured using an amorphous oxide film can be obtained. In order to improve the surface flatness, the oxide film is preferably formed over a flat surface. Specifically, the oxide film is preferably formed over a surface with an average surface roughness (Rₐ) of less than or equal to 1 nm, preferably less than or equal to 0.3 nm, more preferably less than or equal to 0.1 nm.

Note that Rₐ is obtained by expanding the arithmetic means surface roughness that is defined by JIS B 0601:2001 (ISO 4287:1997) into three dimensions so as to be able to be applied to a curved surface. Rₐ can be expressed as an “average value of the absolute values of deviations from a reference surface to a specific surface” and is defined by the following formula.

$$Ra = \frac{1}{{S}_{0}} {\int }_{{y}_{1}}^{{y}_{2}} {\int }_{{x}_{1}}^{{x}_{2}} \vert f ( x , y ) - {Z}_{0} \vert d x d y \qquad [ Formula 1 ]$$

Here, the specific surface is a surface which is a target of roughness measurement, and is a quadrilateral region which is specified by four points represented by the coordinates (x₁, y₁, f(x₁,y₁)), (x₁, y₂, f(x₁,y₂)), (x₂, y₁, f(x₂,y₁)), and (x₂, y₂, f(x₂,y₂)). S₀ represents the area of a rectangle which is obtained by projecting the specific surface on the xy plane, and Z₀ represents the height of the reference surface (the average height of the specific surface). Rₐ can be measured using an atomic force microscope (AFM).

A transistor manufactured using the CAAC-OS film described in the above embodiment as the oxide film 404 has little change in electrical characteristics due to irradiation with visible light or ultraviolet light. Therefore, the reliability of the transistor can be improved.

### [5.1.2. Top-Gate Transistor]

FIG. 12A illustrates a transistor 422 having a top-gate structure.

The transistor 422 includes an insulating film 408 provided over a substrate 400 having an insulating surface, an oxide film 404 provided over the insulating film 408, a source electrode 405a and a drain electrode 405b provided in contact with the oxide film 404, a gate insulating film 409 provided over the oxide film 404, the source electrode 405a, and the drain electrode 405b, and a gate electrode 410 overlapping with the oxide film 404 with the gate insulating film 409 provided therebetween.

In FIG. 12A, the oxide film 404 is a semiconductor film, and a channel of the transistor is formed in the oxide film 404. The oxide film 404 is preferably the CAAC-OS film which is described in the above embodiment. Note that the oxide film 404 may be an amorphous oxide film, a single crystal oxide film, a polycrystalline oxide film, or a microcrystalline oxide film. The oxide film 404 has a thickness of 1 nm to 50 nm, preferably 5 nm to 20 nm.

### [5.1.3. Dual-Gate Transistor]

FIG. 12B illustrates a transistor 423 having a dual-gate structure, which includes two gate electrodes above and below a channel formation region with gate insulating films provided therebetween.

The transistor 423 includes a gate electrode 401 provided over a substrate 400 having an insulating surface, a gate insulating film 402 provided over the gate electrode 401, an oxide film 404 overlapping with the gate electrode 401 with the gate insulating film 402 provided therebetween, a source electrode 405a and a drain electrode 405b provided in contact with the oxide film 404, an insulating film 406 covering the source electrode 405a and the drain electrode 405b and in contact with the oxide film 404, and an electrode layer 407 overlapping with the oxide film 404 with the insulating film 406 provided therebetween.

In the transistor 423, the insulating film 406 functions as a gate insulating film, and the electrode layer 407 functions as a gate electrode. One of the pair of gate electrodes may be supplied with a signal for controlling whether to turn on or off the transistor, and the other gate electrode may be supplied with a ground potential or a fixed potential such as a negative potential. By controlling the level of the potential supplied to the other gate electrode, the threshold voltage of the transistor 423 can be controlled. By controlling the potentials of both gate electrodes as described above, a change in threshold voltage of the transistor can be further reduced. Thus, for example, the transistor can be prevented from becoming normally on.

In FIG. 12B, the oxide film 404 is a semiconductor film, and a channel of the transistor is formed in the oxide film 404. The oxide film 404 is preferably the CAAC-OS film which is described in the above embodiment. Note that the oxide film 404 may be an amorphous oxide film, a single crystal oxide film, a polycrystalline oxide film, or a microcrystalline oxide film. The oxide film 404 has a thickness of 1 nm to 50 nm, preferably 5 nm to 20 nm.

In each of the above structures, it is preferable that the oxide film 404 where the channel of the transistor is formed be highly purified by reducing the concentration of impurities and by reducing oxygen vacancies in the oxide film 404. The oxide film which is highly purified is i-type (intrinsic) semiconductor or substantially i-type semiconductor. The carrier density of an oxide film which is substantially i-type is lower than 1×10¹⁷/cm³, lower than 1×10¹⁵/cm³, or lower than 1×10¹³/cm³.

For example, the oxide film 404 is formed as described in the above embodiment so that the film does not contain hydrogen, water, and the like, whereby the concentration of impurities contained in the oxide film 404 can be reduced. Alternatively, the concentration of impurities may be reduced by performing heat treatment after the oxide film 404 is formed, thereby removing hydrogen, water, and the like from the oxide film. After that, the oxide film 404 can be highly purified by supplying oxygen to the oxide film 404 to fill oxygen vacancies.

In the oxide film 404, hydrogen, nitrogen, carbon, silicon, and a metal element other than main components are impurities. In order to reduce the concentration of impurities in the oxide film 404, it is preferable to reduce the concentration of impurities in the gate insulating film 402 and the insulating film 406 which are adjacent to the oxide film 404. For example, silicon in the oxide film 404 forms an impurity state. In addition, the impurity state may serve as a trap, leading to deterioration of electrical characteristics of the transistor in some cases.

Therefore, the concentration of hydrogen in the oxide film, which is measured by secondary ion mass spectrometry (SIMS), should be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

The concentration of nitrogen in the oxide film, which is measured by SIMS, should be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of carbon in the oxide film, which is measured by SIMS, should be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of silicon in the oxide film, which is measured by SIMS, should be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The amount of each of the following gases released from the oxide film should be 1×10¹⁹/cm³ or less, preferably 1×10¹⁸/cm³ or less, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

The off-state current of a transistor manufactured using the above oxide film 404 for a channel formation region can be sufficiently reduced (in this embodiment, the off-state current means a drain current when a potential difference between a source and a gate is equal to or lower than the threshold voltage in the off state, for example). In the case where a highly purified oxide film is used for a transistor having a channel length of 10 μm, an oxide film thickness of 30 nm, and a drain voltage of about 1 V to 10 V, the off-state current of the transistor can be 1×10⁻¹³ A or less. In addition, the off-state current per channel width (the value obtained by dividing the off-state current by the channel width of the transistor) can be about 1×10⁻²³ A/μm (10 yA/μm) to 1×10⁻²² A/μm (100 yA/μm).

In each of the transistors described above, the gate insulating film 402 is formed using a silicon oxide film, a silicon oxynitride film, a silicon nitride oxide film, a silicon nitride film, a gallium oxide film, an aluminum oxide film, a silicon nitride film, or an aluminum oxynitride film. In the case of the gate insulating film 402 having a single-layer structure, a silicon oxide or silicon oxynitride film is used, for example. In the case of a two-layer structure, a silicon oxide or silicon oxynitride film and a silicon nitride film thereover are provided as the gate insulating film 402.

In each of the transistors described above, the insulating film 406 is formed using a silicon oxide film, a silicon oxynitride film, a silicon nitride oxide film, a silicon nitride film, a gallium oxide film, an aluminum oxide film, a silicon nitride film, or an aluminum oxynitride film. In the case of the insulating film 406 having a single-layer structure, a silicon oxynitride film is used, for example. In the case of a two-layer structure, a silicon oxide or silicon oxynitride film and a silicon nitride film thereover are provided as the insulating film 406.

As described above, a transistor in one embodiment of the present invention includes the oxide film described in the above embodiment. Therefore, the transistor has electrically stable characteristics. The use of the transistor in a semiconductor device makes it possible to improve reliability.

### [5.2. Transistor Manufactured Using Stacked-Layer Film of Oxide Films]

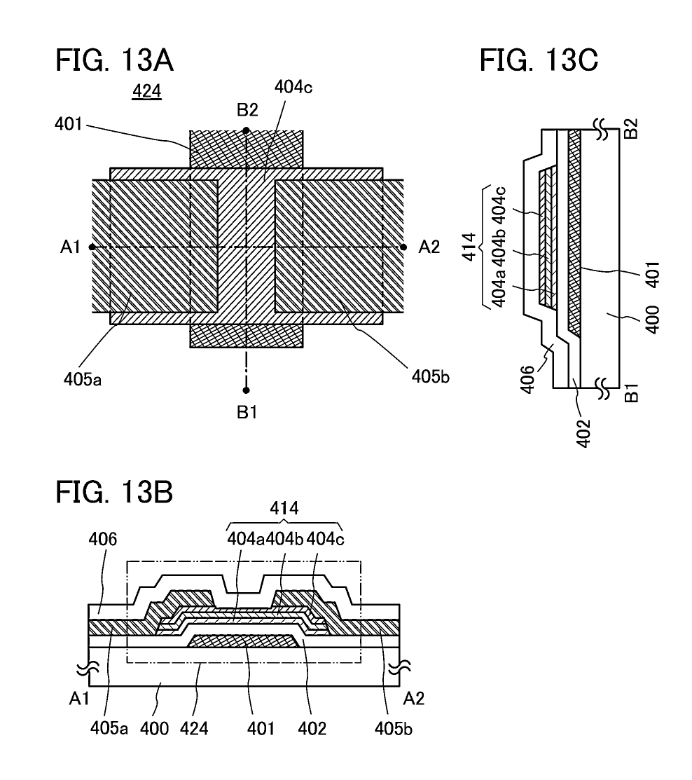

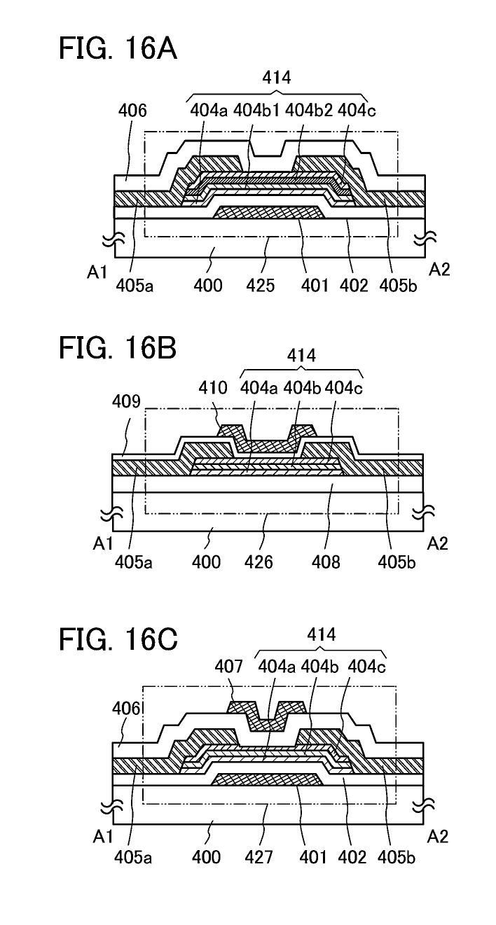

Next, transistors each manufactured using a stacked-layer film of oxide films (hereinafter referred to as a stacked-layer oxide film) will be described with reference to FIGS. 13A to 13C and FIGS. 16A to 16C.

### [5.2.1. Bottom-Gate Transistor]

FIGS. 13A to 13C illustrate a structural example of a transistor 424 having a bottom-gate structure. FIG. 13A is a plan view of the transistor 424. FIG. 13B is a cross-sectional view taken along the long dashed short dashed line A1-A2 in FIG. 13A. FIG. 13C is a cross-sectional view taken along the long dashed short dashed line B1-B2 in FIG. 13A.

The transistor 424 includes a gate electrode 401 provided over a substrate 400 having an insulating surface, a gate insulating film 402 provided over the gate electrode 401, a stacked-layer oxide film 414 overlapping with the gate electrode 401 with the gate insulating film 402 provided therebetween, and a source electrode 405a and a drain electrode 405b provided in contact with the stacked-layer oxide film 414. In addition, an insulating film 406 is provided so as to cover the source electrode 405a and the drain electrode 405b and be in contact with the stacked-layer oxide film 414.

The stacked-layer oxide film 414 is formed by stacking a plurality of oxide films and has a structure in which three layers, i.e., an oxide film 404a, an oxide film 404b, and an oxide film 404c, are sequentially stacked, for example.

The oxide film 404a is an oxide film which contains one, two, or more elements contained in the oxide film 404b and in which the energy at the bottom of the conduction band is closer to the vacuum level than that in the oxide film 404b by higher than or equal to 0.05 eV, 0.07 eV, 0.1 eV, or 0.15 eV and lower than or equal to 2 eV, 1 eV, 0.5 eV, or 0.4 eV. Note that the oxide film 404b preferably contains at least indium, in which case carrier mobility can be increased. At this time, by application of an electric field to the gate electrode 401, in the stacked-layer oxide film 414, a channel is formed in the oxide film 404b in which the energy at the bottom of the conduction band is low. That is, since the oxide film 404a is provided between the oxide film 404b and the gate insulating film 402, a channel of the transistor can be formed in the oxide film 404b which is not in contact with the gate insulating film 402. In addition, since the oxide film 404a contains one or more metal elements contained in the oxide film 404b, interface scattering is unlikely to occur at the interface between the oxide film 404b and the oxide film 404a. Therefore, carrier movement is not inhibited at the interface; thus, the field-effect mobility of the transistor is increased.

For example, the oxide film 404a may be an oxide film which contains aluminum, gallium, germanium, yttrium, zirconium, tin, lanthanum, or cerium at an atomic ratio higher than that in the oxide film 404b, for example. Specifically, an oxide film which contains the above element at an atomic ratio 1.5 or more times, preferably 2 or more times, more preferably 3 or more times that in the oxide film 404b is used as the oxide film 404a. Since the above element strongly binds to oxygen, it has a function of preventing oxygen vacancies from being generated in an oxide film. That is, the oxide film 404a is an oxide film in which oxygen vacancies are less likely to be generated than in the oxide film 404b.

Alternatively, assuming that the oxide film 404a is an In-M-Zn oxide with In:M:Zn=x₁:y₁:z₁ (in atomic ratio) and the oxide film 404b is an In-M-Zn oxide with In:M:Zn=x₂:y₂:z₂ (in atomic ratio), the oxide film 404a and the oxide film 404b are selected such that y₁/x₁ is greater than y₂/x₂. Note that the element M is a metal element which has a higher ability than In to bind to oxygen, examples of which include Al, Ti, Ga, Y, Zr, Sn, La, Ce, Nd, Hf, and the like. The oxide film 404a and the oxide film 404b are preferably selected such that y₁/x₁ is 1.5 or more times y₂/x₂. The oxide film 404a and the oxide film 404b are more preferably selected such that y₁/x₁ is 2 or more times y₂/x₂. The oxide film 404a and the oxide film 404b are still more preferably selected such that y₁/x₁ is 3 or more times y₂/x₂. At this time, it is preferable that y₂ be greater than or equal to x₂ in the oxide film 404b, in which case the transistor can have stable electrical characteristics. Note that y₂ is preferably less than 3 times x₂ because the field-effect mobility of the transistor is lowered if y₂ is 3 or more times x₂.

The oxide film 404a has a thickness of 3 nm to 100 nm, preferably 3 nm to 50 nm. The oxide film 404b has a thickness of 3 nm to 200 nm, preferably 3 nm to 100 nm, more preferably 3 nm to 50 nm.

The oxide film 404c is an oxide film which contains one, two, or more elements contained in the oxide film 404b and in which the energy at the bottom of the conduction band is closer to the vacuum level than that in the oxide film 404b by higher than or equal to 0.05 eV, 0.07 eV, 0.1 eV, or 0.15 eV and lower than or equal to 2 eV, 1 eV, 0.5 eV, or 0.4 eV. Since the oxide film 404c contains one or more metal elements contained in the oxide film 404b, an interface state is unlikely to be formed at the interface between the oxide film 404b and the oxide film 404c. If the interface has an interface state, a second transistor having a channel at the interface and having a different threshold voltage might be formed, and an apparent threshold voltage of the transistor 424 might be changed. Therefore, when the oxide film 404c is provided, variation in electrical characteristics such as threshold voltage among transistors can be reduced.

For example, the oxide film 404c may be an oxide film containing aluminum, gallium, germanium, yttrium, zirconium, tin, lanthanum, or cerium at an atomic ratio higher than that in the oxide film 404b, for example. Specifically, an oxide film containing the above element at an atomic ratio 1.5 or more times, preferably 2 or more times, more preferably 3 or more times that in the oxide film 404b is used as the oxide film 404c. Since the above element strongly binds to oxygen, it has a function of preventing oxygen vacancies from being generated in an oxide film. That is, the oxide film 404c is an oxide film in which oxygen vacancies are less likely to be generated than in the oxide film 404b.

Alternatively, assuming that the oxide film 404b is an In-M-Zn oxide with In:M:Zn=x₂:y₂:z₂ (in atomic ratio) and the oxide film 404c is an In-M-Zn oxide with In:M:Zn=x₃:y₃:z₃ (in atomic ratio), the oxide film 404b and the oxide film 404c are selected such that y₃/x₃ is greater than y₂/x₂. Note that the element M is a metal element which has a higher ability than In to bind to oxygen, examples of which include Al, Ti, Ga, Y, Zr, Sn, La, Ce, Nd, Hf, and the like. The oxide film 404b and the oxide film 404c are preferably selected such that y₃/x₃ is 1.5 or more times y₂/x₂. The oxide film 404b and the oxide film 404c are more preferably selected such that y₃/x₃ is 2 or more times y₂/x₂. The oxide film 404b and the oxide film 404c are still more preferably selected such that y₃/x₃ is 3 or more times y₂/x₂. At this time, it is preferable that y₂ be greater than or equal to x₂ in the oxide film 404b, in which case the transistor can have stable electrical characteristics. Note that y₂ is preferably equal to x₂ or less than 3 times x₂ because the field-effect mobility of the transistor is lowered if y₂ is 3 or more times x₂.

The oxide film 404c has a thickness of 3 nm to 100 nm, preferably 3 nm to 50 nm.

Note that the oxide film 404a, the oxide film 404b, and the oxide film 404c can each be formed with an amorphous oxide film, a single crystal oxide film, a polycrystalline oxide film, or a microcrystalline oxide film, as well as the CAAC-OS film described in the above embodiment. In the transistor 424, the oxide film 404b is a CAAC-OS film including a crystal part, and the oxide film 404a and the oxide film 404c do not necessarily have crystallinity and may be amorphous oxide films. For example, the oxide film 404a may be an amorphous oxide film, and the oxide film 404b and the oxide film 404c may be CAAC-OS films. When the oxide film 404b in which a channel is formed is a CAAC-OS film, the transistor can have stable electrical characteristics. In addition, when the oxide film 404a is an amorphous oxide film, the effect of the oxide film 404a on the formation of the oxide film 404b can be reduced, which enables the oxide film 404b to be likely to be a CAAC-OS film.

### [5.2.2. Energy Band Structure of Stacked-Layer Oxide Film]

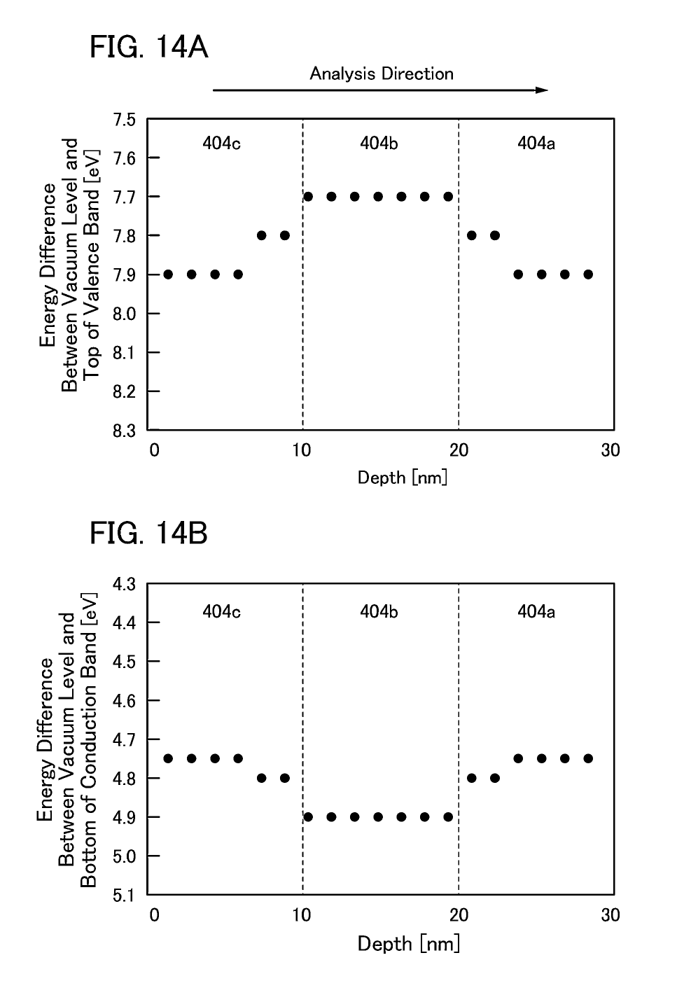

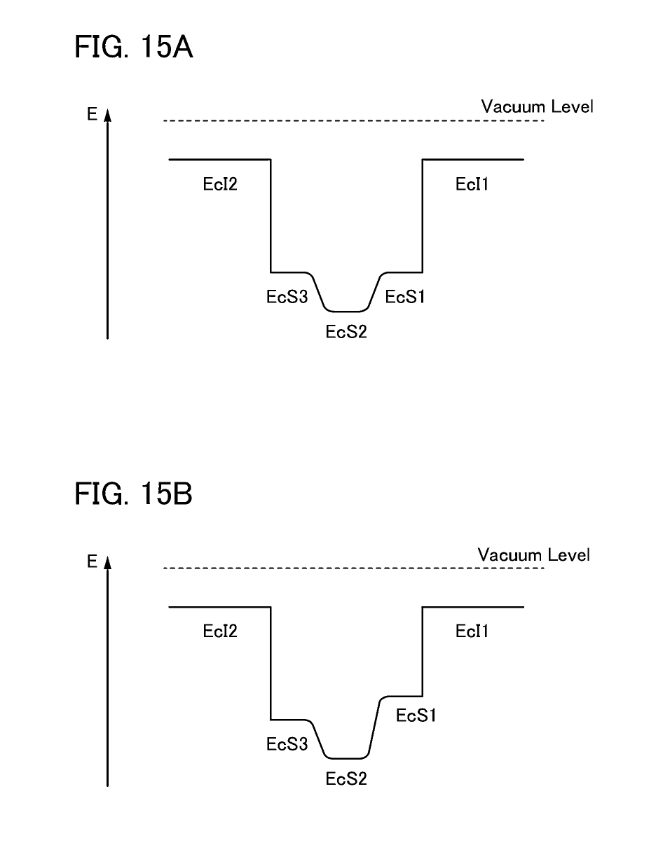

Here, an energy band structure of the stacked-layer oxide film 414 will be described with reference to FIGS. 14A and 14B and FIGS. 15A and 15B.

First, the structure of the stacked-layer oxide film 414 for explanation of the band structure will be described. An InGa—Zn oxide having an energy gap of 3.15 eV was used as the oxide film 404a; an InGa—Zn oxide having an energy gap of 2.8 eV was used as the oxide film 404b; and an oxide film having properties similar to those of the oxide film 404a was used as the oxide film 404c. The energy gap in the vicinity of the interface between the oxide film 404a and the oxide film 404b was 3 eV, and the energy gap in the vicinity of the interface between the oxide film 404c and the oxide film 404b was 3 eV. The energy gaps were measured using a spectroscopic ellipsometer (UT-300 manufactured by HORIBA Jobin Yvon). The thickness of the oxide film 404a was 10 nm; the thickness of the oxide film 404b was 10 nm; and the thickness of the oxide film 404c was 10 nm.

FIG. 14A is a graph on which values of the energy difference between the vacuum level and the top of the valence band of each layer are plotted; the values were measured using an ultraviolet photoelectron spectrometer (UPS) (VersaProbe manufactured by PHI) while the stacked-layer oxide film 414 was being etched from the oxide film 404c.

FIG. 14B is a graph on which values of the energy difference between the vacuum level and the bottom of the conduction band are plotted; the values were calculated by subtracting the energy gap of each layer from the energy difference between the vacuum level and the top of the valence band.

FIG. 15A illustrates a partial schematic band structure of FIG. 14B. With reference to FIG. 15A, a case will be described in which silicon oxide films are provided in contact with the oxide film 404a and the oxide film 404c. Here, EcI1 represents the energy at the bottom of the conduction band of the silicon oxide film. EcS1 represents the energy at the bottom of the conduction band of the oxide film 404a. EcS2 represents the energy at the bottom of the conduction band of the oxide film 404b. EcS3 represents the energy at the bottom of the conduction band of the oxide film 404c. EcI2 represents the energy at the bottom of the conduction band of the silicon oxide film.

As illustrated in FIG. 15A, the energy at the bottom of the conduction band changes continuously in the oxide film 404a, the oxide film 404b, and the oxide film 404c.

Note that FIG. 15A illustrates the case where the oxide film 404a and the oxide film 404c are oxide films having similar properties; however, the oxide film 404a and the oxide film 404c may be oxide films having different properties. For example, in the case where EcS1 is higher than EcS3, part of the band structure can be illustrated as in FIG. 15B. Although not illustrated in FIG. 15A or 15B, EcS3 may be higher than EcS1.

It can be seen from FIG. 14B and FIGS. 15A and 15B that the oxide film 404a, the oxide film 404b, and the oxide film 404c in the stacked-layer oxide film 414 form a well structure in terms of the energy at the bottom of the conduction band. In a transistor manufactured using the stacked-layer oxide film 414, a channel is formed in the oxide film 404b.

The stacked-layer oxide film formed by stacking oxide films having a common main component is manufactured not simply by stacking the films, but so as to have a continuous junction (particularly, a U-shaped well structure where the energy at the bottom of the conduction band changes continuously between the films). That is, a stacked-layer structure is formed such that there exist no impurities which form a defect state such as a trap center or a recombination center, or a barrier inhibiting carrier flow, for the oxide films at each interface. If impurities are mixed between the films in the stacked-layer oxide film, the continuity of the energy band is lost and carriers disappear by being trapped or recombined at the interface.

In order to form the continuous junction, the oxide films need to be stacked successively using the above-described multi-chamber film formation apparatus including the load lock chamber, without being exposed to the air. Each chamber of the film formation apparatus is preferably evacuated to a high vacuum (about 1×10⁻⁴ Pa to 5×10⁻⁷ Pa) using an entrapment vacuum pump such as a cryopump in order to remove as much water or the like as possible, which is an impurity for the oxide films. Alternatively, a combination of a turbo molecular pump with a cold trap is preferable in order to prevent backflow of a gas containing carbon, moisture, or the like from a gas evacuation system into the chamber.

In order to obtain a high-purity intrinsic oxide film, it is necessary to highly purify a sputtering gas as well as to evacuate the chamber to a high vacuum. The entry of moisture or the like to the oxide film can be minimized by using, as a sputtering gas, a highly purified oxygen gas or argon gas whose dew point is −40° C. or lower, preferably −80° C. or lower, more preferably −100° C. or lower.

In addition, it is preferable that a particle separated from a sputtering target maintains a flat-plate-like shape until the particle reaches the deposition surface, and that the entry of moisture to a deposition surface be prevented by heating a substrate at 100° C. or higher.

As a sputtering apparatus, it is preferable to employ a sputtering apparatus using a direct-current (DC) power source. Note that a power source of a sputtering apparatus is not limited thereto, and a sputtering apparatus using a high-frequency (RF) power source or a sputtering apparatus using an alternate-current (AC) power source may be employed, for example.

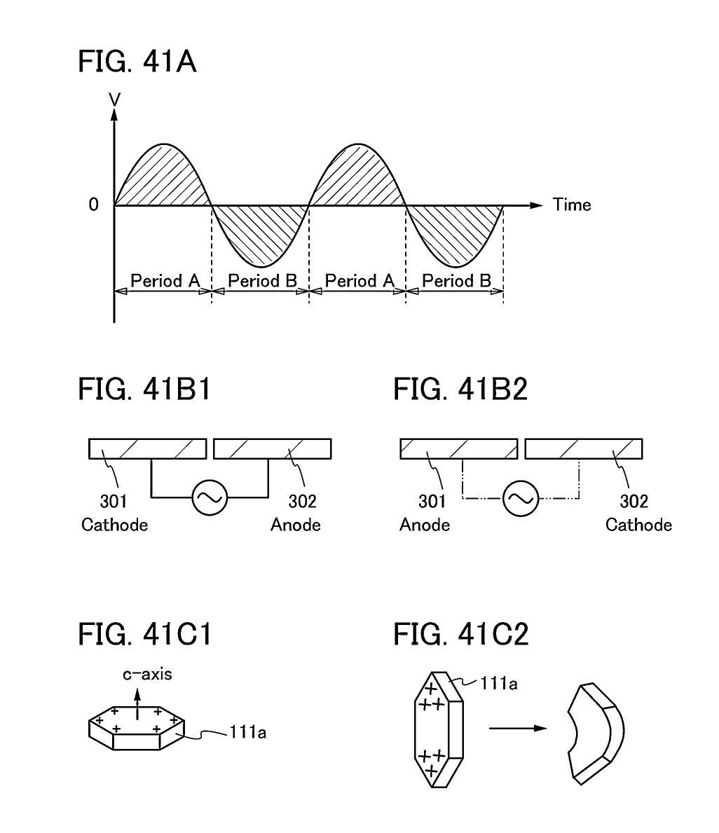

Here, a sputtering apparatus using an alternate-current (AC) power source is described. For example, a sputtering apparatus using an alternate-current (AC) power source has a structure in which each of two adjacent targets alternates between a cathode potential and an anode potential. In a period A shown in FIG. 41A, a target 301 functions as a cathode, and a target 302 functions as a cathode as illustrated in FIG. 41B1. In a period B shown in FIG. 41A, the target 301 functions as an anode, and the target 302 functions as a cathode as illustrated in FIG. 41B2. The total time of the period A and the period B is 20 μsec to 50 μsec, and the period A and the period B are repeated at a constant frequency. In this manner, by making the two adjacent targets function as a cathode and as an anode alternately, stable discharge can be achieved. As a result, even when a large-sized substrate is used, uniform discharge is possible; accordingly, uniform film characteristics can be obtained also in the case of using the large-sized substrate. Moreover, since the large-sized substrate can be used, mass productivity can be improved.

At the time of sputtering, as illustrated in FIG. 41C1, the sputtered particle 111a carries positive charges which repel each other, thereby maintaining its flat-plate-like shape. In the case where an oxide film is formed with a sputtering apparatus using an alternate-current (AC) power source, while one of targets is at an anode potential, there is a moment when no electric field is applied to a peripheral region of the target. At this time, charges carried by the sputtered particle 111a may disappear and the structure of the sputtered particle may be deformed as illustrated in FIG. 41C2. Therefore, forming an oxide film with a sputtering apparatus using a direct-current (DC) power source is preferable to forming an oxide film with a sputtering apparatus using an alternate-current (AC) power source.

Note that as illustrated in FIGS. 15A and 15B, trap states resulting from impurities or defects can be formed in the vicinity of the interfaces between the oxide film 404a and an insulating film such as the silicon oxide film and between the oxide film 404c and an insulating film. Since the oxide film 404a and the oxide film 404c are provided, the oxide film 404b can be distanced from the trap states. However, in the case where the energy difference between EcS1 and EcS2 or between EcS3 and EcS2 is small, electrons in the oxide film 404b may reach the trap level by passing over the energy gap. Since the electron is trapped at the trap level, a negative fixed charge is generated, causing the threshold voltage of the transistor to be shifted in the positive direction.

Therefore, each of the energy differences between EcS1 and EcS2 and between EcS3 and EcS2 is preferably set to be larger than or equal to 0.1 eV, more preferably larger than or equal to 0.15 eV, in which case a change in the threshold voltage of the transistor can be reduced and stable electrical characteristics can be obtained.

### [5.2.3. Top-Gate Transistor]

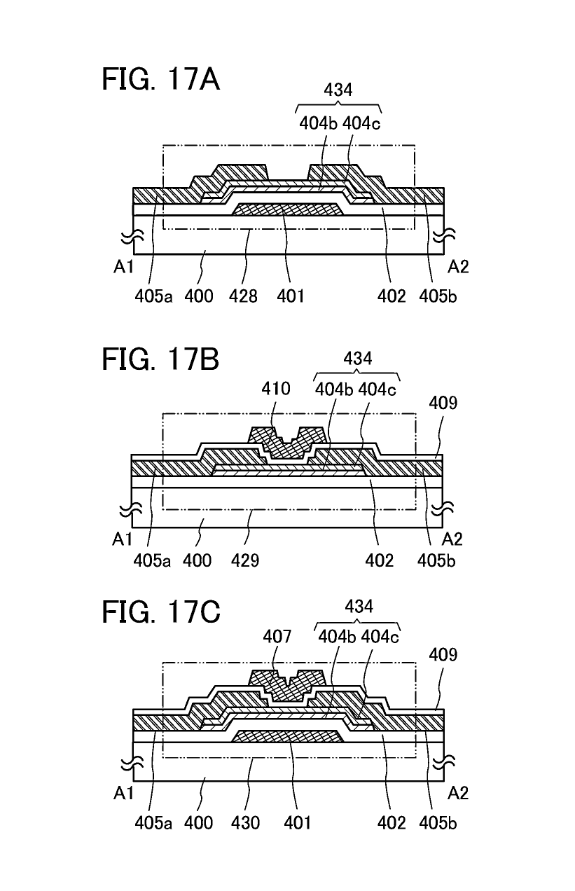

Next, other structural examples of transistors manufactured using a stacked-layer film of oxide films are illustrated in FIGS. 16A to 16C and FIGS. 17A to 17C.

FIG. 16A illustrates a transistor 425 in which the oxide film 404b in the stacked-layer oxide film 414 has a two-layer structure. An oxide film 404b1 and an oxide film 404b2 are formed using materials each of which satisfies the above-described atomic ratio relationship with the oxide film 404a and the above-described atomic ratio relationship with the oxide film 404c. Note that components other than the stacked-layer oxide film 414 (corresponding to the stacked-layer oxide film 414 in FIGS. 13A to 13C) are similar to those of the transistor 424 illustrated in FIGS. 13A to 13C.

FIG. 16B illustrates a transistor 426 having a top-gate structure.

The transistor 426 includes an insulating film 408 provided over a substrate 400 having an insulating surface, a stacked-layer oxide film 414 provided over the insulating film 408, a source electrode 405a and a drain electrode 405b provided in contact with the stacked-layer oxide film 414, a gate insulating film 409 provided over the stacked-layer oxide film 414, the source electrode 405a, and the drain electrode 405b, and a gate electrode 410 overlapping with the stacked-layer oxide film 414 with the gate insulating film 409 provided therebetween.

Note that the stacked-layer oxide film 414 illustrated in FIG. 16B has a structure similar to that of the stacked-layer oxide film 414 illustrated in FIGS. 13A to 13C.

### [5.2.4. Dual-Gate Transistor]

FIG. 16C illustrates a transistor 427 having a dual-gate structure, which includes two gate electrodes above and below a channel formation region with gate insulating films provided therebetween.

The transistor 427 includes a gate electrode 401 provided over a substrate 400 having an insulating surface, a gate insulating film 402 provided over the gate electrode 401, a stacked-layer oxide film 414 overlapping with the gate electrode 401 with the gate insulating film 402 provided therebetween, a source electrode 405a and a drain electrode 405b provided in contact with the stacked-layer oxide film 414, an insulating film 406 covering the source electrode 405a and the drain electrode 405b and in contact with the stacked-layer oxide film 414, and an electrode layer 407 overlapping with the stacked-layer oxide film 414 with the insulating film 406 provided therebetween.

In the transistor 427, the insulating film 406 functions as a gate insulating film, and the electrode layer 407 functions as a gate electrode. One of the pair of gate electrodes may be supplied with a signal for controlling whether to turn on or off the transistor, and the other gate electrode may be supplied with a ground potential or a fixed potential such as a negative potential. By controlling the level of the potential supplied to the other gate electrode, the threshold voltage of the transistor 427 can be controlled. By controlling the potentials of both gate electrodes as described above, a change in threshold voltage of the transistor can be further reduced. Thus, reliability can be improved.

Note that the stacked-layer oxide film 414 illustrated in FIG. 16C has a structure similar to that of the stacked-layer oxide film 414 illustrated in FIGS. 13A to 13C.

### [5.2.5. Transistor Manufactured Using Stacked-Layer Film of Two Oxide Films]

Next, transistors manufactured using a stacked-layer oxide film having a two-layer structure are illustrated in FIGS. 17A to 17C.

FIG. 17A illustrates a transistor 428 having a bottom-gate structure. In the transistor 428, a stacked-layer oxide film 434 has a two-layer structure.

An oxide film 404c is an oxide film which contains one or more metal elements contained in an oxide film 404b and in which the energy at the bottom of the conduction band is closer to the vacuum level than that in the oxide film 404b by higher than or equal to 0.05 eV, 0.07 eV, 0.1 eV, or 0.15 eV and lower than or equal to 2 eV, 1 eV, 0.5 eV, or 0.4 eV. Since the oxide film 404c contains one or more metal elements contained in the oxide film 404b, an interface state is unlikely to be formed at the interface between the oxide film 404b and the oxide film 404c. If the interface has an interface state, a second transistor having a channel at the interface and having a different threshold voltage might be formed, and an apparent threshold voltage of the transistor 428 might be changed. Therefore, when the oxide film 404c is provided, variation in electrical characteristics such as threshold voltage among transistors can be reduced.

For example, the oxide film 404c may be an oxide film containing aluminum, gallium, germanium, yttrium, zirconium, tin, lanthanum, or cerium at an atomic ratio higher than that in the oxide film 404b, for example. Specifically, an oxide film containing the above element at an atomic ratio 1.5 or more times, preferably 2 or more times, more preferably 3 or more times that in the oxide film 404b is used as the oxide film 404c. Since the above element strongly binds to oxygen, it has a function of preventing oxygen vacancies from being generated in an oxide film. That is, the oxide film 404c is an oxide film in which oxygen vacancies are less likely to be generated than in the oxide film 404b.

Alternatively, assuming that the oxide film 404b is an In-M-Zn oxide with In:M:Zn=x₂:y₂:z₂ (in atomic ratio) and the oxide film 404c is an In-M-Zn oxide with In:M:Zn=x₃:y₃:z₃ (in atomic ratio), the oxide film 404b and the oxide film 404c are selected such that y₃/x₃ is greater than y₂/x₂. Note that the element M is a metal element which has a higher ability than In to bind to oxygen, examples of which include Al, Ti, Ga, Y, Zr, Sn, La, Ce, Nd, Hf, and the like. The oxide film 404b and the oxide film 404c are preferably selected such that y₃/x₃ is 1.5 or more times y₂/x₂. The oxide film 404b and the oxide film 404c are more preferably selected such that y₃/x₃ is 2 or more times y₂/x₂. The oxide film 404b and the oxide film 404c are still more preferably selected such that y₃/x₃ is 3 or more times y₂/x₂. At this time, it is preferable that y₂ be greater than or equal to x₂ in the oxide film 404b, in which case the transistor can have stable electrical characteristics. Note that y₂ is preferably equal to x₂ or less than 3 times x₂ because the field-effect mobility of the transistor is lowered if y₂ is 3 or more times x₂.

The oxide film 404c has a thickness of 3 nm to 100 nm, preferably 3 nm to 50 nm.

Note that the oxide film 404b and the oxide film 404c are each preferably formed with the CAAC-OS film described in the above embodiment, as well as an amorphous oxide film, a single crystal oxide film, a polycrystalline oxide film, or a microcrystalline oxide film. In the transistor 428, the oxide film 404b and the oxide film 404c are CAAC-OS films including crystal parts. When the oxide film 404b and the oxide film 404c are CAAC-OS films, the transistor can have stable electrical characteristics.

Other examples of transistors including the stacked-layer oxide film 434 include a transistor having a top-gate structure illustrated in FIG. 17B and a transistor having a dual-gate structure illustrated in FIG. 17C.

It is preferable that at least the oxide film 404b in the stacked-layer oxide film 414 or the stacked-layer oxide film 434 where the channel of the transistor is formed be highly purified by reducing the concentration of impurities and by reducing oxygen vacancies in the oxide film 404b. The oxide film 404b which is highly purified is i-type (intrinsic) semiconductor or substantially i-type semiconductor. The carrier density of an oxide film which is substantially i-type is lower than 1×10¹⁷/cm³, lower than 1×10¹⁵/cm³, or lower than 1×10¹³/cm³.

For example, the oxide film is formed as described in the above embodiment so that the film does not contain hydrogen, water, and the like, whereby the concentration of impurities contained in the oxide film can be reduced. Alternatively, the concentration of impurities may be reduced by performing heat treatment after the oxide film is formed, thereby removing hydrogen, water, and the like from the oxide film. After that, the oxide film can be highly purified by supplying oxygen to the oxide film to fill oxygen vacancies.

In the stacked-layer oxide film 414 and the stacked-layer oxide film 434, hydrogen, nitrogen, carbon, silicon, and a metal element other than main components are impurities. In order to reduce the concentration of impurities in the stacked-layer oxide film 414, it is preferable to reduce the concentration of impurities in the gate insulating film 402 and the insulating film 406 which are adjacent to the stacked-layer oxide film 414. For example, silicon in the stacked-layer oxide film 414 forms an impurity state. In addition, the impurity state may serve as a trap, leading to deterioration of electrical characteristics of the transistor in some cases.

Therefore, the concentration of hydrogen in each oxide film, which is measured by secondary ion mass spectrometry (SIMS), should be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

The concentration of nitrogen in each oxide film, which is measured by SIMS, should be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of carbon in each oxide film, which is measured by SIMS, should be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of silicon in each oxide film, which is measured by SIMS, should be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The amount of each of the following gases released from each oxide film should be 1×10¹⁹/cm³ or less, preferably 1×10¹⁸/cm³ or less, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

The off-state current of a transistor manufactured using the above oxide film for a channel formation region can be sufficiently reduced (in this embodiment, the off-state current means a drain current when a potential difference between a source and a gate is equal to or lower than the threshold voltage in the off state, for example). In the case where a highly purified oxide film is used for a transistor having a channel length of 10 μm, an oxide film thickness of 30 nm, and a drain voltage of about 1 V to 10 V, the off-state current of the transistor can be 1×10⁻¹³ A or less. In addition, the off-state current per channel width (the value obtained by dividing the off-state current by the channel width of the transistor) can be about 1×10⁻²³ A/μm (10 yA/μm) to 1×10⁻²² A/μm (100 yA/μm). When the off-state current of the transistor per channel width has the value mentioned above, the on/off ratio of the transistor can be in the range from 15 digits (1×10¹⁵) to 50 digits (1×10⁵⁰), preferably from 20 digits (1×10²⁰) to 50 digits (1×10⁵⁰).

As described above, a transistor in one embodiment of the present invention has electrically stable characteristics. The use of the transistor in a semiconductor device makes it possible to improve reliability.

### [5.3. Method for Manufacturing Transistor]

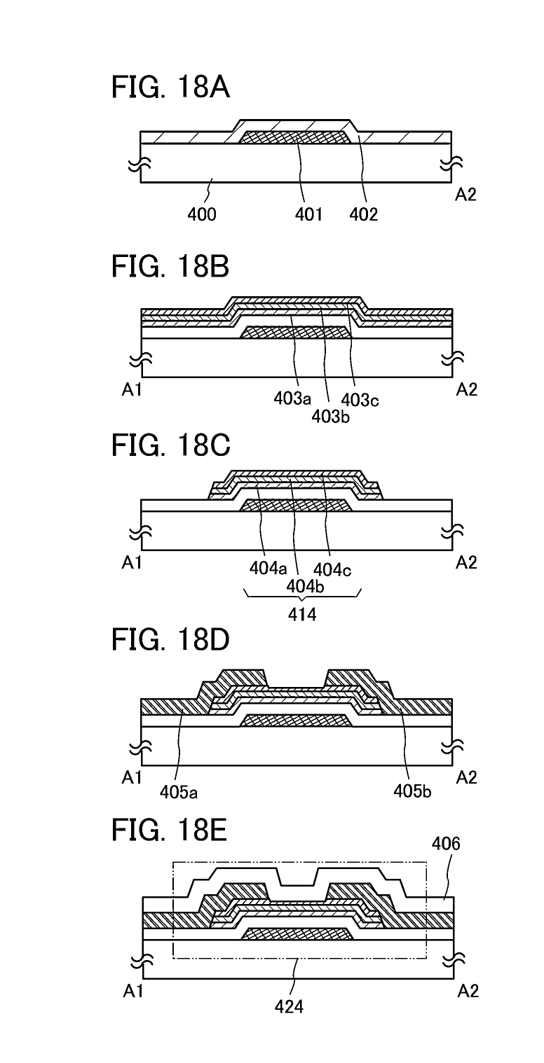

Next, a method for manufacturing the transistor 424 illustrated in FIGS. 13A to 13C will be described with reference to FIGS. 18A to 18E.

First, the gate electrode 401 is formed over the substrate 400 (see FIG. 18A).

Although there is no particular limitation on a substrate which can be used as the substrate 400 having an insulating surface, it is at least necessary that the substrate have heat resistance sufficient to withstand heat treatment performed later. For example, a variety of glass substrates used in the electronics industry, such as a barium borosilicate glass substrate or an aluminoborosilicate glass substrate can be used. Note that as the substrate 400, a substrate having a strain point of higher than or equal to 650° C. and lower than or equal to 750° C. (preferably higher than or equal to 700° C. and lower than or equal to 740° C.) is preferably used.

In the case where a large-sized glass substrate having the size of, for example, the fifth generation (1000 mm×1200 mm, or 1300 mm×1700 mm), the sixth generation (1700 mm×1800 mm), the seventh generation (1870 mm×2200 mm), the eighth generation (2200 mm×2700 mm), the ninth generation (2400 mm×2800 mm), the tenth generation (2880 mm×3130 mm), or the like is used, minute processing might become difficult owing to shrinkage of the substrate caused by heat treatment or the like in the process for manufacturing a semiconductor device. Therefore, when such a large-sized glass substrate is used as the substrate, the one with a small shrinkage is preferably used. For example, a large-sized glass substrate which has a shrinkage of 20 ppm or less, preferably 10 ppm or less, more preferably 5 ppm or less after heat treatment preferably at 450° C., more preferably 700° C. for one hour may be used as the substrate.

As the substrate 400, a ceramic substrate, a quartz substrate, a sapphire substrate, or the like can be used. Alternatively, a single crystal semiconductor substrate or a polycrystalline semiconductor substrate made of silicon, silicon carbide, or the like, a compound semiconductor substrate made of silicon germanium or the like, an SDI substrate, or the like can be used. Still alternatively, any of these substrates over which a semiconductor element is provided may be used.

The semiconductor device may be manufactured using a flexible substrate as the substrate 400. In order to manufacture a flexible semiconductor device, the transistor 424 including the stacked-layer oxide film 414 may be directly formed over a flexible substrate. Alternatively, the transistor 424 including the stacked-layer oxide film 414 may be formed over a formation substrate, and then, the transistor 424 may be separated and transferred to a flexible substrate. Note that in order to separate the transistor from the formation substrate and transfer it to the flexible substrate, a separation layer may be provided between the formation substrate and the transistor 424 including the stacked-layer oxide film.

The gate electrode 401 can be formed by a plasma CVD method, a sputtering method, or the like. The gate electrode 401 can be formed using a metal material such as molybdenum, titanium, tantalum, tungsten, aluminum, copper, chromium, neodymium, or scandium or an alloy material which contains any of these materials as a main component. Alternatively, a semiconductor film typified by a polycrystalline silicon film doped with an impurity element such as phosphorus, or a silicide film such as a nickel silicide film may be used as the gate electrode 401. The gate electrode 401 may have either a single-layer structure or a stacked-layer structure.

The gate electrode 401 can also be formed using a conductive material such as indium oxide-tin oxide, indium oxide containing tungsten oxide, indium zinc oxide containing tungsten oxide, indium oxide containing titanium oxide, indium tin oxide containing titanium oxide, indium oxide-zinc oxide, or indium tin oxide to which silicon oxide is added. It is also possible that the gate electrode 401 has a stacked-layer structure of the above conductive material and the above metal material.

As the gate electrode 401, a metal oxide film containing nitrogen, specifically, an InGa—Zn—O film containing nitrogen, an In—Sn—O film containing nitrogen, an In—Ga—O film containing nitrogen, an InZn—O film containing nitrogen, a Sn—O film containing nitrogen, an InO film containing nitrogen, or a metal nitride (InN, SnN, or the like) film can be used.

The gate insulating film 402 can be formed using a silicon oxide film, a silicon oxynitride film, a silicon nitride oxide film, a silicon nitride film, a gallium oxide film, an aluminum oxide film, a silicon nitride film, or an aluminum oxynitride film.

When the gate insulating film 402 is formed using a high-k material such as hafnium oxide, yttrium oxide, hafnium silicate (HfSiₓO_{y} (x>0, y>0)), hafnium silicate to which nitrogen is added (HfSiOₓN_{y} (x>0, y>0)), hafnium aluminate (HfAlₓO_{y} (x>0, y>0)), or lanthanum oxide, gate leakage current can be reduced. Further, the gate insulating film 402 may have either a single-layer structure or a stacked-layer structure.

Note that in the gate insulating film 402, a region to be in contact with the oxide film 404a which is formed later is preferably an oxide insulating layer and preferably has a region (oxygen excess region) containing oxygen in excess of the stoichiometric composition. In order to provide the oxygen excess region in the gate insulating film 402, the gate insulating film 402 may be formed in an oxygen atmosphere, for example. Alternatively, the oxygen excess region may be formed by introduction of oxygen into the gate insulating film 402 after the film formation. Oxygen can be introduced by an ion implantation method, an ion doping method, a plasma immersion ion implantation method, plasma treatment, or the like.

When the oxygen excess region is provided in the gate insulating film 402, oxygen can be supplied to the stacked-layer oxide film 414 from the gate insulating film 402 by performing heat treatment after the stacked-layer oxide film 414 is formed. Accordingly, oxygen vacancies in the stacked-layer oxide film 414 can be reduced.

In this embodiment, a silicon nitride film and a silicon oxide film are formed as the gate insulating film 402.

Next, an oxide film 403a, an oxide film 403b, and an oxide film 403c used for forming the stacked-layer oxide film are sequentially formed over the gate insulating film 402 (see FIG. 18B).

With reference to FIG. 18B, a case is described in which the oxide film 403a is formed using a sputtering target which is an oxide with an atomic ratio of In:Ga:Zn=1:3:2, the oxide film 403b is formed using a sputtering target which is an oxide with an atomic ratio of In:Ga:Zn=1:1:1, and the oxide film 403c is formed using a sputtering target which is an oxide with an atomic ratio of In:Ga:Zn=1:3:2. The above embodiment can be referred to for the film formation conditions and the like for the oxide films 403a to 403c; thus, detailed description thereof is omitted here.

In the transistor 424, at least the oxide film 403b is a CAAC-OS film including crystal parts, and the oxide film 403a and the oxide film 403c do not necessarily include crystal parts. After the film formation, the oxide film 403c does not necessarily include crystal parts, and in this case, an amorphous oxide film may be changed into the oxide film 403c including crystal parts by performing heat treatment in any step after the film formation. The heat treatment for crystallizing an amorphous oxide semiconductor is performed at a temperature higher than or equal to 250° C. and lower than or equal to 700° C., preferably higher than or equal to 400° C., more preferably higher than or equal to 550° C. The heat treatment can also serve as another heat treatment in the manufacturing process. A laser irradiation apparatus may be used for the heat treatment for crystallization.

Note that it is preferable that the oxide films 403a to 403c be formed successively without being exposed to the air. Successive formation of the oxide films without exposure to the air can prevent attachment of hydrogen or a hydrogen compound (e.g., adsorbed water) to surfaces of the oxide films and therefore can reduce the entry of impurities. In addition, it is preferable that the gate insulating film 402 to the stacked-layer oxide film 414 (the oxide film 403c) be formed successively without being exposed to the air.

Next, the oxide films 403a to 403c are preferably subjected to heat treatment for removal of excess hydrogen (including water and a hydroxyl group) contained in the films (this treatment is also referred to as dehydration or dehydrogenation). The temperature of the heat treatment is higher than or equal to 300° C. and lower than or equal to 700° C., or lower than the strain point of the substrate. The heat treatment can be performed under reduced pressure, a nitrogen atmosphere, or the like. The heat treatment enables hydrogen, which is an impurity imparting n-type conductivity, to be removed.

Note that the heat treatment for dehydration or dehydrogenation may be performed at any timing in the process of manufacturing the transistor as long as the heat treatment is performed after the formation of the oxide films 403a to 403c. For example, the heat treatment may be performed after a stacked-layer oxide film 403 is processed into an island shape. The heat treatment for dehydration or dehydrogenation may be performed plural times, and may also serve as another heat treatment. A laser irradiation apparatus may be used for the heat treatment.

In the heat treatment, it is preferable that water, hydrogen, and the like be not contained in nitrogen or a rare gas such as helium, neon, or argon. Alternatively, the purity of nitrogen or a rare gas such as helium, neon, or argon introduced into a heat treatment apparatus is preferably set to 6N (99.9999%) or more, further preferably 7N (99.99999%) or more (i.e., the impurity concentration is 1 ppm or less, preferably 0.1 ppm or less).

In addition, after the stacked-layer oxide film is heated by the heat treatment, a high-purity oxygen gas, a high-purity dinitrogen monoxide gas, or ultra-dry air (with a moisture content of 20 ppm (equivalent to a dew point of −55° C.) or less, preferably 1 ppm or less, further preferably 10 ppb or less, when measured with a dew point meter using cavity ring down laser spectroscopy (CRDS)) may be introduced into the same furnace while the heating temperature is maintained or slow cooling is performed to lower the temperature from the heating temperature. It is preferable that water, hydrogen, and the like be not contained in the oxygen gas or the dinitrogen monoxide gas. The purity of the oxygen gas or the dinitrogen monoxide gas that is introduced into the heat treatment apparatus is preferably greater than or equal to 6N, more preferably greater than or equal to 7N (i.e., the concentration of impurities in the oxygen gas or the dinitrogen monoxide gas is preferably less than or equal to 1 ppm, more preferably less than or equal to 0.1 ppm). The oxygen gas or the dinitrogen monoxide gas acts to supply oxygen that is a main component material of the stacked-layer oxide film and that is reduced by the step of removing an impurity for the dehydration or dehydrogenation, so that the stacked-layer oxide film can be a highly purified and i-type (intrinsic) stacked-layer oxide film.

Oxygen might be decreased by desorption at the same time as the dehydration or dehydrogenation treatment. Thus, oxygen (including at least one of an oxygen radical, an oxygen atom, and an oxygen ion) may be introduced into the stacked-layer oxide film after the dehydration or dehydrogenation treatment, in order to supply oxygen to the stacked-layer oxide film.

By introduction of oxygen into the stacked-layer oxide film for oxygen supply after the dehydration or dehydrogenation treatment, the stacked-layer oxide film can be highly purified and i-type (intrinsic). The change in the electrical characteristics of a transistor including an i-type (intrinsic) stacked-layer oxide film is suppressed, and the transistor is electrically stable.

In the case where the oxygen introducing step is performed after the dehydration or dehydrogenation treatment, oxygen may be directly introduced into the oxide film or may be introduced through an insulating film which is formed later. The oxygen introducing step may be performed once or plural times after the formation of the oxide film 403a, after the formation of the oxide film 403b, and/or after the formation of the oxide film 403c. For example, the oxygen introducing step may be performed after the formation of the oxide film 403a.

As a method for introducing oxygen (including at least one of an oxygen radical, an oxygen atom, and an oxygen ion), an ion implantation method, an ion doping method, a plasma immersion ion implantation method, plasma treatment, or the like can be used. A gas containing oxygen can be used for oxygen introducing treatment. As the gas containing oxygen, oxygen, dinitrogen monoxide, nitrogen dioxide, carbon dioxide, carbon monoxide, or the like can be used. Further, the gas containing oxygen for the oxygen introducing treatment may contain a rare gas.

For example, in the case where an oxygen ion is implanted by an ion implantation method, the dose may be greater than or equal to 1×10¹³ ions/cm² and less than or equal to 5×10¹⁶ ions/cm².

Through the oxygen introducing step, oxygen contained in the oxide films 403a to 403c can fill oxygen vacancies in the oxide films 403a to 403c by interdiffusing in the oxide films 403a to 403c. Accordingly, oxygen vacancies in the oxide films 403a to 403c can be reduced.

For example, in the case where an oxygen ion is implanted by an ion implantation method, the dose may be greater than or equal to 1×10¹³ ions/cm² and less than or equal to 5×10¹⁶ ions/cm².

Next, the oxide films 403a to 403c are processed into the oxide films 404a to 404c having an island shape by etching treatment using a photolithography method, whereby the stacked-layer oxide film 414 is formed (see FIG. 18C).

Note that in this embodiment, the oxide films 404a to 404c having an island shape are obtained by performing etching treatment once, so that edge portions of the oxide films in the stacked-layer oxide film 414 are aligned with each other. Note that in this specification and the like, “aligned” includes “substantially aligned”. For example, an edge portion of a layer A and an edge portion of a layer B, which are included in a stacked-layer structure and etched using the same mask, are considered to be aligned with each other.

Next, a conductive film is formed over the stacked-layer oxide film 414 and processed into the source electrode 405a and the drain electrode 405b (including a wiring formed using the same film).

For the source electrode 405a and the drain electrode 405b, it is possible to use, for example, a metal film containing an element selected from aluminum, chromium, copper, tantalum, titanium, molybdenum, and tungsten, a metal nitride film containing any of these elements as its component (a titanium nitride film, a molybdenum nitride film, or a tungsten nitride film), or the like. Alternatively, a film of a high-melting-point metal such as titanium, molybdenum, or tungsten or a metal nitride film thereof (e.g., a titanium nitride film, a molybdenum nitride film, or a tungsten nitride film) may be formed over and/or under a metal film such as an aluminum film or a copper film. Further alternatively, the conductive film used for forming the source electrode 405a and the drain electrode 405b may be formed using a conductive metal oxide. As the conductive metal oxide, indium oxide (In₂O₃), tin oxide (SnO₂), zinc oxide (ZnO), indium oxide-tin oxide (In₂O₃—SnO₂), indium oxide-zinc oxide (In₂O₃—ZnO), or any of these metal oxide materials containing silicon oxide can be used.

The gap between the source electrode 405a and the drain electrode 405b is the channel length L of the transistor. In the case where the channel length L is less than 50 nm, a mask obtained by exposing a resist to an electron beam and then developing the resist is preferably used as an etching mask. Then, the conductive film is etched using the etching mask, whereby the source electrode 405a and the drain electrode 405b can be formed. Precise exposure and development using an electron beam can provide a precise pattern; thus, the gap between the source electrode 405a and the drain electrode 405b, i.e., the channel length, can be less than 50 nm, e.g., 30 nm or 20 nm. At a higher acceleration voltage, an electron beam can provide a more precise pattern. Note that the mask obtained by exposing a resist to an electron beam and then developing the resist is not necessarily used for a region other than the region which determines the channel length L.

The insulating film 406 can be formed by a plasma CVD method, a sputtering method, an evaporation method, or the like.

As the insulating film 406, it is possible to use a single layer or a stack of one or more inorganic insulating films, typical examples of which are a silicon oxide film, a silicon oxynitride film, an aluminum oxide film, an aluminum oxynitride film, a gallium oxide film, a hafnium oxide film, a magnesium oxide film, a zirconium oxide film, a lanthanum oxide film, a barium oxide film, a silicon nitride film, a silicon nitride oxide film, an aluminum nitride film, and an aluminum nitride oxide film.

In this embodiment, a silicon oxide film is formed as the insulating film 406.

Here, the oxygen introducing step may be performed in order to form an oxygen excess region in the insulating film 406. The oxygen introducing step for the insulating film 406 can be performed in a manner similar to that for the gate insulating film 402.

In addition, a planarization insulating film may be formed over the transistor in order to reduce surface unevenness due to the transistor. As the planarization insulating film, an organic material such as a polyimide-, acrylic-, or benzocyclobutene-based resin can be used. Other than such organic materials, it is also possible to use a low dielectric constant material (low-k material) or the like. Note that the planarization insulating film may be formed by stacking a plurality of insulating films formed using any of these materials.

Through the above steps, a semiconductor device in one embodiment of the present invention can be manufactured (see FIG. 18E).

When an oxide insulating film is used as an insulating film in contact with the stacked-layer oxide film 414 or an oxygen excess region is formed in the insulating film, excess oxygen contained in the insulating film can be supplied to the stacked-layer oxide film 414 by performing heat treatment or the like. Accordingly, oxygen vacancies in the stacked-layer oxide film 414 can be reduced.

Although the manufacturing method in the case of the stacked-layer oxide film is described above, a transistor can be manufactured similarly in the case of a single-layer oxide film.

A transistor manufactured using the CAAC-OS film described in the above embodiment as at least one film in the stacked-layer oxide film 414, preferably as the oxide film 404b, has little change in electrical characteristics due to irradiation with visible light or ultraviolet light. Therefore, the reliability of the transistor can be improved.

In the transistor, trap states resulting from impurities or defects can be formed in the vicinity of the interfaces between the oxide film 404a and an insulating film such as a silicon oxide film and between the oxide film 404c and an insulating film. However, since the oxide film 404a and the oxide film 404c are provided, the oxide film 404b in which a channel is formed can be distanced from the trap states.

In addition, since the oxide film 404a and the oxide film 404c contain one or more metal elements contained in the oxide film 404b, interface scattering is unlikely to occur at the interfaces between the oxide film 404b and the oxide film 404a and between the oxide film 404b and the oxide film 404c. Accordingly, carrier movement is not inhibited, and thus, the field-effect mobility of the transistor can be increased.

It is preferable that at least the oxide film 404b in the stacked-layer oxide film 414 where the channel of the transistor is formed be highly purified by reducing the concentration of impurities and by reducing oxygen vacancies in the oxide film 404b. The oxide film which is highly purified is i-type (intrinsic) semiconductor or substantially i-type semiconductor. The carrier density of an oxide film which is substantially i-type is lower than 1×10¹⁷/cm³, lower than 1×10¹⁵/cm³, or lower than 1×10¹³/cm³.

For example, the oxide film is formed as described in the above embodiment so that the film does not contain hydrogen, water, and the like, whereby the concentration of impurities contained in the oxide film can be reduced. Alternatively, the concentration of impurities may be reduced by performing heat treatment after the oxide film is formed, thereby removing hydrogen, water, and the like from the oxide film. After that, the oxide film can be highly purified by supplying oxygen to the oxide film to fill oxygen vacancies.

Therefore, the concentration of hydrogen in each oxide film, which is measured by secondary ion mass spectrometry (SIMS), is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

The concentration of nitrogen in each oxide film, which is measured by SIMS, is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of carbon in each oxide film, which is measured by SIMS, is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of silicon in each oxide film, which is measured by SIMS, is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The amount of each of the following gases released from each oxide film is 1×10¹⁹/cm³ or less, preferably 1×10¹⁸/cm³ or less, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

In the stacked-layer oxide film 414, hydrogen, nitrogen, carbon, silicon, and a metal element other than main components are impurities. In order to reduce the concentration of impurities in the stacked-layer oxide film 414, it is preferable to reduce the concentration of impurities in the gate insulating film 402 and the insulating film 406 which are adjacent to the stacked-layer oxide film 414. For example, silicon in the stacked-layer oxide film 414 forms an impurity state. In addition, the impurity state may serve as a trap, leading to deterioration of electrical characteristics of the transistor in some cases.

The off-state current of a transistor using the above oxide film for a channel formation region can be sufficiently reduced (here, the off-state current means a drain current when a potential difference between a source and a gate is equal to or lower than the threshold voltage in the off state, for example). In the case where a highly purified oxide film is used for a transistor having a channel length of 10 μm, an oxide film thickness of 30 nm, and a drain voltage of about 1 V to 10 V, the off-state current of the transistor can be 1×10⁻¹³ A or less. In addition, the off-state current per channel width (the value obtained by dividing the off-state current by the channel width of the transistor) can be about 1×10⁻²³ A/μm (10 yA/μm) to 1×10⁻²² A/μm (100 yA/μm).

This embodiment can be implemented in appropriate combinations with any of the other embodiments.

### 6. Sixth Embodiment

### Semiconductor Device

In this embodiment, a semiconductor device including the transistor described in the above embodiment will be described. Note that a semiconductor device in one embodiment of the present invention includes, in its category, various semiconductor integrated circuits formed using semiconductor elements, such as microprocessors, image processing circuits, controllers for display modules, digital signal processors (DSPs), microcontrollers, and the like. In addition, the semiconductor device in one embodiment of the present invention includes, in its category, various devices such as display modules and RF tags formed using the above semiconductor integrated circuits.

### [6.1. Display Module]

Display modules to which the transistor described in the above embodiment is applied will be described here.

As a display element provided in a display module, a light-emitting element (also referred to as a light-emitting display element), a liquid crystal element (also referred to as a liquid crystal display element), or the like can be used. The light-emitting element includes, in its category, an element whose luminance is controlled by current or voltage, and specifically includes an inorganic electroluminescent (EL) element, an organic EL element, and the like. The transistor described in the above embodiment can also be applied to display modules such as electronic paper whose contrast is changed by an electric effect (e.g., electronic ink), a digital micromirror device (DMD), a plasma display panel (PDP), and a field emission display (FED). In this embodiment, a display module including an EL element and a display module including a liquid crystal element will be described as examples of display modules.

Note that the display module in this embodiment includes, in its category, a panel in which a display element is sealed with a substrate, a resin material, or the like and the panel further provided with an IC including a built-in scan line driver circuit or a signal line driver circuit. In addition, the display module includes, in its category, panels having any of the following: a printed board provided with an arithmetic unit such as a controller, an element such as a resistor (R), a capacitor (C), or a coil (L), or the like; an optically functioning film such as a polarizing plate; a light source (including a lighting device) such as a cold cathode fluorescent lamp (CCFL) or a light-emitting diode (LED); an input device such as a resistive touch sensor or a capacitive touch sensor; a cooling device; a bezel (frame) which protects the panel; and the like.

The above-mentioned IC may be mounted on a connector such as a TAB tape, a TCP, or a COF, or may be directly mounted on a panel by a COG method.

### [6.1.1. Display Module Including EL Element]

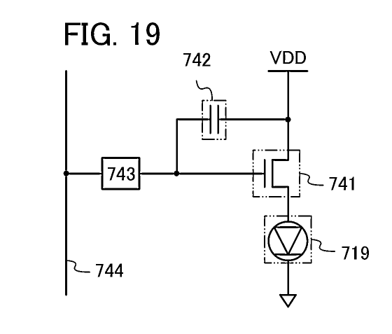

FIG. 19 is an example of a circuit diagram of a pixel in a display module including an EL element.

The display module illustrated in FIG. 19 includes a switch element 743, a transistor 741, a capacitor 742, and a light-emitting element 719.

A gate of the transistor 741 is electrically connected to one terminal of the switch element 743 and one terminal of the capacitor 742. A source of the transistor 741 is electrically connected to one terminal of the light-emitting element 719. A drain of the transistor 741 is electrically connected to the other terminal of the capacitor 742 and is supplied with a power supply potential VDD. The other terminal of the switch element 743 is electrically connected to a signal line 744. The other terminal of the light-emitting element 719 is supplied with a constant potential. Note that the constant potential is a ground potential (GND) or a potential lower than the ground potential.

Note that as the transistor 741, the transistor described in the above embodiment and manufactured using the oxide film is used. The transistor has stable electrical characteristics. Therefore, the display module can have high display quality.

It is preferable to use a transistor as the switch element 743. The use of a transistor allows the display module to have smaller pixel area and higher resolution. As the switch element 743, the transistor described in the above embodiment and manufactured using the oxide film may be used. The use of that transistor as the switch element 743 enables the switch element 743 to be manufactured through the same process as the transistor 741 and enables display modules to be obtained with high productivity.

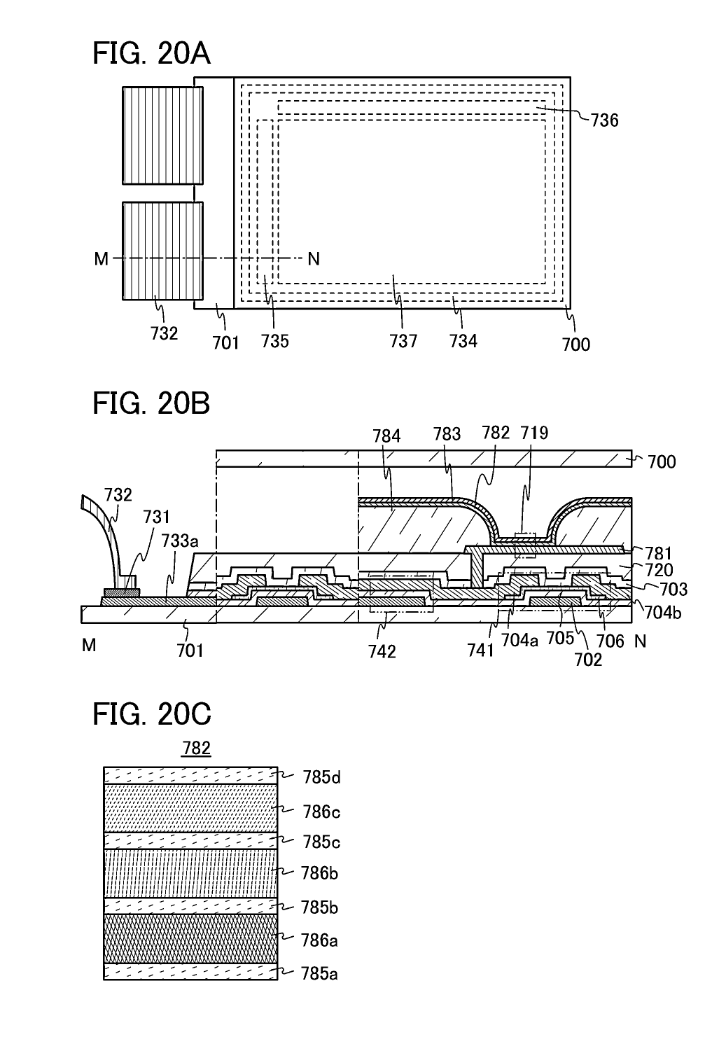

FIG. 20A is a top view of the display module including the EL element. The display module including the EL element includes a substrate 701, a substrate 700, a sealant 734, a driver circuit 735, a driver circuit 736, a pixel region 737, and an FPC 732. The sealant 734 is provided between the substrate 701 and the substrate 700 so as to surround the pixel region 737, the driver circuit 735, and the driver circuit 736. Note that the driver circuit 735 and/or the driver circuit 736 may be provided outside the sealant 734.

Entry of moisture such as water causes element breakdown or malfunction of the transistor manufactured using the oxide film in one embodiment of the present invention and the EL element. Thus, sufficient sealing with the sealant 734 is needed to maintain and/or improve the reliability of a semiconductor device.

As the sealant 734, a resin material such as an epoxy resin, an acrylic resin, or a urethane resin can be used, for example. Such a resin material may be a heat-curable resin material, a photo-curable resin material, or a heat- and photo-curable resin material. Furthermore, as the sealant 734, a mixture of different kinds of resins, such as a mixture of an acrylic-based resin and an epoxy-based resin, may be used. Such a resin mixed with a UV initiator, a heat-curing agent, a coupling agent, or the like as appropriate is used.

As the sealant 734, instead of the above resin, frit glass including low-melting-point glass (a glass material with glass frit) can be used. In the case where frit glass is used as the sealant 734, airtightness can be increased as compared with the case where a resin is used.

In FIG. 20A, the sealant 734 is provided so as to surround the pixel region 737; the pixel region 737 may be surrounded doubly or multiply to improve reliability, and furthermore, the sealant 734 may be provided at the side of the substrate 700 or 701.

FIG. 20B is a cross-sectional view of the display module including the EL element, which is taken along the long dashed short dashed line M-N in FIG. 20A. The FPC 732 is electrically connected to a wiring 733a through a terminal 731. Note that the wiring 733a is formed using the same layer as a gate electrode 702.

Note that FIG. 20B illustrates an example in which the transistor 741 and the capacitor 742 are provided on the same plane. In such a structure, the capacitor 742 can be manufactured on the same plane as the gate electrode, a gate insulating film, and a source electrode (drain electrode) of the transistor 741. When the transistor 741 and the capacitor 742 are provided on the same plane in this manner, the process for manufacturing the display module can be shortened and the productivity can be improved.

FIG. 20B illustrates an example in which a transistor having the bottom-gate structure among the transistor structures described in the above embodiment is used as the transistor 741. That is, the gate electrode 702 is provided over the substrate 701, and an oxide film 706 is provided over the gate electrode 702 with a gate insulating film 705 provided therebetween. The above embodiment can be referred to for the details of the transistor 741.

An insulating film 720 is provided over the transistor 741 and the capacitor 742.

An opening reaching a source electrode 704a of the transistor 741 is provided in the insulating film 720 and a protective insulating film 703.

An electrode 781 is provided over the insulating film 720. The electrode 781 is in contact with the source electrode 704a of the transistor 741 through the opening provided in the insulating film 720 and the protective insulating film 703.

A partition 784 having an opening reaching the electrode 781 is provided over the electrode 781.

Over the partition 784, a light-emitting layer 782 is provided which is in contact with the electrode 781 in the opening provided in the partition 784.

An electrode 783 is provided over the light-emitting layer 782.

A region where the electrode 781, the light-emitting layer 782, and the electrode 783 overlap with each other serves as the light-emitting element 719.

Note that the insulating film 720 may be formed as a single layer or a stacked layer using one or more insulating films containing any of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide. A resin film of a polyimide resin, an acrylic resin, an epoxy resin, a silicone resin, or the like can also be used.

The light-emitting layer 782 is not limited to a single layer and may be provided by stacking a plurality of kinds of light-emitting layers and the like. For example, the light-emitting layer 782 may have a structure illustrated in FIG. 20C. FIG. 20C illustrates a structure in which an intermediate layer 785a, a light-emitting layer 786a, an intermediate layer 785b, a light-emitting layer 786b, an intermediate layer 785c, a light-emitting layer 786c, and an intermediate layer 785d are stacked in this order. At this time, when the light-emitting element 719 is formed using light-emitting layers with appropriate emission colors as the light-emitting layer 786a, the light-emitting layer 786b, and the light-emitting layer 786c, the light-emitting element 719 can have high color rendering properties or high emission efficiency.

By stacking a plurality of kinds of light-emitting layers, white light may be obtained. Although not illustrated in FIG. 20B, white light may be extracted through a coloring layer.

Although the structure in which three light-emitting layers and four intermediate layers are provided is shown here, the number of light-emitting layers and the number of intermediate layers can be changed as appropriate without limitation. For example, the light-emitting layer 782 can be formed with only the intermediate layer 785a, the light-emitting layer 786a, the intermediate layer 785b, the light-emitting layer 786b, and the intermediate layer 785c. Alternatively, the light-emitting layer 782 can be formed with only the intermediate layer 785a, the light-emitting layer 786a, the intermediate layer 785b, the light-emitting layer 786b, the light-emitting layer 786c, and the intermediate layer 785d, and the intermediate layer 785c may be omitted.

In addition, the intermediate layer can be formed using a stacked-layer structure of a hole-injection layer, a hole-transport layer, an electron-transport layer, an electron-injection layer, and the like. Note that not all of these layers need to be provided as the intermediate layer. These layers may be selected and provided as appropriate. Note that a plurality of layers having similar functions may be provided. Further, a carrier generation layer, an electron-relay layer, or the like may be added as appropriate as an intermediate layer.

As the electrode 781, a conductive film having a visible light transmitting property may be used. The phrase “having a visible light transmitting property” means that the average transmittance in the visible light region (e.g., the wavelength range from 400 nm to 800 nm) is 70% or higher, particularly 80% or higher.

As the electrode 781, an oxide film such as an InZn—W oxide film, an In—Sn oxide film, an InZn oxide film, an In oxide film, a Zn oxide film, or a Sn oxide film may be used, for example. A slight amount of Al, Ga, Sb, F, or the like may be added to the above oxide film. Further, a metal thin film having a thickness small enough to transmit light (preferably, approximately 5 nm to 30 nm) can also be used. For example, an Ag film, a Mg film, or an Ag—Mg alloy film having a thickness of 5 nm may be used.

Alternatively, as the electrode 781, a film capable of efficiently reflecting visible light is preferable. For example, a film containing lithium, aluminum, titanium, magnesium, lanthanum, silver, silicon, or nickel may be used as the electrode 781.

As the electrode 783, a film selected from the films given as examples of the electrode 781 can be used. Note that in the case where the electrode 781 has a visible light transmitting property, the electrode 783 is preferably capable of efficiently reflecting visible light. In the case where the electrode 781 is capable of efficiently reflecting visible light, the electrode 783 preferably has a visible light transmitting property.

Note that the electrode 781 and the electrode 783 provided in the structure illustrated in FIG. 20B may be interchanged. It is preferable to use a conductive film having a high work function for the electrode which functions as an anode, and a conductive film having a low work function for the electrode which functions as a cathode. Note that in the case where a carrier generation layer is provided in contact with the anode, a variety of conductive films can be used for the anode regardless of their work functions.

For the partition 784, the protective insulating film 703 can be referred to. A resin film of a polyimide resin, an acrylic resin, an epoxy resin, a silicone resin, or the like can also be used.

The transistor 741 connected to the light-emitting element 719 has stable electrical characteristics. Therefore, a display module having high display quality can be provided.

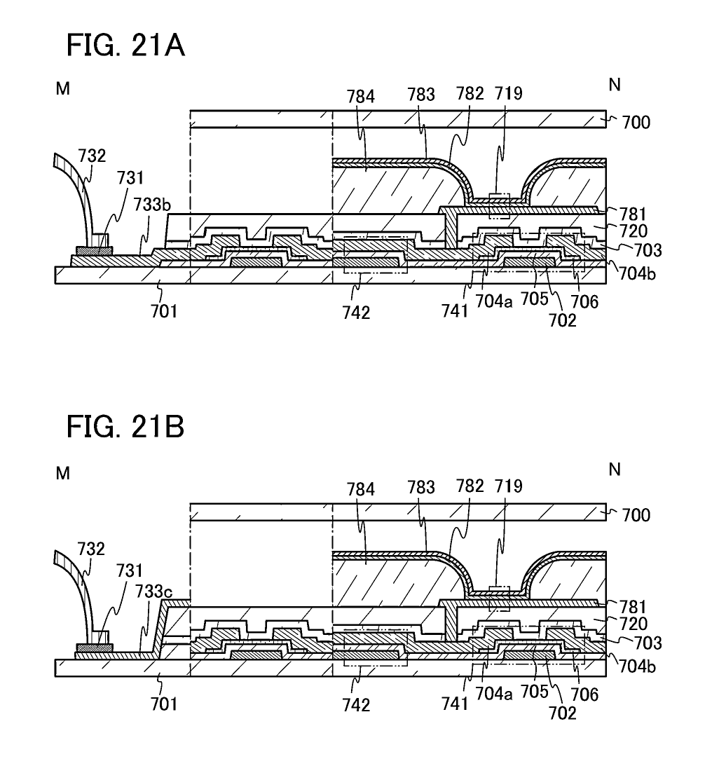

FIGS. 21A and 21B are each an example of a cross-sectional view of a display module including an EL element, which is partly different from that in FIG. 20B. Specifically, a wiring connected to the FPC 732 is different. In FIG. 21A, the FPC 732 is connected to a wiring 733b through the terminal 731. The wiring 733b is formed using the same layer as the source electrode 704a and the drain electrode 704b. In FIG. 21B, the FPC 732 is electrically connected to a wiring 733c through the terminal 731. The wiring 733c is formed using the same layer as the electrode 781.

### [6.1.2. Display Module Including Liquid Crystal Element]

Next, a display module including a liquid crystal element (hereinafter referred to as a liquid crystal display module) will be described.

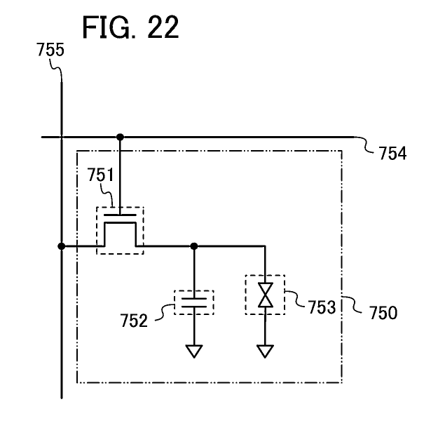

FIG. 22 is a circuit diagram illustrating a structural example of a pixel of a liquid crystal display module. A pixel 750 illustrated in FIG. 22 includes a transistor 751, a capacitor 752, and an element 753 in which a space between a pair of electrodes is filled with a liquid crystal (hereinafter also referred to as a liquid crystal element).

One of a source and a drain of the transistor 751 is electrically connected to a signal line 755, and a gate of the transistor 751 is electrically connected to a scan line 754.

One electrode of the capacitor 752 is electrically connected to the other of the source and the drain of the transistor 751, and the other electrode of the capacitor 752 is electrically connected to a wiring supplied with a common potential.

One electrode of the liquid crystal element 753 is electrically connected to the other of the source and the drain of the transistor 751, and the other electrode of the liquid crystal element 753 is electrically connected to the wiring supplied with the common potential. Note that the common potential supplied to the wiring electrically connected to the other electrode of the capacitor 752 and the common potential supplied to the other electrode of the liquid crystal element 753 may be different potentials.

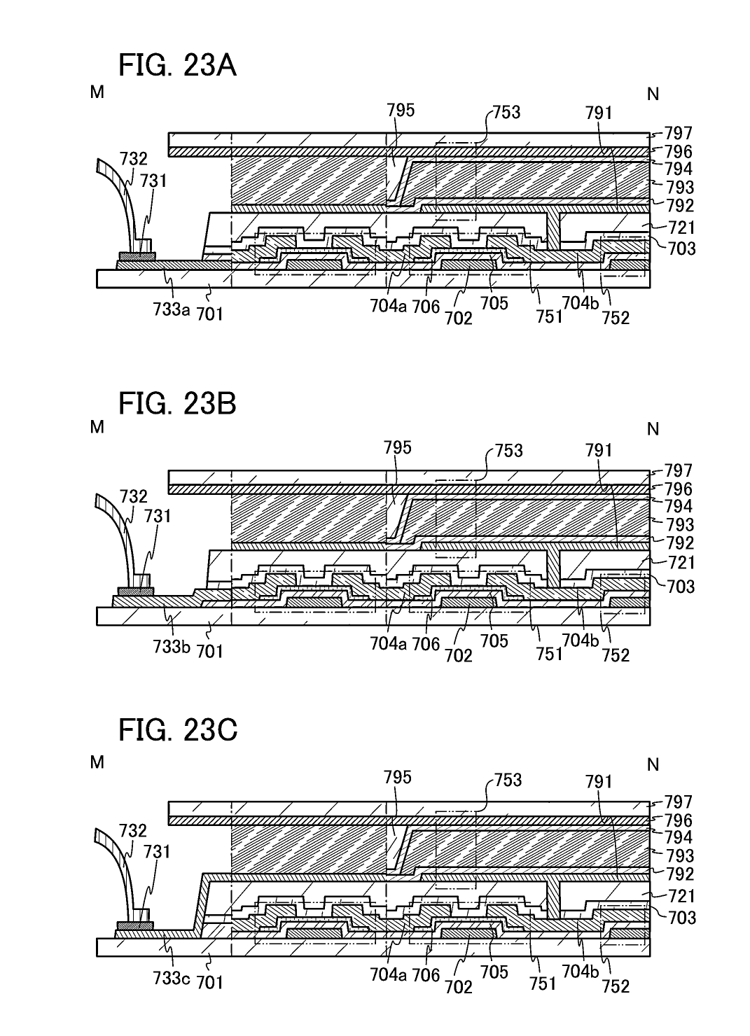

Note that a top view of the liquid crystal display module is substantially similar to that of the display module including the EL element. A cross-sectional view of the liquid crystal display module, which is taken along the long dashed short dashed line M-N in FIG. 20A, is shown in FIG. 23A. In FIG. 23A, an FPC 732 is electrically connected to a wiring 733a through a terminal 731. Note that the wiring 733a is formed using the same layer as a gate electrode 702.

FIG. 23A illustrates an example in which the transistor 751 and the capacitor 752 are provided on the same plane. In such a structure, the capacitor 752 can be manufactured on the same plane as the gate electrode, a gate insulating film, and a source electrode (drain electrode) of the transistor 751. When the transistor 751 and the capacitor 752 are provided on the same plane in this manner, the process for manufacturing the display module can be shortened and the productivity can be improved.

As the transistor 751, the transistor described in the above embodiment can be used. FIG. 23A illustrates an example in which a transistor having the bottom-gate structure among the transistors described in the fifth embodiment is used. That is, the gate electrode 702 is provided over a substrate 701, and an oxide film 706 is provided over the gate electrode 702 with a gate insulating film 705 provided therebetween. The above embodiment can be referred to for the details of the transistor 751.

Note that the transistor 751 can have extremely low off-state current. Therefore, a charge held by the capacitor 752 does not leak easily, and a voltage applied to the liquid crystal element 753 can be maintained for a long time. Thus, by turning off the transistor 751 when a moving image with little motion or a still image is displayed, an electrode for operating the transistor 751 becomes unnecessary, and the display module can have low power consumption.

An insulating film 721 is provided over the transistor 751 and the capacitor 752.

An opening reaching a source electrode 704a of the transistor 751 is provided in the insulating film 721 and a protective insulating film 703.

An electrode 791 is provided over the insulating film 721. The electrode 791 is in contact with a drain electrode 704b of the transistor 751 through the opening provided in the insulating film 721 and the protective insulating film 703.

An insulating film 792 functioning as an alignment film is provided over the electrode 791.

A liquid crystal layer 793 is provided over the insulating film 792, and an insulating film 794 functioning as an alignment film is provided over the liquid crystal layer 793.

A spacer 795 is provided over the insulating film 794.

An electrode 796 is provided over the spacer 795 and the insulating film 794, and a substrate 797 is provided over the electrode 796.

Note that the insulating film 721 may be formed as a single layer or a stacked layer using one or more insulating films containing any of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide. A resin film of a polyimide resin, an acrylic resin, an epoxy resin, a silicone resin, or the like can also be used.

For the liquid crystal layer 793, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used.

Such a liquid crystal exhibits a cholesteric phase, a smectic phase, a cubic phase, a chiral nematic phase, an isotropic phase, or the like depending on conditions.

Note that a liquid crystal exhibiting a blue phase may be used for the liquid crystal layer 793. In that case, the insulating film 792 and the insulating film 794 which serve as alignment films can be omitted from the structure. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which several weight percent or more of a chiral material is mixed is used for the liquid crystal layer in order to improve the temperature range. The liquid crystal composition which includes a liquid crystal exhibiting a blue phase and a chiral material has a short response time of 1 msec or less, and has optical isotropy, which contributes to the exclusion of the alignment process and reduction of viewing angle dependence. In addition, since an alignment film does not need to be provided and rubbing treatment is unnecessary, electrostatic discharge damage caused by the rubbing treatment can be prevented and defects and damage of a display panel in the manufacturing process can be reduced. Thus, the display panel can be provided with high productivity. Thus, the liquid crystal display module can be provided with high productivity. A transistor manufactured using an oxide film has a possibility that the electrical characteristics of the transistor may fluctuate significantly by the influence of static electricity and may deviate from the designed range. Therefore, it is more effective to use a liquid crystal composition exhibiting a blue phase for the liquid crystal display module including the transistor manufactured using an oxide.

The resistivity of the liquid crystal material is higher than or equal to 1×10⁹ Ω·cm, preferably higher than or equal to 1×10¹¹ Ω·cm, further preferably higher than or equal to 1×10¹² Ω·cm. Note that the resistivity in this specification is measured at 20° C.

The size of a storage capacitor formed in the liquid crystal display module is set considering the leakage current of the transistor provided in a pixel portion or the like so that charge can be held for a predetermined period. The size of the storage capacitor may be set considering the off-state current of the transistor or the like. When a transistor including the oxide film disclosed in this specification is used, it is sufficient to provide a storage capacitor having a capacitance that is ⅓ or less, preferably ⅕ or less, of liquid crystal capacitance of each pixel.

In the transistor manufactured using the oxide film disclosed in this specification, the current in an off state (off-state current) can be controlled to be small. Accordingly, an electric signal such as an image signal can be held for a longer period, and a writing interval can be set longer in an on state. Accordingly, the frequency of refresh operation can be reduced, which is effective in suppressing power consumption.

The transistor manufactured using the oxide film disclosed in this specification can have relatively high field-effect mobility and thus can operate at high speed. For example, when such a transistor which can operate at high speed is used for a liquid crystal display module, a switching transistor in a pixel portion and a driver transistor in a driver circuit portion can be formed over one substrate. That is, since a semiconductor device formed using a silicon wafer or the like is not additionally needed as a driver circuit, the number of components of the semiconductor device can be reduced. In addition, by using a transistor which can operate at high speed in a pixel portion, a high-quality image can be provided.

For the liquid crystal display module, a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an anti-ferroelectric liquid crystal (AFLC) mode, or the like can be used.

Alternatively, a normally black liquid crystal display module such as a transmissive liquid crystal display module utilizing a vertical alignment (VA) mode may be used. The vertical alignment mode is a method of controlling alignment of liquid crystal molecules of a liquid crystal display panel, in which liquid crystal molecules are aligned in a vertical direction with respect to a panel surface when no voltage is applied. Some examples of the vertical alignment mode can be given. For example, a multi-domain vertical alignment (MVA) mode, a patterned vertical alignment (PVA) mode, or an advanced super view (ASV) mode can be used. Moreover, it is possible to use a method called domain multiplication or multi-domain design, in which a pixel is divided into some regions (subpixels) and molecules are aligned in different directions in their respective regions.

As the electrode 791, a conductive film having a visible light transmitting property may be used.

As the electrode 791, an oxide film such as an InZn—W oxide film, an In—Sn oxide film, an InZn oxide film, an In oxide film, a Zn oxide film, or a Sn oxide film may be used, for example. A slight amount of Al, Ga, Sb, F, or the like may be added to the oxide film. Further, a metal thin film having a thickness small enough to transmit light (preferably, approximately 5 nm to 30 nm) can also be used.

Alternatively, as the electrode 791, a film capable of efficiently reflecting visible light is preferable. For example, a film containing aluminum, titanium, chromium, copper, molybdenum, silver, tantalum, or tungsten may be used as the electrode 791.

As the electrode 796, a film selected from the films given as examples of the electrode 791 can be used. Note that in the case where the electrode 791 has a visible light transmitting property, the electrode 796 is preferably capable of efficiently reflecting visible light. In the case where the electrode 791 is capable of efficiently reflecting visible light, the electrode 796 preferably has a visible light transmitting property.

Note that the electrode 791 and the electrode 796 provided in the structure illustrated in FIG. 23A may be interchanged.

For the insulating film 792 and the insulating film 794, a material selected from organic compounds or inorganic compounds may be used.

For the spacer 795, a material selected from organic compounds such as an acrylic resin or inorganic compounds such as silica may be used. Note that the spacer 795 can have any of various shapes such as a columnar shape or a spherical shape.

A region where the electrode 791, the insulating film 792, the liquid crystal layer 793, the insulating film 794, and the electrode 796 overlap with each other serves as the liquid crystal element 753.

For the substrate 797, glass, a resin, a metal, or the like may be used. The substrate 797 may have flexibility.

Although not illustrated, a black matrix (a light-blocking layer) and color filters for three colors of RGB (R, G, and B represent red, green, and blue, respectively) can be provided over the substrate 797.

On the sides of the substrate 701 and the substrate 797 which are opposite the sides facing the liquid crystal layer 793, an optical member (an optical substrate) such as a polarizing member, a retardation member, or an anti-reflection member, or the like may be provided as appropriate. For example, circular polarization may be obtained by using a polarizing substrate and a retardation substrate.

As a display method in the pixel portion, a progressive method, an interlace method, or the like can be employed. Further, color components controlled in a pixel at the time of color display are not limited to the three colors of RGB. For example, RGBW (W represents white); RGB and one or more of yellow, cyan, magenta, and the like; or the like can be used. Note that the sizes of display regions may be different between respective dots of color components. Note that this embodiment is not limited to a display panel for color display, and can also be applied to a liquid crystal display module for monochrome display.

FIGS. 23B and 23C are each an example of a cross-sectional view of a liquid crystal display module which is partly different from that in FIG. 23A. Specifically, a wiring connected to the FPC 732 is different. In FIG. 23B, the FPC 732 is connected to a wiring 733b through the terminal 731. The wiring 733b is formed using the same layer as the source electrode 704a and the drain electrode 704b. In FIG. 23C, the FPC 732 is connected to a wiring 733c through the terminal 731. The wiring 733c is formed using the same layer as the electrode 791.

The transistor 751 connected to the liquid crystal element 753 has stable electrical characteristics. Therefore, a display module having high display quality can be provided. In addition, the transistor 751 can have extremely low off-state current; thus, a liquid crystal display module with low power consumption can be provided.

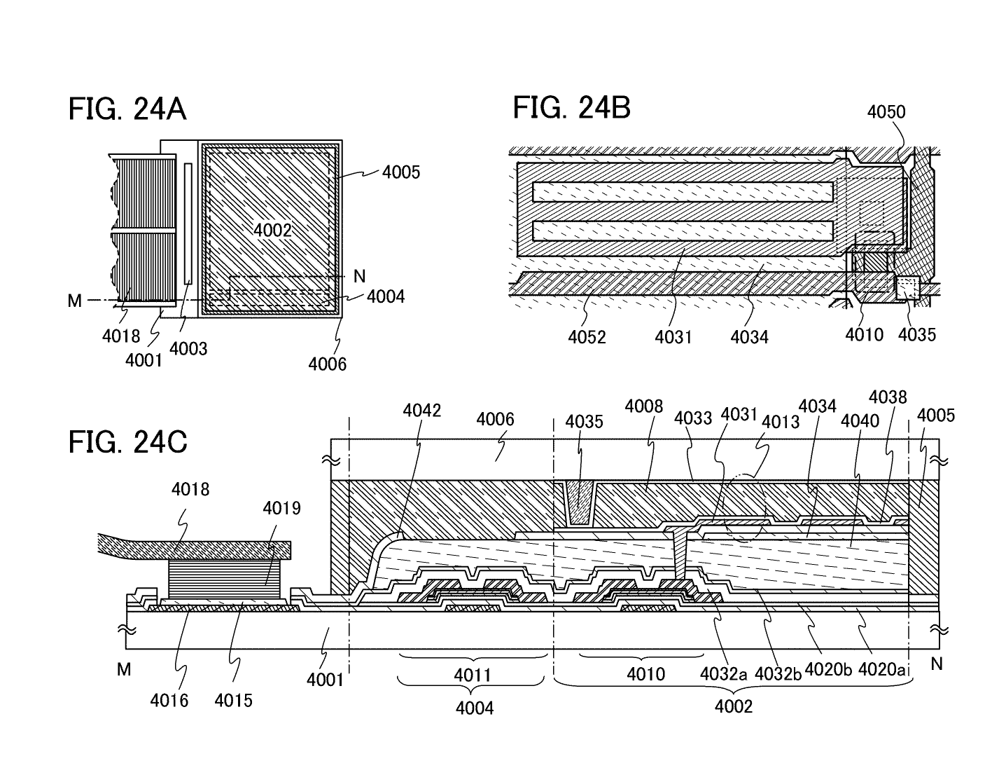

Here, as an example of a display mode of the above-described display module including the liquid crystal element, a display module including a fringe field switching (FFS) mode liquid crystal element will be described with reference to FIGS. 24A to 24C.

FIG. 24A is a plan view of a display module including a liquid crystal element. In FIG. 24A, a sealant 4005 is provided so as to surround a pixel portion 4002 and a scan line driver circuit 4004 which are provided over a substrate 4001. A substrate 4006 is provided over the pixel portion 4002 and the scan line driver circuit 4004. Consequently, the pixel portion 4002 and the scan line driver circuit 4004 are sealed together with a liquid crystal element, by the substrate 4001, the sealant 4005, and the substrate 4006. In FIG. 24A, an IC chip or a signal line driver circuit 4003 which is formed using a single crystal semiconductor film or a polycrystalline semiconductor film over a substrate separately prepared is mounted in a region that is different from the region surrounded by the sealant 4005 over the substrate 4001. Various signals and potentials are supplied to the pixel portion 4002 from a flexible printed circuit (FPC) 4018 through the signal line driver circuit 4003 and the scan line driver circuit 4004.

Although FIG. 24A illustrates an example in which the signal line driver circuit 4003 is formed separately and mounted on the substrate 4001, one embodiment of the present invention is not limited to this structure. The scan line driver circuit may be separately formed and then mounted, or only part of the signal line driver circuit or part of the scan line driver circuit may be separately formed and then mounted.

Note that there is no particular limitation on the method for connecting a separately formed driver circuit, and a chip on glass (COG) method, a wire bonding method, a tape automated bonding (TAB) method, or the like can be used. FIG. 24A illustrates an example in which the signal line driver circuit 4003 is mounted by a COG method.

The pixel portion and the scan line driver circuit which are provided over the substrate include a plurality of transistors; the transistor described in the above embodiment can be applied thereto.

FIG. 24B illustrates an example of a pixel structure of the pixel portion 4002 where the fringe field switching (FFS) mode is employed. FFS is a display mode in which liquid crystal molecules are aligned by a fringe electric field formed by a common electrode (hereinafter referred to as a first electrode) and a pixel electrode (hereinafter referred to as a second electrode) which are parallel and overlap with each other over a substrate. Increases in aperture ratio and viewing angle of a liquid crystal display module can be achieved.

A pixel includes an intersection of a wiring 4050 electrically connected to a gate electrode of a transistor 4010 and a wiring 4052 electrically connected to one of source and drain electrodes of the transistor 4010. The wiring 4050 functions as a gate signal line (scan line) and the wiring 4052 functions as a source signal line. In addition, the pixel includes a first electrode 4034 isolated from other pixels or shared with other pixels and a second electrode 4031 isolated from other pixels and electrically connected to the other of the source and drain electrodes of the transistor 4010. The second electrode 4031 is provided so as to overlap with the first electrode 4034 and provided with a plurality of openings which form slits.

FIG. 24C corresponds to a cross-sectional view taken along the line M-N in FIG. 24A. In the display module including a liquid crystal element, the transistor 4010 provided in the pixel portion 4002 is electrically connected to the liquid crystal element.

As illustrated in FIGS. 24A and 24C, the display module including the liquid crystal element includes a connection terminal electrode 4015 and a terminal electrode 4016. The connection terminal electrode 4015 and the terminal electrode 4016 are electrically connected to a terminal included in the FPC 4018 through an anisotropic conductive layer 4019.

The connection terminal electrode 4015 is formed using the same conductive layer as the first electrode 4034, and the terminal electrode 4016 is formed using the same conductive layer as gate electrodes of the transistor 4010 and a transistor 4011. For the terminal electrode 4016 and the gate electrodes of the transistors 4010 and 4011, a material which can be used for the gate electrode 401 illustrated in FIGS. 11A to 11C can be used, for example.

The pixel portion 4002 and the scan line driver circuit 4004 which are provided over the substrate 4001 include a plurality of transistors. FIG. 24C illustrates the transistor 4010 included in the pixel portion 4002 and the transistor 4011 included in the scan line driver circuit 4004 as an example, and insulating films 4032a and 4032b are provided over the transistors 4010 and 4011. For the insulating films 4032a and 4032b, a material which can be used for the insulating film 406 illustrated in FIGS. 11A to 11C can be used, for example.

In FIG. 24C, a planarization insulating film 4040 is provided over the insulating film 4032b, and an insulating film 4042 is provided between the first electrode 4034 and the second electrode 4031.

For the planarization insulating film 4040, an organic resin such as an acrylic-, polyimide-, or benzocyclobutene-based resin, polyamide, or epoxy can be used. Other than such organic materials, it is also possible to use a low dielectric constant material (low-k material), a siloxane-based resin, or the like.

For the insulating film 4042, a material which can be used for the insulating film 406 illustrated in FIGS. 11A to 11C can be used, for example.

As the transistors 4010 and 4011, the transistor including the oxide film described in the above embodiment can be used. The transistors 4010 and 4011 are transistors having a bottom-gate structure.

A gate insulating film included in the transistors 4010 and 4011 can have a single-layer structure or a stacked-layer structure. In this embodiment, a stacked-layer structure of gate insulating films 4020a and 4020b is provided. In FIG. 24C, the gate insulating film 4020a and the insulating film 4032b extend under the sealant 4005 so as to cover an end portion of the connection terminal electrode 4015, and the insulating film 4032b covers side surfaces of the gate insulating film 4020b and the insulating film 4032a. For the gate insulating films 4020a and 4020b, a material which can be used for the gate insulating film 402 illustrated in FIGS. 11A to 11C can be used, for example.

In addition, a conductive layer may be provided so as to overlap with the oxide film of the transistor 4011 in the driver circuit. By providing the conductive layer so as to overlap with the oxide film, the threshold voltage of the transistor 4011 can be controlled.

In addition, the conductive layer has a function of blocking an external electric field (particularly, blocking static electricity), i.e., preventing an external electric field from affecting the inside (a circuit portion including a transistor). The blocking function of the conductive layer can prevent fluctuation in the electrical characteristics of the transistor due to an influence of an external electric field such as static electricity.

In FIG. 24C, a liquid crystal element 4013 includes the first electrode 4034, the second electrode 4031, and a liquid crystal layer 4008. Note that insulating films 4038 and 4033 functioning as alignment films are provided so that the liquid crystal layer 4008 is interposed therebetween. As the liquid crystal layer 4008, a layer of a material which can be used for the liquid crystal layer 793 illustrated in FIGS. 23A to 23C can be used, for example.

The liquid crystal element 4013 includes the second electrode 4031 having an opening pattern below the liquid crystal layer 4008 and the first electrode 4034 having a plate-like shape below the second electrode 4031 with the insulating film 4042 provided therebetween. The second electrode 4031 having an opening pattern has a shape including a bend portion or a branching comb-like shape. Since the second electrode 4031 has an opening pattern, the first electrode 4034 and the second electrode 4031 can form a fringe electric field therebetween. Note that the second electrode 4031 may have a plate-like shape and may be provided in contact with the planarization insulating film 4040, and the first electrode 4034 may have an opening pattern, may function as a pixel electrode, and may be provided over the second electrode 4031 with the insulating film 4042 provided therebetween.

The first electrode 4034 and the second electrode 4031 can be formed using a light-transmitting conductive material such as indium oxide containing tungsten oxide, indium zinc oxide containing tungsten oxide, indium oxide containing titanium oxide, indium tin oxide containing titanium oxide, indium tin oxide, indium zinc oxide, indium tin oxide to which silicon oxide is added, or graphene.

The first electrode 4034 and the second electrode 4031 can be formed using one or plural kinds selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag), alloys thereof, and nitrides thereof.

A conductive composition containing a conductive high molecule (also referred to as conductive polymer) can be used for the first electrode 4034 and the second electrode 4031.

A spacer 4035 is a columnar spacer obtained by selective etching of an insulating film and is provided in order to control the thickness (cell gap) of the liquid crystal layer 4008. Alternatively, a spherical spacer may be used.

Alternatively, a liquid crystal composition exhibiting a blue phase for which an alignment film is unnecessary may be used for the liquid crystal layer 4008. In this case, the liquid crystal layer 4008 is in contact with the first electrode 4034 and the second electrode 4031.

Note that the insulating film 4042 illustrated in FIG. 24C partly has an opening, through which moisture contained in the planarization insulating film 4040 can be released. Note that the opening is not necessarily provided depending on the film quality of the insulating film 4042 provided over the planarization insulating film 4040.

The size of a storage capacitor formed in the display module including the liquid crystal element is set considering the leakage current of the transistor provided in the pixel portion or the like so that charge can be held for a predetermined period. The size of the storage capacitor may be set considering the off-state current of the transistor or the like. By using the transistor including the oxide film described in the above embodiment, the size of the storage capacitor can be reduced. Accordingly, the aperture ratio of each pixel can be increased.

As illustrated in FIGS. 24B and 24C, a structure may be employed in which no capacitor is provided as a storage capacitor in a pixel, and parasitic capacitance generated between the first electrode 4034 and the second electrode 4031 may be used as a storage capacitor. When a capacitor is not provided in this manner, the aperture ratio of the pixel can be further increased.

In the transistor manufactured using the oxide film described in the above embodiment, the current in an off state (off-state current) can be controlled to be small. Accordingly, an electric signal such as an image signal can be held for a longer period, and a writing interval can be set longer. Accordingly, the frequency of refresh operation can be reduced, which is effective in suppressing power consumption.

The transistor manufactured using the oxide film described in the above embodiment can have high field-effect mobility and thus can operate at high speed. For example, when such a transistor is used for a display module including a liquid crystal element, a switching transistor in a pixel portion and a transistor in a driver circuit portion can be formed over one substrate. In addition, by using such a transistor in a pixel portion, a high-quality image can be provided.

In the display module including the liquid crystal element, a black matrix (light-blocking layer), an optical member (optical substrate) such as a polarizing member, a retardation member, or an anti-reflection member, and the like are provided as appropriate. For example, circular polarization may be obtained by using a polarizing plate and a retardation plate. In addition, a backlight, a side light, or the like may be used as a light source.

In addition, a touch sensor may be provided over the pixel portion 4002. When a touch sensor is provided, intuitive operation is possible.

### [6.1.3. Display Module Including Electrophoretic Element]

Further, electronic paper in which electronic ink is driven can be provided as a display module. The electronic paper is also referred to as an electrophoretic display device (electrophoretic display) and is advantageous in that it has the same level of readability as plain paper, it has lower power consumption than other display modules, and it can be made thin and lightweight.

The display module including an electrophoretic element can have various modes; for example, the display module including an electrophoretic element contains a plurality of microcapsules dispersed in a solvent or a solute, each microcapsule containing first particles which are positively charged and second particles which are negatively charged. By applying an electric field to the microcapsules, the particles in the microcapsules move in opposite directions to each other and only the color of the particles gathering on one side is displayed. Note that the first particles or the second particles contain a pigment and do not move without an electric field. Moreover, the first particles and the second particles have different colors (which may be colorless).

Thus, the display module including an electrophoretic element is a display that utilizes a so-called dielectrophoretic effect by which a substance having a high dielectric constant moves to a high electric field region.

A solution in which the above microcapsules are dispersed in a solvent is referred to as electronic ink. This electronic ink can be printed on a surface of glass, plastic, cloth, paper, or the like. Furthermore, by using a color filter or particles that have a pigment, color display can also be achieved.

Note that the first particles and the second particles in the microcapsules may each be formed of a single material selected from a conductive material, an insulating material, a semiconductor material, a magnetic material, a liquid crystal material, a ferroelectric material, an electroluminescent material, an electrochromic material, and a magnetophoretic material, or formed of a composite material of any of these materials.

As the electronic paper, a display module using a twisting ball display method can be used. The twisting ball display method refers to a method in which spherical particles each colored in black and white are arranged between a first electrode layer and a second electrode layer which are electrode layers used for a display element, and a potential difference is generated between the first electrode layer and the second electrode layer to control the orientation of the spherical particles, so that display is performed.

In order to drive such an electrophoretic element described above, an electric field applied to the electrophoretic element can be controlled with a transistor manufactured using an oxide film. The driving method is similar to that used for the display module including a liquid crystal element.

### [6.2. Sensor]

### [6.2.1. Image Sensor]

An image sensor capable of reading information on an object can be manufactured using the transistor described in the above embodiment.

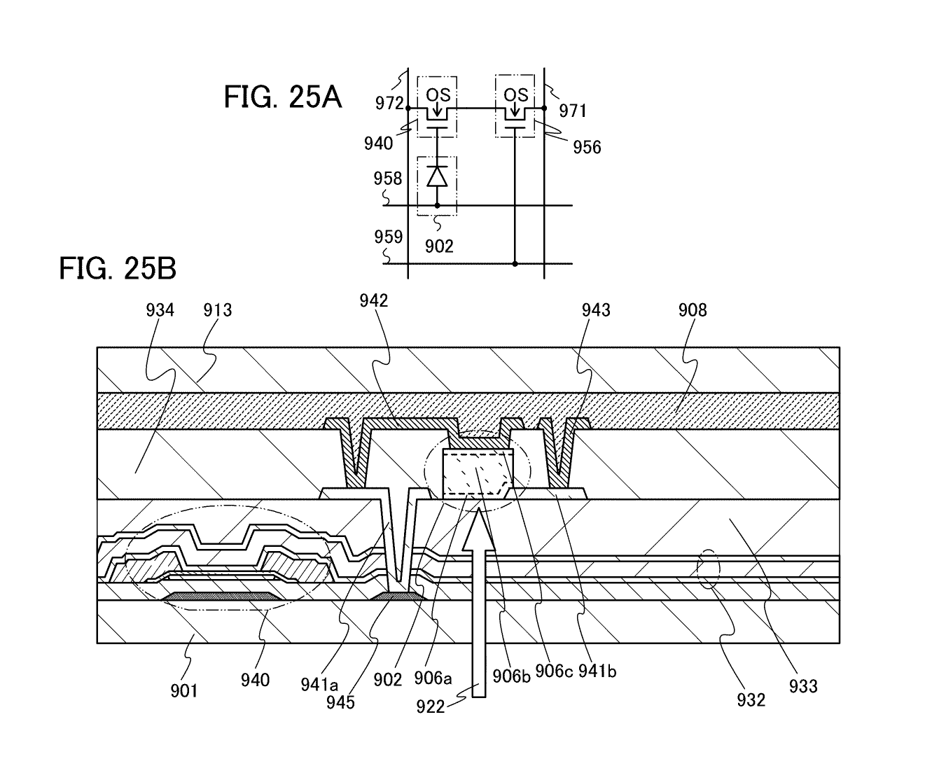

FIG. 25A illustrates an example of an image sensor. FIG. 25A is an equivalent circuit diagram of a photosensor, and FIG. 25B is a cross-sectional view illustrating part of the photosensor.

One electrode of a photodiode 902 is electrically connected to a photodiode reset signal line 958, and the other electrode of the photodiode 902 is electrically connected to a gate of a transistor 940. One of a source and a drain of the transistor 940 is electrically connected to a photosensor reference signal line 972, and the other of the source and the drain of the transistor 940 is electrically connected to one of a source and a drain of a transistor 956. A gate of the transistor 956 is electrically connected to a gate signal line 959, and the other of the source and the drain of the transistor 956 is electrically connected to a photosensor output signal line 971.

Note that in circuit diagrams in this specification, a transistor formed using an oxide semiconductor film is denoted by a symbol “OS” so that it can be identified as a transistor formed using an oxide semiconductor film. In FIG. 25A, the transistor 940 and the transistor 956 are each a transistor including an oxide semiconductor film, to which the transistor described in the fifth embodiment can be applied. In this embodiment, an example is described in which the transistor having the bottom-gate structure among the transistors described in the fifth embodiment is used.

FIG. 25B is a cross-sectional view of the photodiode 902 and the transistor 940 in the photosensor. The photodiode 902 functioning as a sensor and the transistor 940 are provided over a substrate 901 (element substrate) having an insulating surface. A substrate 913 is provided over the photodiode 902 and the transistor 940 with the use of an adhesive layer 908.

An insulating film 932, a planarization film 933, and a planarization film 934 are provided over the transistor 940. The photodiode 902 includes an electrode 941b formed over the planarization film 933, a first semiconductor film 906a, a second semiconductor film 906b, and a third semiconductor film 906c stacked over the electrode 941b in this order, an electrode 942 which is provided over the planarization film 934 and electrically connected to the electrode 941b through the first to third semiconductor films, and an electrode 941a which is formed using the same layer as the electrode 941b and electrically connected to the electrode 942.

The electrode 941b is electrically connected to a conductive film 943 formed over the planarization film 934, and the electrode 942 is electrically connected to a conductive film 945 through the electrode 941a. The conductive film 945 is electrically connected to a gate electrode of the transistor 940, and the photodiode 902 is electrically connected to the transistor 940.

Here, a pin photodiode in which a semiconductor film having p-type conductivity as the first semiconductor film 906a, a high-resistance semiconductor film (i-type semiconductor film) as the second semiconductor film 906b, and a semiconductor film having n-type conductivity as the third semiconductor film 906c are stacked is illustrated as an example.

The first semiconductor film 906a is a p-type semiconductor film and can be formed using an amorphous silicon film containing an impurity element imparting p-type conductivity. The first semiconductor film 906a is formed by a plasma CVD method with the use of a semiconductor source gas containing an impurity element belonging to Group 13 (e.g., boron (B)). As the semiconductor source gas, silane (SiH₄) may be used. Alternatively, Si₂H₆, SiH₂Cl₂, SiHCl₃, SiCl₄, SiF₄, or the like may be used. Further alternatively, an amorphous silicon film which does not contain an impurity element may be formed, and then an impurity element may be introduced to the amorphous silicon film by a diffusion method or an ion implantation method. Heating or the like may be conducted after introducing the impurity element by an ion implantation method or the like, in order to diffuse the impurity element. In this case, as a method of forming the amorphous silicon film, an LPCVD method, a vapor deposition method, a sputtering method, or the like may be used. The first semiconductor film 906a is preferably formed to have a thickness greater than or equal to 10 nm and less than or equal to 50 nm.

The second semiconductor film 906b is an i-type semiconductor film (intrinsic semiconductor film) and is formed using an amorphous silicon film. As for formation of the second semiconductor film 906b, an amorphous silicon film is formed by a plasma CVD method with the use of a semiconductor source gas. As the semiconductor source gas, silane (SiH₄) may be used. Alternatively, Si₂H₆, SiH₂Cl₂, SiHCl₃, SiCl₄, SiF₄, or the like may be used. The second semiconductor film 906b may be formed by an LPCVD method, a vapor deposition method, a sputtering method, or the like. The second semiconductor film 906b is preferably formed to have a thickness greater than or equal to 200 nm and less than or equal to 1000 nm.

The third semiconductor film 906c is an n-type semiconductor film and is formed using an amorphous silicon film containing an impurity element imparting n-type conductivity. The third semiconductor film 906c is formed by a plasma CVD method with the use of a semiconductor source gas containing an impurity element belonging to Group 15 (e.g., phosphorus (P)). As the semiconductor source gas, silane (SiH₄) may be used. Alternatively, Si₂H₆, SiH₂Cl₂, SiHCl₃, SiCl₄, SiF₄, or the like may be used. Further alternatively, an amorphous silicon film which does not contain an impurity element may be formed, and then an impurity element may be introduced to the amorphous silicon film by a diffusion method or an ion implantation method. Heating or the like may be conducted after introducing the impurity element by an ion implantation method or the like, in order to diffuse the impurity element. In this case, as a method of forming the amorphous silicon film, an LPCVD method, a vapor deposition method, a sputtering method, or the like may be used. The third semiconductor film 906c is preferably formed to have a thickness greater than or equal to 20 nm and less than or equal to 200 nm.

The first semiconductor film 906a, the second semiconductor film 906b, and the third semiconductor film 906c are not necessarily formed using an amorphous semiconductor, and may be formed using a polycrystalline semiconductor or a microcrystalline semiconductor (semi-amorphous semiconductor: SAS).

The mobility of holes generated by the photoelectric effect is lower than the mobility of electrons. Therefore, a pin photodiode has favorable characteristics when a surface on the p-type semiconductor film side is used as a light-receiving plane. Here, an example is described in which light 922 received by the photodiode 902 from a surface of the substrate 901 where the pin photodiode is formed is converted into electric signals. Further, light from the side of the semiconductor film having a conductivity type opposite to that of the semiconductor film on the light-receiving plane is disturbance light; therefore, the electrode is preferably formed using a light-blocking conductive film. Note that a surface on the n-type semiconductor film side can alternatively be used as the light-receiving plane.

With the use of an insulating material, the insulating film 932, the planarization film 933, and the planarization film 934 can be formed using a sputtering method, a plasma CVD method, spin coating, dipping, spray coating, a droplet discharge method (an inkjet method), screen printing, offset printing, or the like depending on the material.

For the planarization films 933 and 934, for example, an organic insulating material having heat resistance, such as a polyimide, an acrylic resin, a benzocyclobutene-based resin, a polyamide, or an epoxy resin, can be used. Other than such organic insulating materials, it is possible to use a single layer or stacked layers of a low dielectric constant material (low-k material), a siloxane-based resin, phosphosilicate glass (PSG), borophosphosilicate glass (BPSG), or the like.

By sensing of light that enters the photodiode 902, information on an object to be detected can be read. Note that a light source such as a backlight can be used at the time of reading information on an object to be detected.

### [6.2.2. Touch Panel]

Here, a display module including an EL element, which has a touch input function with a sensor provided in a pixel region, will be described.

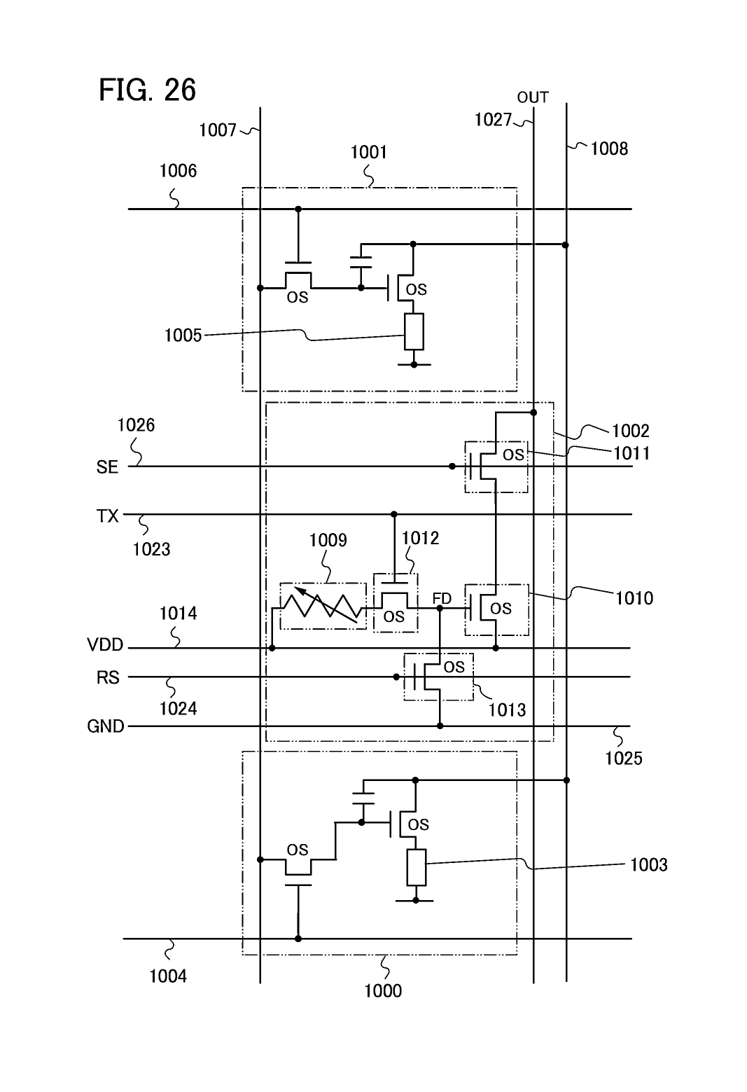

A circuit diagram of a pixel 1000, a photosensor 1002, and an adjacent pixel 1001 is described with reference to FIG. 26. The pixel 1000 including a light-emitting element 1003 is electrically connected to a scan line driver circuit through a scan line 1004 and to a signal line driver circuit through a signal line 1007.

The adjacent pixel 1001 including an adjacent light-emitting element 1005 is electrically connected to the scan line driver circuit through a scan line 1006 and to the signal line driver circuit through the signal line 1007. Both the light-emitting element 1003 and the adjacent light-emitting element 1005 emit white light and are connected to a common power supply line 1008. By passage through a coloring layer (red, blue, or green) of a color filter overlapping with the adjacent light-emitting element 1005, one of red, blue, and green colors is perceived by human eyes.

The photosensor 1002 provided between the pixel 1000 and the adjacent pixel 1001 includes a sensor element 1009, a transistor 1010, a transistor 1011, a transistor 1012, and a transistor 1013. Each of the transistors 1010, 1011, 1012, and 1013 includes an oxide semiconductor film in a channel formation region and has the advantage of significantly low leakage current in an off state (also referred to as “off-state current”). Accordingly, there is an advantage that a charge (potential) accumulated at a node can be held for a long time in the off state.

One terminal of the sensor element 1009 is electrically connected to a power supply line 1014 (VDD), and the other terminal of the sensor element 1009 is electrically connected to one of a source and a drain of the transistor 1012.

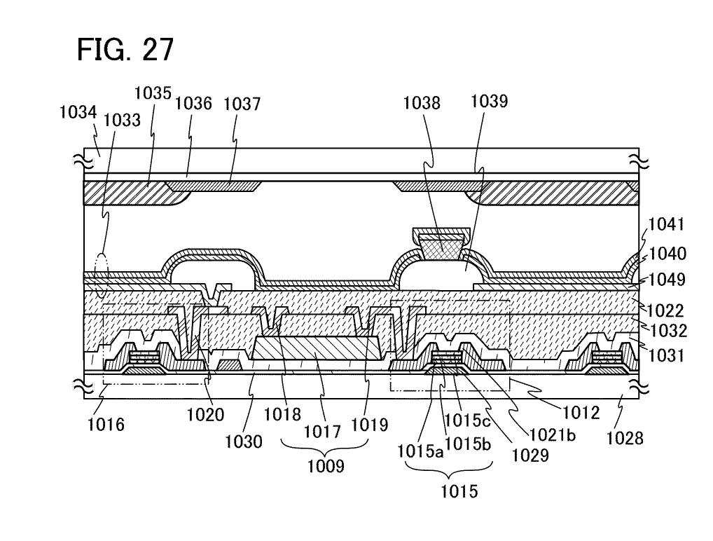

FIG. 27 is an example of a cross-sectional view of a panel provided with the photosensor. As illustrated in FIG. 27, a light-emitting element 1033, a transistor 1016 manufactured using a multilayer film 1015 for driving the light-emitting element, the transistor 1012 manufactured using the multilayer film 1015 for driving the sensor element 1009, and the sensor element 1009 manufactured using an amorphous silicon layer 1017 are provided over the same substrate 1028. The transistor 1012 and the transistor 1016 each include a gate electrode 1029 over the substrate 1028, a gate insulating film 1030 over the gate electrode 1029, and the multilayer film 1015 over the gate insulating film 1030. For example, the multilayer film 1015 has, but is not limited to, a three-layer structure of oxides 1015a, 1015b, and 1015c. These transistors are covered with an insulating film 1031 and an insulating film 1032.

The sensor element 1009 includes the amorphous silicon layer 1017 in contact with and connected to a pair of electrodes 1018 and 1019, as illustrated in FIG. 27.

In FIG. 27, an electrode 1049 is a reflective electrode and is electrically connected to a drain electrode 1021b of the transistor 1016 through a wiring 1020. The wiring 1020 and the pair of electrodes 1018 and 1019 are covered with an interlayer insulating film 1022, and the electrode 1049 is provided over the interlayer insulating film 1022.

The light-emitting element 1033 electrically connected to the transistor 1016, and a first partition 1039 and a second partition 1038 which isolate the light-emitting element 1033 are provided. Further, a sealing substrate 1034 is fixed to the substrate 1028 with a sealant or the like. The sealing substrate 1034 is provided with a base layer 1036, a black matrix 1037, a red color filter (not shown), a green color filter (not shown), and a blue color filter 1035. The light-emitting element 1033 includes the electrode 1049 functioning as an anode, a light-emitting layer 1040, and a cathode 1041.

A gate of the transistor 1012 is electrically connected to a signal line 1023 (TX); the one of the source and the drain of the transistor 1012 is electrically connected to the other terminal of the sensor element 1009; and the other of the source and the drain of the transistor 1012 is electrically connected to one of a source and a drain of the transistor 1013 and a gate of the transistor 1010. Note that the other of the source and the drain of the transistor 1012, the one of the source and the drain of the transistor 1013, and the gate of the transistor 1010 are a node FD.

A gate of the transistor 1013 is electrically connected to a reset line 1024 (RS), and the one of the source and the drain of the transistor 1013 is electrically connected to the other of the source and the drain of the transistor 1012 and the gate of the transistor 1010. The other of the source and the drain of the transistor 1013 is electrically connected to a ground line 1025 (GND).

One of a source and a drain of the transistor 1010 is electrically connected to the power supply line 1014 (VDD), and the other of the source and the drain of the transistor 1010 is electrically connected to one of a source and a drain of the transistor 1011.

A gate of the transistor 1011 is electrically connected to a selection line 1026 (SE), and the other of the source and the drain of the transistor 1011 is electrically connected to a photosensor output signal line 1027 (OUT). The photosensor output signal line 1027 (OUT) is electrically connected to a photosensor reading circuit.

Note that a high-level power supply potential (VDD) and a ground potential (GND (0 V)) as a low-level power supply potential (VSS) are input to the power supply line 1014 (VDD) and the ground line 1025 (GND), respectively. Although the ground potential (GND (0 V)) is used as the low-level power supply potential (VSS) here, the low-level power supply potential (VSS) is not limited thereto. Any potential that is lower than the high-level power supply potential (VDD) can be used as the low-level power supply potential (VSS). Note that the high-level power supply potential (VDD) is higher than or equal to a high-level potential VH; a low-level potential VL is higher than or equal to the ground potential (GND); and the high-level potential VH is higher than the low-level potential VL.

In this embodiment, the panel itself has a touch input function. However, in the case of using an analog resistive touch panel, the touch panel may be attached to the panel. Similarly, in the case of using a surface capacitive touch panel, the touch panel may be attached to the panel. Furthermore, in the case of using a projected capacitive (mutual capacitive) touch panel, the touch panel may be attached to the panel.

In this embodiment, an example of a touch input function with a photosensor is described. Since the photosensor can be formed over the same substrate as transistors, the number of components can be reduced.

In addition, in this embodiment, an example of the display module including an EL element and having a touch input function is described; a display module including a liquid crystal element can also have a touch input function.

### [6.3. LSI]

The display modules and the sensors have been described as applications of the transistor manufactured using the oxide film in one embodiment of the present invention. The transistor can also be applied to LSIs, e.g., arithmetic processing units such as a central processing unit (CPU) and a digital signal processor (DSP), and a memory. As typical examples of LSIs, examples of a memory, a CPU, and a microcomputer will be described below.

### [6.3.1. Memory]

Here, a static random access memory (SRAM), a memory including a flip-flop to which a circuit of an inverter is applied, will be described.

### [6.3.1.1. Circuit Configuration and Operation]

An SRAM retains data by using a flip-flop. Thus, unlike a dynamic random access memory (DRAM), an SRAM does not require refresh operation. Therefore, power consumption at the time of data retention can be reduced. In addition, an SRAM does not require a capacitor and is therefore suitable for applications where high speed operation is required.

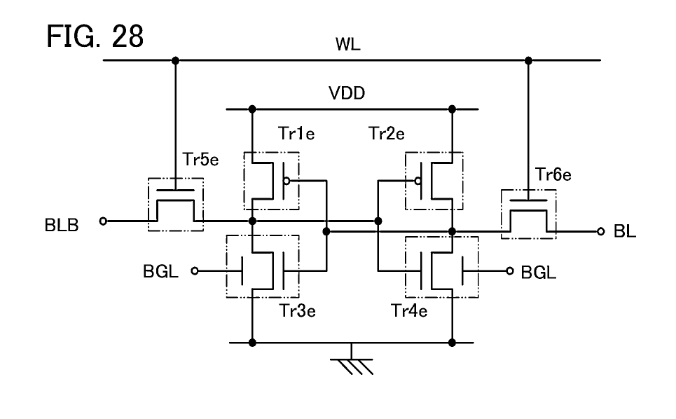

FIG. 28 is a circuit diagram corresponding to a memory cell of an SRAM in one embodiment of the present invention. Note that FIG. 28 illustrates only one memory cell; the present invention can also be applied to a memory cell array in which a plurality of such memory cells are arranged.

The memory cell illustrated in FIG. 28 includes a transistor Tr1e, a transistor Tr2e, a transistor Tr3e, a transistor Tr4e, a transistor Tr5e, and a transistor Tr6e. The transistors Tr1e and Tr2e are p-channel transistors. The transistors Tr3e and Tr4e are n-channel transistors. A gate of the transistor Tr1e is electrically connected to a drain of the transistor Tr2e, a gate of the transistor Tr3e, a drain of the transistor Tr4e, and one of a source and a drain of the transistor Tr6e. A source of the transistor Tr1e is electrically connected to VDD. A drain of the transistor Tr1e is electrically connected to a gate of the transistor Tr2e, a drain of the transistor Tr3e, and one of a source and a drain of the transistor Tr5e. A source of the transistor Tr2e is electrically connected to VDD. A source of the transistor Tr3e is electrically connected to GND. A back gate of the transistor Tr3e is electrically connected to a back gate line BGL. A source of the transistor Tr4e is electrically connected to GND. A back gate of the transistor Tr4e is electrically connected to the back gate line BGL. A gate of the transistor Tr5e is electrically connected to a word line WL. The other of the source and the drain of the transistor Tr5e is electrically connected to a bit line BLB. A gate of the transistor Tr6e is electrically connected to the word line WL. The other of the source and the drain of the transistor Tr6e is electrically connected to a bit line BL.

Note that this embodiment shows an example where n-channel transistors are used as the transistors Tr5e and Tr6e. However, the transistors Tr5e and Tr6e are not limited to n-channel transistors and may be p-channel transistors. In that case, writing, retaining, and reading methods described below may be changed as appropriate.

A flip-flop is thus configured in such a manner that an inverter including the transistors Tr1e and Tr3e and an inverter including the transistors Tr2e and Tr4e are connected in a ring.

The p-channel transistors may be, but are not limited to, transistors using silicon for example. The n-channel transistors may each be the transistor including an oxide semiconductor film described in the above embodiment.

In this embodiment, the transistors Tr3e and Tr4e may each be the transistor including an oxide film described in the above embodiment. In addition, with an extremely low off-state current, the transistor has an extremely low flow-through current.

Note that instead of the p-channel transistors, n-channel transistors may be applied to the transistors Tr1e and Tr2e. In the case where n-channel transistors are used as the transistors Tr1e and Tr2e, depletion transistors may be employed.

Writing, retaining, and reading operation of the memory cell illustrated in FIG. 28 will be described below.

In writing, first, a potential corresponding to data 0 or data 1 is applied to the bit line BL and the bit line BLB.

For example, in the case where data 1 is to be written, the VDD is applied to the bit line BL and the GND is applied to the bit line BLB. Then, a potential (VH) higher than or equal to the sum of the VDD and the threshold voltage of the transistors Tr5e and Tr6e is applied to the word line WL.

Next, the potential of the word line WL is set to be lower than the threshold voltage of the transistors Tr5e and Tr6e, whereby the data 1 written to the flip-flop is retained. In the case of the SRAM, a current flowing in retaining data is only the leakage current of the transistors. Here, any of the transistors including an oxide film described in the above embodiment, which has an extremely low off-state current, is applied to some of the transistors in the SRAM, resulting in a reduction in stand-by power for retaining data because leakage current due to the transistor is extremely low.

In reading, the VDD is applied to the bit line BL and the bit line BLB in advance. Then, the VH is applied to the word line WL, so that the bit line BLB is discharged through the transistors Tr5e and Tr3e to be equal to the GND while the potential of the bit line BL is kept at VDD. The potential difference between the bit line BL and the bit line BLB is amplified by a sense amplifier (not illustrated), whereby the retained data 1 can be read.

In the case where data 0 is to be written, the GND is applied to the bit line BL and the VDD is applied to the bit line BLB; then, the VH is applied to the word line WL. Next, the potential of the word line WL is set to be lower than the threshold voltage of the transistors Tr5e and Tr6e, whereby the data 0 written to the flip-flop is retained. In reading, the VDD is applied to the bit line BL and the bit line BLB in advance. Then, the VH is applied to the word line WL, so that the bit line BL is discharged through the transistors Tr6e and Tr4e to be equal to the GND while the potential of the bit line BLB is kept at VDD. The potential difference between the bit line BL and the bit line BLB is amplified by the sense amplifier, whereby the retained data 0 can be read.

In the above-described manner, an SRAM with low stand-by power can be provided.

### [6.3.1.2 Stacked-Layer Structure]

The transistor including an oxide film described in the above embodiment can have extremely low off-state current. That is, the transistor has electrical characteristics in which leakage of charge through the transistor is unlikely to occur. A memory which includes a transistor having such electrical characteristics will be described below. The memory includes a memory element which is superior in function to a known memory element.

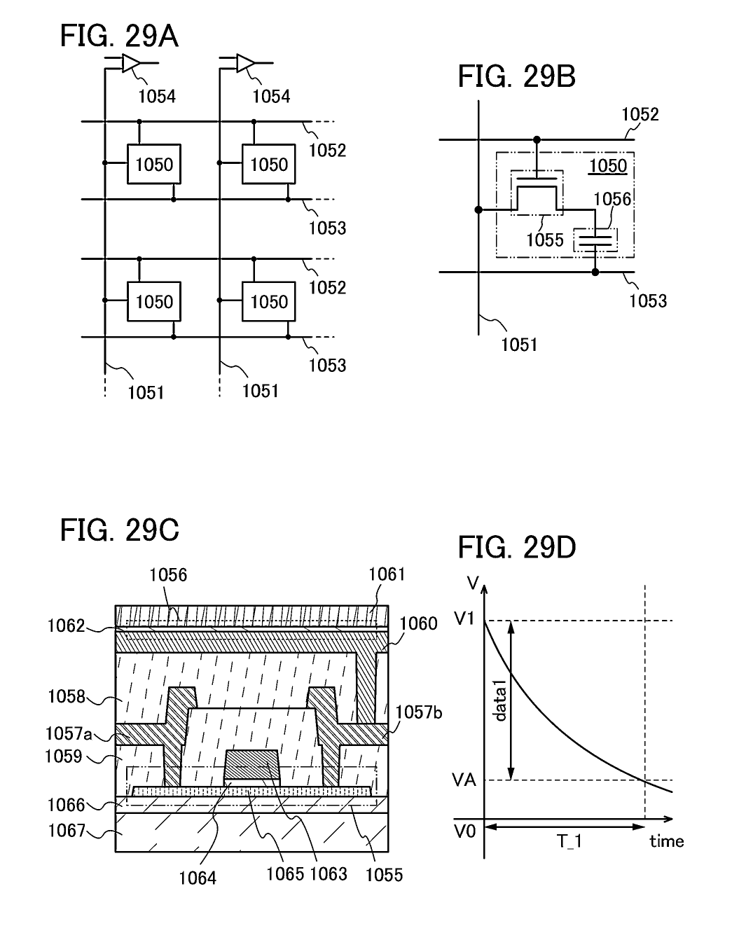

First, the memory will be specifically described with reference to FIGS. 29A to 29D. FIG. 29A is a circuit diagram showing a memory cell array of the memory. FIG. 29B is a circuit diagram of a memory cell. FIG. 29C illustrates an example of a cross-sectional structure corresponding to the memory cell in FIG. 29B. FIG. 29D is a graph showing the electrical characteristics of the memory cell in FIG. 29B.

The memory cell array in FIG. 29A includes a plurality of memory cells 1050, a plurality of bit lines 1051, a plurality of word lines 1052, a plurality of capacitor lines 1053, and a plurality of sense amplifiers 1054.

Note that the bit lines 1051 and the word lines 1052 are provided in a grid pattern, and the memory cell 1050 is provided for each intersection of the bit line 1051 and the word line 1052. The bit lines 1051 are connected to the sense amplifiers 1054, which have a function of reading the potentials of the bit lines 1051 as data.

As shown in FIG. 29B, the memory cell 1050 includes a transistor 1055, which is provided over a substrate 1067 with a base insulating film 1066 therebetween, and a capacitor 1056. A gate of the transistor 1055 is electrically connected to the word line 1052. A source of the transistor 1055 is electrically connected to the bit line 1051. A drain of the transistor 1055 is electrically connected to one terminal of the capacitor 1056. The other terminal of the capacitor 1056 is electrically connected to the capacitor line 1053.

FIG. 29C illustrates an example of a cross-sectional structure of the memory cell. The memory cell includes the transistor 1055, wirings 1057a and 1057b connected to the transistor 1055, an insulating film 1058 over the transistor 1055 and the wirings 1057a and 1057b, and the capacitor 1056 over the insulating film 1058.

Note that in FIG. 29C, a transistor having a top-gate structure is used as the transistor 1055.

The insulating film 1058 and an interlayer insulating film 1059 may each be formed as a single layer or a stacked layer using one or more insulating films containing any of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide. A resin film of a polyimide resin, an acrylic resin, an epoxy resin, a silicone resin, or the like can also be used.

The capacitor 1056 includes an electrode 1060 in contact with the wiring 1057b, an electrode 1061 overlapping with the electrode 1060, and an insulating film 1062 provided between the electrode 1060 and the electrode 1061.

The electrode 1060 may be formed using a single layer or a stacked layer of a simple substance selected from aluminum, titanium, chromium, cobalt, nickel, copper, yttrium, zirconium, molybdenum, silver, tantalum, and tungsten; a nitride containing one or more kinds of the above substances; an oxide containing one or more kinds of the above substances; or an alloy containing one or more kinds of the above substances.

The electrode 1061 may be formed using a single layer or a stacked layer of a simple substance selected from aluminum, titanium, chromium, cobalt, nickel, copper, yttrium, zirconium, molybdenum, silver, tantalum, and tungsten; a nitride containing one or more kinds of the above substances; an oxide containing one or more kinds of the above substances; or an alloy containing one or more kinds of the above substances.

The insulating film 1062 may be formed as a single layer or a stacked layer using one or more insulating films containing any of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

Note that although FIG. 29C shows an example where the transistor 1055 and the capacitor 1056 are provided in different layers, one embodiment of the present invention is not limited to this structure. For example, the transistor 1055 and the capacitor 1056 may be provided in the same plane. With such a structure, memory cells having similar structures can be disposed so as to overlap with each other, in which case a large number of memory cells can be integrated in an area for one memory cell. Accordingly, the degree of integration of the memory can be improved.

Here, the wiring 1057a in FIG. 29C is electrically connected to the bit line 1051 in FIG. 29B. A gate electrode 1063 over an oxide film 1065 with a gate insulating film 1064 therebetween in FIG. 29C is electrically connected to the word line 1052 in FIG. 29B. The electrode 1061 in FIG. 29C is electrically connected to the capacitor line 1053 in FIG. 29B.

As shown in FIG. 29D, a voltage retained in the capacitor 1056 gradually decreases with time due to leakage through the transistor 1055. A voltage originally charged from V0 to V1 is decreased with time to VA that is a limit for reading out data 1. This period is called a retention period T_1. In the case of a two-level memory cell, refresh operation needs to be performed within the retention period T_1.

For example, in the case where the off-state current of the transistor 1055 is not sufficiently small, the retention period T_1 becomes short because the voltage retained in the capacitor 1056 significantly changes with time. Accordingly, refresh operation needs to be frequently performed. An increase in frequency of refresh operation increases power consumption of the memory.

Since the off-state current of the transistor 1055 is extremely small in this embodiment, the retention period T_1 can be made extremely long. In other words, the frequency of refresh operation can be reduced; thus, power consumption can be reduced. For example, in the case where a memory cell is formed using the transistor 1055 having an off-state current of 1×10⁻²¹ A to 1×10⁻²⁵ A, data can be retained for several days to several decades without supply of electric power.

As described above, according to one embodiment of the present invention, a memory with high degree of integration and low power consumption can be provided.

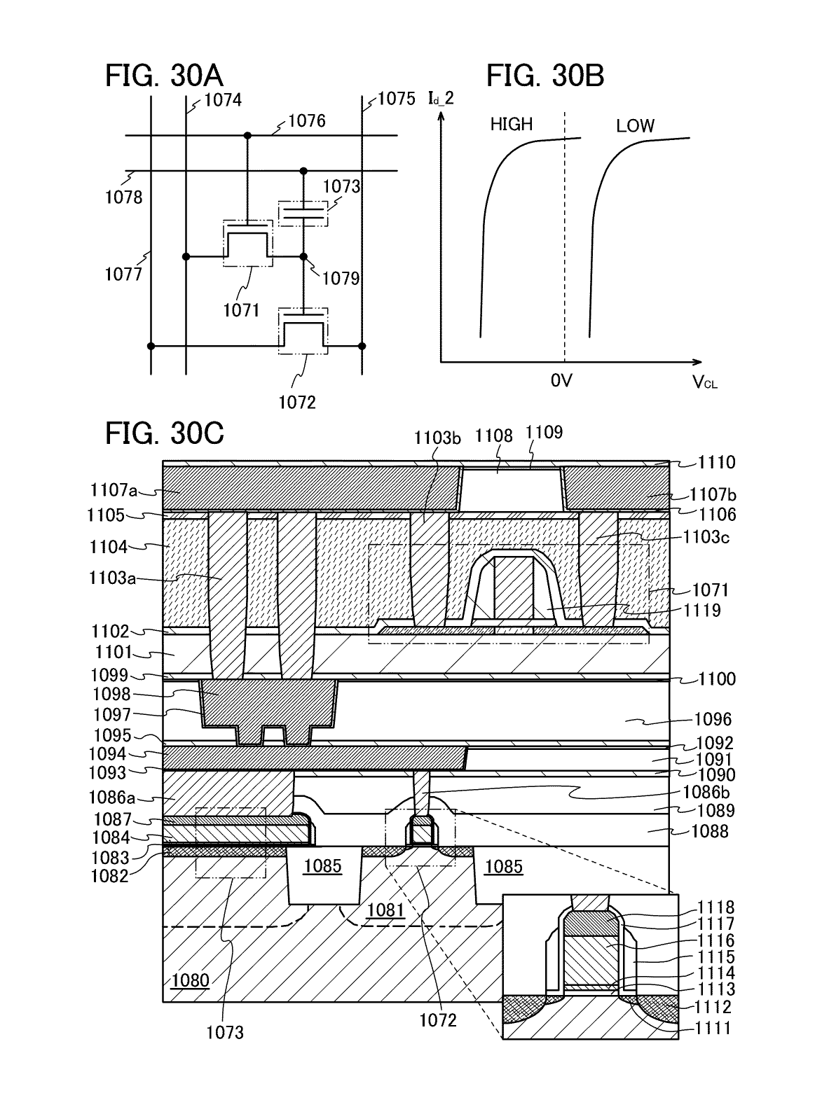

Next, a memory different from that in FIGS. 29A to 29D will be described with reference to FIGS. 30A to 30C. FIG. 30A is a circuit diagram showing a memory cell and wirings included in the memory. FIG. 30B is a graph showing the electrical characteristics of the memory cell in FIG. 30A. FIG. 30C is an example of a cross-sectional view corresponding to the memory cell in FIG. 30A.

As shown in FIG. 30A, the memory cell includes a transistor 1071, a transistor 1072, and a capacitor 1073. Here, a gate of the transistor 1071 is electrically connected to a word line 1076. A source of the transistor 1071 is electrically connected to a source line 1074. A drain of the transistor 1071 is electrically connected to a gate of the transistor 1072 and one terminal of the capacitor 1073, and this portion is referred to as a node 1079. A source of the transistor 1072 is electrically connected to a source line 1075. A drain of the transistor 1072 is electrically connected to a drain line 1077. The other terminal of the capacitor 1073 is electrically connected to a capacitor line 1078.

The memory illustrated in FIGS. 30A to 30C utilizes variation in the apparent threshold voltage of the transistor 1072, which depends on the potential of the node 1079. For example, FIG. 30B shows a relation between a voltage V_{CL} of the capacitor line 1078 and a drain current I_{d}_{_{—}}2 flowing through the transistor 1072.

Note that the potential of the node 1079 can be controlled through the transistor 1071. For example, the potential of the source line 1074 is set to a power supply potential VDD. In this case, when the potential of the word line 1076 is set to be higher than or equal to the sum of the power supply potential VDD and the threshold voltage Vth of the transistor 1071, the potential of the node 1079 can be HIGH. Further, when the potential of the word line 1076 is set to be lower than or equal to the threshold voltage Vth of the transistor 1071, the potential of the node 1079 can be LOW.

Thus, the transistor 1072 has electrical characteristics shown with either a V_{CL}-I_{d}_{_{—}}2 curve denoted as LOW or a V_{CL}-I_{d}_{_{—}}2 curve denoted as HIGH. That is, when the potential of the node 1079 is LOW, I_{d}_{_{—}}2 is small at a V_{CL} of 0 V; accordingly, data 0 is stored. Further, when the potential of the node 1079 is HIGH, I_{d}_{_{—}}2 is large at a V_{CL} of 0 V; accordingly, data 1 is stored. In this manner, data can be stored.

FIG. 30C illustrates an example of a cross-sectional structure of the memory cell.

FIG. 30C is a cross-sectional view of the memory cell including the transistor 1072, the transistor 1071 provided over the transistor 1072 with insulating films or the like provided therebetween, and the capacitor 1073.

In this embodiment, a semiconductor device is described which has a structure where a semiconductor material is used for the transistor 1072 in a lower portion, the oxide film in one embodiment of the present invention is used for the transistor 1071 in an upper portion, and a semiconductor substrate is used as the semiconductor material.

FIG. 30C illustrates one example of a cross-sectional structure of the semiconductor device in which a transistor including a semiconductor material is provided in a lower portion and a transistor including the oxide film in one embodiment of the present invention is provided in an upper portion. Here, different materials are used as the semiconductor material and the oxide film in one embodiment of the present invention. For example, the semiconductor material can be a semiconductor material other than an oxide or an oxide semiconductor. As the semiconductor material other than an oxide or an oxide semiconductor, for example, silicon, germanium, silicon germanium, silicon carbide, gallium arsenide, or the like can be used, and a single crystal semiconductor is preferably used. A transistor manufactured using a single crystal semiconductor can operate at high speed easily. On the other hand, the transistor including the oxide film can be used in a circuit utilizing a characteristic that is significantly low off-state current of about several yoctoamperes per micrometer (yA/μm) to several zeptoamperes per micrometer (zA/μm). Accordingly, the semiconductor device illustrated in FIG. 30C can be used to form a logic circuit with low power consumption, for example. Alternatively, an organic semiconductor material or the like may be used as the semiconductor material.

Although not illustrated, a semiconductor-on-insulator (SOI) substrate may be used instead of the semiconductor substrate.

The SOI substrate (also referred to as SOI wafer) includes a semiconductor substrate, a buried oxide film (also referred to as a buried oxide (BOX) layer) over the semiconductor substrate, and a semiconductor film (hereinafter referred to as an SOI layer) over the buried oxide film. As the SOI substrate, any of the following substrates can be used as appropriate: a SIMOX (Separation by IMplanted OXygen (a registered trademark of SUMCO TECHXIV Corporation)) substrate in which a BOX layer and an SOI layer are formed by implanting oxygen ions to a predetermined depth of a silicon substrate and performing high-temperature treatment; an ELTRAN (Epitaxial Layer TRANsfer (a registered trademark of Canon Inc.)) substrate formed using a porous silicon layer by anodization; a UNIBOND (a registered trademark of Soitec (S.O.I.TEC Silicon On Insulator Technologies S.A.)) substrate in which an SOI layer is formed by implanting hydrogen ions into a substrate (device wafer) provided with a thermal oxide film to form a weakened layer, bonding the substrate to another silicon substrate (handle wafer), and then separating the handle wafer from the weakened layer through heat treatment; and the like.

Note that the SOI substrate generally refers to a substrate in which an SOI layer made of a silicon thin film is provided over a silicon substrate with a BOX layer provided therebetween, but without limitation to silicon, another single crystal semiconductor material may be used. In addition, the SOI substrate includes, in its category, a substrate having a structure in which a semiconductor layer is provided over an insulating substrate such as a glass substrate with an insulating layer provided therebetween.

In the case of using the SOI substrate instead of the semiconductor substrate, the SOI layer is used for a channel region of the transistor in the lower portion. Compared with a transistor formed using a bulk silicon substrate, a transistor formed using an SOI substrate has many advantages such as small parasitic capacitance due to the presence of a BOX layer, low probability of soft errors caused by incidence of a rays or the like, no occurrence of latch-up caused by formation of a parasitic transistor, and easy element isolation.

The SOI layer includes a single crystal semiconductor such as single crystal silicon. Therefore, when the SOI layer is used for the transistor in the lower portion, the operation speed of the semiconductor device can be increased.

In FIG. 30C, either an n-channel transistor (NMOSFET) or a p-channel transistor (PMOSFET) can be used as the transistor 1072. In the example illustrated in FIG. 30C, the transistor 1072 is electrically isolated from other elements by a shallow trench isolation (STI) region 1085. The use of the STI region 1085 can reduce the generation of a bird's beak in an element isolation region, which is caused in an LOCOS element isolation method, and can reduce the size of the element isolation region. On the other hand, in a semiconductor device which is not required to be structurally miniaturized or downsized, the STI region 1085 is not necessarily formed, and an element isolation means such as LOCOS can be used. Note that a well 1081 is formed within the STI region 1085 in order to control the threshold voltage of the transistor 1072.

The transistor 1072 in FIG. 30C includes a channel formation region provided in a substrate 1080, impurity regions 1112 (also referred to as a source region and a drain region) provided such that the channel formation region is sandwiched therebetween, gate insulating films 1113 and 1114 provided over the channel formation region, and gate electrodes 1116 and 1118 provided over the gate insulating films 1113 and 1114 so as to overlap with the channel formation region. A gate electrode can have, but is not limited to, a stacked structure of the gate electrode 1116 including a first material for increasing processing accuracy and the gate electrode 1118 including a second material for decreasing the resistance as a wiring; the material, the number of stacked layers, the shape, or the like can be adjusted as appropriate for required specifications. Note that a transistor whose source electrode and drain electrode are not illustrated in a drawing may also be referred to as a transistor for the sake of convenience.

Further, although not illustrated, contact plugs are connected to the impurity regions 1112 provided in the substrate 1080. Here, the contact plugs also function as a source electrode and a drain electrode of the transistor 1072 or the like. In addition, impurity regions 1111 which are different from the impurity regions 1112 are provided between the impurity regions 1112 and the channel formation region. The impurity regions 1111 function as LDD regions or extension regions for controlling the distribution of an electric field in the vicinity of the channel formation region, depending on the concentration of an impurity introduced thereto. A sidewall insulating film 1115 is provided at the side of the gate electrodes 1116 and 1118 with an insulating film 1117 provided therebetween. By using the insulating film 1117 and the sidewall insulating film 1115, the LDD regions or extension regions can be formed.

The transistor 1072 is covered with an interlayer insulating film 1088. The interlayer insulating film 1088 can function as a protective film and can prevent impurities from entering the channel formation region from the outside. In addition, when the interlayer insulating film 1088 is formed using a material such as silicon nitride by a CVD method, in the case where single crystal silicon is used for the channel formation region, hydrogenation can be performed by heat treatment. When an insulating film having tensile stress or compressive stress is used as the interlayer insulating film 1088, distortion can be caused in the semiconductor material in the channel formation region. By subjecting a silicon material in the channel formation region to tensile stress in the case of an n-channel transistor or subjecting a silicon material in the channel formation region to compressive stress in the case of a p-channel transistor, the mobility of the transistor can be improved.

Note that the transistor 1072 illustrated in FIG. 30C may have a fin structure (also referred to as a tri-gate structure or an Q-gate structure). The fin structure refers to a structure in which part of a semiconductor substrate is processed into a plate-like projection and a gate electrode is provided so as to cross the longitudinal direction of the projection. The gate electrode covers the upper surface and the side surface of the projection with a gate insulating film provided therebetween. When the transistor 1072 has the fin structure, the channel width can be decreased so that the degree of integration of transistors can be increased. In addition, the transistor can allow more current to flow and can have higher control efficiency; thus, the off-state current and threshold voltage of the transistor can be lowered.

The capacitor 1073 is formed by a stack of an impurity region 1082 which is provided in the substrate 1080, electrodes 1084 and 1087, and an insulating film 1083 which is provided therebetween and serves as a dielectric film. Here, the insulating film 1083 is formed using the same materials as the gate insulating films 1113 and 1114 of the transistor 1072, and the electrodes 1084 and 1087 are formed using the same materials as the gate electrodes 1116 and 1118 of the transistor 1072. The impurity region 1082 can be formed at the same timing as the impurity regions 1112 of the transistor 1072.

The transistor 1071 in FIG. 30C includes an oxide film provided over a base insulating film 1101. As the transistor 1071, the transistor described in the above embodiment can be used.

The transistor 1071 manufactured using the oxide film in one embodiment of the present invention is electrically connected to a transistor including a semiconductor material such as the transistor 1072 in a lower layer, depending on a necessary circuit configuration. FIG. 30C illustrates, as one example, a structure in which a source or a drain of the transistor 1071 is electrically connected to the gate of the transistor 1072.

One of the source and the drain of the transistor 1071 manufactured using the oxide film in one embodiment of the present invention is connected to a wiring 1107a which is formed above the transistor 1071, through a contact plug 1103b which penetrates an insulating film 1102, an interlayer insulating film 1104, and an interlayer insulating film 1105 provided over the transistor 1071.

Here, contact plugs (also referred to as connecting conductive portions, embedded plugs, or simply plugs) 1086a, 1086b, 1103a, 1103b, 1103c, and the like each have a columnar or wall shape. The contact plugs are each formed by filling an opening (via) provided in an interlayer insulating film with a conductive material. As the conductive material, a conductive material with high embeddability such as tungsten or polysilicon can be used. Although not illustrated, the side surface and the bottom surface of the material can be covered with a barrier film (a diffusion prevention film) of a titanium film, a titanium nitride film, a stack of these films, or the like. In this case, the barrier film is regarded as part of the contact plug.

For example, the bottom surfaces of the contact plugs 1103b and 1103c are connected to the upper surface of the oxide film. However, the connection of the contact plugs 1103b and 1103c to the oxide film is not limited to this connection structure. For example, the contact plugs 1103b and 1103c may penetrate the oxide film and the bottom surfaces of the contact plugs 1103b and 1103c may be in contact with the upper surface of the base insulating film 1101. In this case, the connection of the contact plugs 1103b and 1103c to the oxide film is made at the side surfaces of the contact plugs 1103b and 1103c. This allows the oxide film and the contact plugs 1103b and 1103c to have better electrical contact. Furthermore, the contact plugs 1103b and 1103c may penetrate into the base insulating film 1101.

Note that one contact plug is used for electrical connection between the oxide film and the wiring 1107a or a wiring 1107b in FIG. 30C. However, in order to decrease the contact resistance between the contact plug and the oxide film or the wiring, a plurality of contact plugs arranged side by side may be used or a contact plug with a large diameter may be used.

Since the contact plugs are formed using a mask, the contact plugs can be formed in any desired position. Even in the case where a contact plug is formed over the transistor 1071 due to processing variation, the semiconductor device can be formed without losing the function of the transistor 1071 as long as the contact plug is in contact with a sidewall insulating film 1119 provided in the transistor 1071. Alternatively, when the contact plug is provided in contact with the sidewall insulating film 1119, element miniaturization can be achieved.

A wiring 1094, a wiring 1098, and the wirings 1107a and 1107b are embedded in an interlayer insulating film 1091, an interlayer insulating film 1096, and an interlayer insulating film 1108, respectively. For the wirings 1094, 1098, 1107a, and 1107b, it is preferable to use a low-resistance conductive material such as copper or aluminum. By using a low-resistance conductive material, RC delay of signals transmitted through the wirings 1094, 1098, 1107a, and 1107b can be reduced. In the case of using copper for the wirings 1094, 1098, 1107a, and 1107b, barrier films 1093, 1097, and 1106 are formed in order to prevent copper from diffusing into the channel formation regions. The barrier films can each be formed using a film of tantalum nitride, a stacked-layer film of tantalum nitride and tantalum, a film of titanium nitride, a stacked-layer film of titanium nitride and titanium, or the like for example, but are not limited to the films of these materials as long as their function of preventing diffusion of the wiring material and their adhesion to the wiring material, a base film, or the like are secured. The barrier films 1093, 1097, and 1106 may be formed as layers that are separate from the wirings 1094, 1098, 1107a, and 1107b, or may be formed in such a manner that a barrier film material contained in a wiring material is separated out by heat treatment to the inner walls of the openings provided in the interlayer insulating films 1091, 1096, and 1108.

For the interlayer insulating films 1091, 1096, and 1108, it is possible to use an insulator such as silicon oxide, silicon oxynitride, silicon nitride oxide, borophosphosilicate glass (BPSG), phosphosilicate glass (PSG), silicon oxide to which carbon is added (SiOC), silicon oxide to which fluorine is added (SiOF), tetraethylorthosilicate (TEOS) which is silicon oxide made from Si(OC₂H₅)₄, hydrogen silsesquioxane (HSQ), methyl silsesquioxane (MSQ), organosilicate glass (OSG), or an organic-polymer-based material. In the case of advancing miniaturization of the semiconductor device, parasitic capacitance between wirings is significant and signal delay is increased. Therefore, the relative permittivity of silicon oxide (k=4.0 to 4.5) is too high, and it is preferable to use a material with k=3.0 or less. In addition, since CMP treatment is performed after the wirings are embedded in the interlayer insulating films, the interlayer insulating films need to have high mechanical strength. As long as their mechanical strength can be secured, the interlayer insulating films can be made porous to have a lower dielectric constant. The interlayer insulating films 1091, 1096, and 1108 are formed by a sputtering method, a CVD method, a coating method including a spin coating method (also referred to as spin on glass (SOG)), or the like.

Interlayer insulating films 1092, 1100, and 1109 may be provided over the interlayer insulating films 1091, 1096, and 1108. The interlayer insulating films 1092, 1100, and 1109 function as etching stoppers when planarization treatment by CMP or the like is performed after the wiring material is embedded in the interlayer insulating films 1091, 1096, and 1108.

Barrier films 1095, 1099, and 1110 are provided over the wirings 1094, 1098, 1107a, and 1107b in order to prevent diffusion of the wiring material such as copper. The barrier films 1095, 1099, and 1110 may be formed not only over the wirings 1094, 1098, 1107a, and 1107b but also over the interlayer insulating films 1091, 1096, and 1108. The barrier films 1095, 1099, and 1110 can be formed using an insulating material such as silicon nitride, SiC, or SiBON. Note that in the case where the barrier films 1095, 1099, and 1110 have a large thickness, which causes an increase in capacitance between wirings, it is preferable to select a material having barrier properties and a low dielectric constant.

The wiring 1098 includes an upper wiring portion and a lower via hole portion. The lower via hole portion is connected to the wiring 1094 in a lower layer. The wiring 1098 having this structure can be formed by a so-called dual damascene method or the like. Wirings in upper and lower layers may be connected using a contact plug instead of the dual damascene method.

As the transistor 1071 illustrated in FIG. 30C, the transistor manufactured using the oxide film described in the above embodiment can be used as appropriate. The transistor 1071 has a short channel length of more than or equal to 5 nm and less than 60 nm, preferably more than or equal to 10 nm and less than or equal to 40 nm. Since the oxide film is used for the channel formation region, the transistor 1071 exhibits no or quite little short-channel effect and shows favorable electrical characteristics as a switching element.

Since the transistor 1071 has low off-sate current, the use of the transistor enables stored data to be retained for a long time. In other words, it is possible to obtain a memory device which does not require refresh operation or has an extremely low frequency of the refresh operation, which leads to a sufficient reduction in power consumption.

The wiring 1094 is provided over the transistor 1072 and the capacitor 1073. The electrodes 1084 and 1087 serving as an upper electrode of the capacitor are electrically connected to the wiring 1094 through the contact plug 1086a which penetrates the interlayer insulating film 1088 and interlayer insulating films 1089 and 1090. The gate electrode of the transistor 1072 is electrically connected to the wiring 1094 through the contact plug 1086b which penetrates the interlayer insulating films 1088, 1089, and 1090. On the other hand, the one of the source and the drain of the transistor 1071 manufactured using the oxide film for the channel is electrically connected to the wiring 1107a in an upper layer through the contact plug 1103b which penetrates the insulating film and the interlayer insulating films, and the wiring 1107a is electrically connected to the wiring 1098 through the contact plug 1103a which penetrates the insulating film, the interlayer insulating films, and the base insulating film 1101. The wiring 1098 is electrically connected to the wiring 1094 in a lower layer. Accordingly, the one of the source and the drain of the transistor 1071 is electrically connected to the upper electrode of the capacitor 1073 and the gate electrode of the transistor 1072.

Note that the electrical connection between wirings using a contact plug may be established using a plurality of contact plugs, like the connection between the wiring 1098 and the wiring 1107a illustrated in FIG. 30C, or may be established using a wall-shaped contact plug, like the connection between the electrodes 1084 and 1087 and the wiring 1094.

The above electrical connections are mere examples, and elements may be connected using a wiring different from the above wirings. For example, in FIG. 30C, two wiring layers are provided between the transistor 1071, the transistor 1072, and the capacitor 1073, but one wiring layer or three or more wiring layers may be provided. Alternatively, without wirings, elements may be electrically connected to each other through a plurality of plugs connected vertically. Furthermore, in FIG. 30C, the wirings 1094 and 1098 are formed by a damascene method (the wiring 1098 is formed by a so-called dual damascene method), but may be formed by another method.

Note that the capacitor 1073 may be omitted in the case where a capacitor is not needed. Furthermore, the capacitor 1073 may be separately provided above the transistor 1072 or above the transistor 1071.

Although not illustrated, a metal oxide film of aluminum oxide, aluminum oxynitride, gallium oxide, gallium oxynitride, yttrium oxide, yttrium oxynitride, hafnium oxide, hafnium oxynitride, or the like which has a blocking effect against oxygen, hydrogen, water, or the like is preferably provided between the base insulating film 1101 and the barrier film 1099 which functions as an impurity diffusion prevention film for the wiring 1098.

In FIG. 30C, the transistor 1071 is provided to overlap with at least part of the transistor 1072. The source region or the drain region of the transistor 1071 is preferably provided to overlap with part of the oxide film. The transistor 1071 may be provided to overlap with the capacitor 1073. When such a planar layout is employed, the area occupied by the semiconductor device can be reduced; thus, the degree of integration can be increased.

Note that although FIG. 30C shows an example where the transistor 1071 and the capacitor 1073 are provided in different layers, one embodiment of the present invention is not limited to this structure. For example, the transistor 1071 and the capacitor 1073 may be provided in the same plane. With such a structure, memory cells having similar structures can be disposed so as to overlap with each other, in which case a large number of memory cells can be integrated in an area for one memory cell. Accordingly, the degree of integration of the semiconductor device can be improved.

As described above, the transistor 1072 provided in a lower portion of the semiconductor device by using a semiconductor material is electrically connected to the transistor 1071 provided in an upper portion by using the oxide film in one embodiment of the present invention, through a plurality of contact plugs and a plurality of wirings. With the above-described structure in which the transistor including a semiconductor material and being capable of operating at high speed is combined with the transistor including the oxide film in one embodiment of the present invention and having significantly low off-state current, a semiconductor device including a logic circuit capable of operating at high speed with low power consumption can be manufactured.

In addition, since data can be retained for a long time and data writing does not require high voltage as compared to the case of a flash memory, a semiconductor device including a memory circuit capable of operating at high speed with low power consumption can be manufactured.

Such a semiconductor device is not limited to the above structure and can be changed as desired unless it deviates from the spirit of the present invention. For example, in the above description, two wiring layers are provided between the transistor including a semiconductor material and the transistor including the oxide film in one embodiment of the present invention, but one wiring layer or three or more wiring layers may be provided, or without wirings, the transistors may be directly connected through only a contact plug. In this case, a through-silicon via (TSV) technique can also be used, for example. In addition, in the above description, a material such as copper is embedded in an interlayer insulating film as a wiring, but a wiring having a three-layer structure of a barrier film\a wiring material layer\a barrier film, for example, may be obtained by patterning through a photolithography process.

In the case where a copper wiring is formed in a tier between the transistor 1072 including a semiconductor material and the transistor 1071 including the oxide film in one embodiment of the present invention, it is particularly necessary to take into consideration the influence of heat treatment performed in the process for manufacturing the transistor 1071 including the oxide film in one embodiment of the present invention. In other words, it is necessary to take care that the temperature of heat treatment performed in the process for manufacturing the transistor 1071 including the oxide film in one embodiment of the present invention is appropriate to the properties of the wiring material. This is because, in the case where high-temperature heat treatment is performed on a component of the transistor 1071 for example, thermal stress is caused in the copper wiring, leading to a problem such as stress migration.

Here, when any of the transistors including an oxide film described in the above embodiment is used as the transistor 1071, charge accumulated in the node 1079 can be prevented from leaking through the transistor 1071 because the off-state current of the transistor is extremely small. Therefore, data can be retained for a long period. Further, a voltage necessary for writing data does not need to be high as compared to the case of a flash memory; thus, power consumption can be made lower and operation speed can be made higher.

As described above, according to one embodiment of the present invention, a memory with high degree of integration and low power consumption can be provided.

Note that the above memory may be provided as one function in another LSI, e.g., an arithmetic processing unit such as a CPU.

17277 0424

As described above, according to one embodiment of the present invention, a memory with high degree of integration and low power consumption can be provided.

Note that the above memory may be provided as one function in another LSI, e.g., an arithmetic processing unit such as a CPU.

### [6.3.2. CPU]

A central processing unit (CPU) can be formed with the use of the transistor including the oxide film described in the above embodiment or the memory element described in the above embodiment for at least part of the CPU.

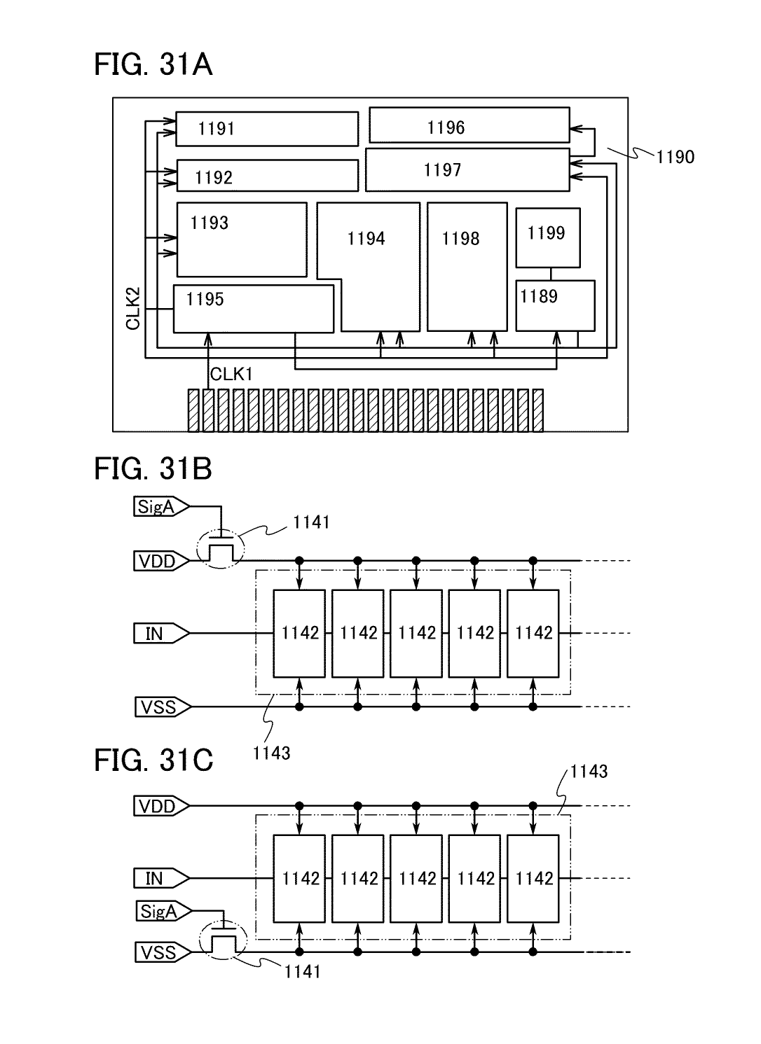

FIG. 31A is a block diagram illustrating a specific configuration of a CPU. The CPU illustrated in FIG. 31A includes an arithmetic logic unit (ALU) 1191, an ALU controller 1192, an instruction decoder 1193, an interrupt controller 1194, a timing controller 1195, a register 1196, a register controller 1197, a bus interface (Bus I/F) 1198, a rewritable ROM 1199, and a ROM interface (ROM I/F) 1189 over a substrate 1190. A semiconductor substrate, an SOI substrate, a glass substrate, or the like is used as the substrate 1190. The ROM 1199 and the ROM interface 1189 may be provided on a separate chip. Obviously, the CPU illustrated in FIG. 31A is just an example in which the configuration is simplified, and actual CPUs may have various configurations depending on the application.

An instruction input to the CPU through the bus interface 1198 is input to the instruction decoder 1193, decoded therein, and then input to the ALU controller 1192, the interrupt controller 1194, the register controller 1197, and the timing controller 1195.

The ALU controller 1192, the interrupt controller 1194, the register controller 1197, and the timing controller 1195 conduct various controls based on the decoded instruction. Specifically, the ALU controller 1192 generates signals for controlling the operation of the ALU 1191. While the CPU is executing a program, the interrupt controller 1194 processes an interrupt request from an external input/output device or a peripheral circuit on the basis of its priority or a mask state. The register controller 1197 generates an address of the register 1196, and reads and writes data from and to the register 1196 depending on the state of the CPU.

The timing controller 1195 generates signals for controlling timing of operation of the ALU 1191, the ALU controller 1192, the instruction decoder 1193, the interrupt controller 1194, and the register controller 1197. For example, the timing controller 1195 is provided with an internal clock generator for generating an internal clock signal CLK2 based on a reference clock signal CLK1, and supplies the clock signal CLK2 to the above-mentioned various circuits.

In the CPU illustrated in FIG. 31A, a memory element is provided in the register 1196. The memory element described in the above embodiment can be used in the register 1196.

In the CPU illustrated in FIG. 31A, the register controller 1197 selects operation of retaining data in the register 1196 in accordance with an instruction from the ALU 1191. That is, data is retained by a flip-flop or by a capacitor in the memory element included in the register 1196. When data is retained by the flip-flop, a power supply voltage is supplied to the memory element in the register 1196. When data is retained by the capacitor, the data in the capacitor is rewritten, and supply of the power supply voltage to the memory element in the register 1196 can be stopped.

The power supply can be stopped by a switching element provided between a memory element group and a node to which a power supply potential (VDD) or a power supply potential (VSS) is supplied, as illustrated in FIG. 31B or FIG. 31C. Circuits illustrated in FIGS. 31B and 31C are described below.

FIGS. 31B and 31C each illustrate an example of a configuration using the transistor including the oxide film described in the above embodiment as a switching element for controlling supply of a power supply potential to a memory element.

The memory device illustrated in FIG. 31B includes a switching element 1141 and a memory element group 1143 including a plurality of memory elements 1142. Specifically, as each of the memory elements 1142, the memory element described in the above embodiment can be used. Each of the memory elements 1142 included in the memory element group 1143 is supplied with a high-level power supply potential (VDD) through the switching element 1141. Further, each of the memory elements 1142 included in the memory element group 1143 is supplied with a potential of a signal IN and a low-level power supply potential (VSS).

As the switching element 1141 in FIG. 31B, the transistor including the oxide film described in the above embodiment is used. The transistor has significantly low off-state current. The switching of the transistor is controlled by a signal SigA supplied to a gate thereof.

Note that FIG. 31B illustrates a configuration in which the switching element 1141 includes only one transistor; however, one embodiment of the present invention is not limited thereto. The switching element 1141 may include a plurality of transistors. In the case where the switching element 1141 includes a plurality of transistors functioning as switching elements, the plurality of transistors may be connected to each other in parallel, in series, or in combination of parallel connection and series connection.

FIG. 31C illustrates an example of a memory device in which each of the memory elements 1142 included in the memory element group 1143 is supplied with the low-level power supply potential (VSS) through the switching element 1141. The supply of the low-level power supply potential (VSS) to each of the memory elements 1142 included in the memory element group 1143 can be controlled by the switching element 1141.

When a switching element is provided between a memory element group and a node to which the power supply potential (VDD) or the power supply potential (VSS) is supplied, data can be retained even in the case where operation of a CPU is temporarily stopped and the supply of the power supply voltage is stopped; accordingly, power consumption can be reduced. For example, while a user of a personal computer does not input data to an input device such as a keyboard, the operation of the CPU can be stopped, so that power consumption can be reduced.

Although the CPU is given as an example, the transistor or the memory element can also be applied to an LSI, e.g., a digital signal processor (DSP), a graphics processing unit (GPU), a custom LSI, or a programmable logic device (PLD) such as a field programmable gate array (FPGA) or a field programmable analog array (FPAA).

### [6.3.3. Microcomputer]

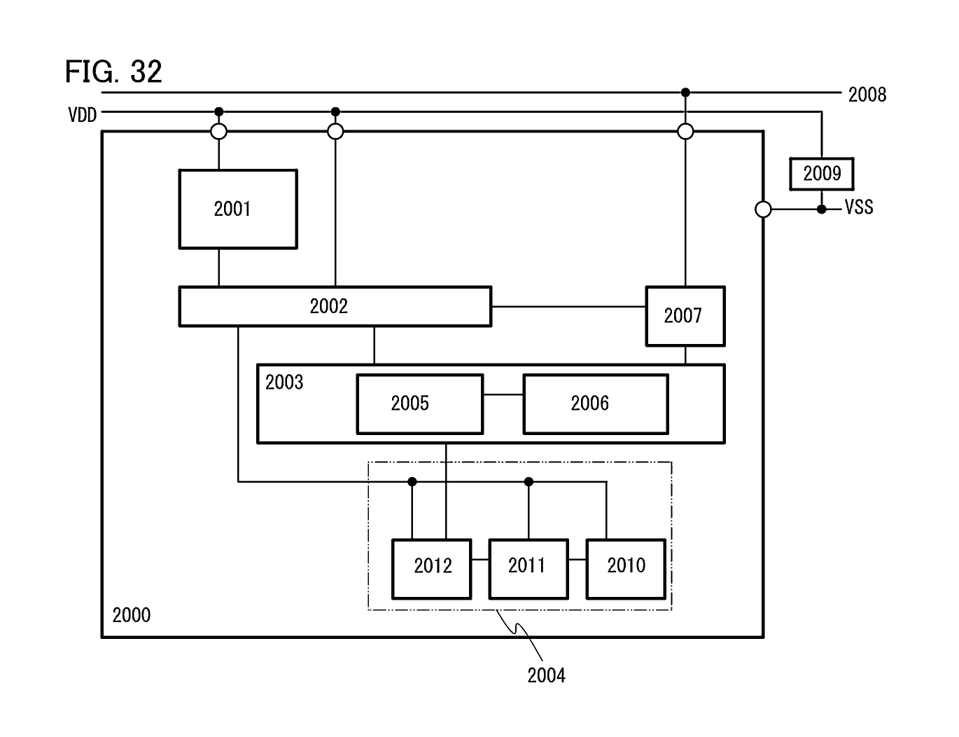

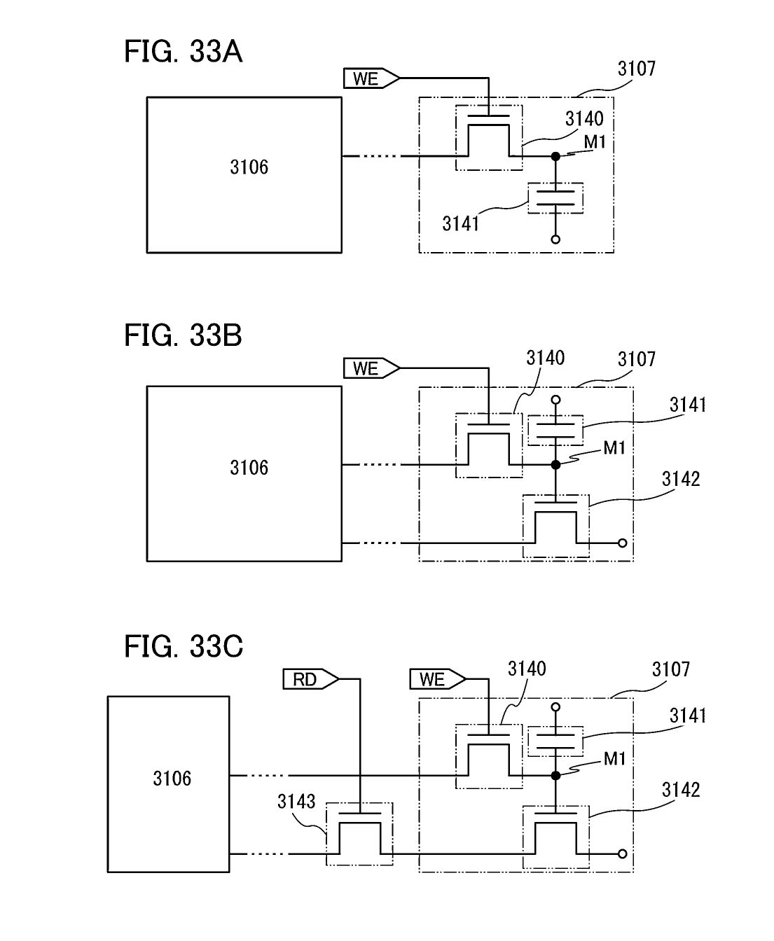

In this embodiment, a configuration and operation of one example of a microcomputer which performs arithmetic processing on a signal detected by a sensor and outputs the result of the arithmetic processing will be described with reference to FIG. 32, FIGS. 33A to 33C, FIG. 34, and FIG. 35.

FIG. 32 is a block diagram of a configuration of a microcomputer in one embodiment of the disclosed invention.

A microcomputer 2000 includes a power gate controller 2001 electrically connected to a high-potential power supply line (VDD), a power gate 2002 electrically connected to the high-potential power supply line (VDD) and the power gate controller 2001, a CPU 2003 electrically connected to the power gate 2002, and a sensing portion 2004 electrically connected to the power gate 2002 and the CPU 2003. The CPU 2003 includes a volatile memory portion 2005 and a nonvolatile memory portion 2006.

The CPU 2003 is electrically connected to a bus line 2008 through an interface 2007. Like the CPU 2003, the interface 2007 is also electrically connected to the power gate 2002. As a bus standard for the interface 2007, I²C bus or the like can be used, for example,

The power gate controller 2001 includes a timer and controls the power gate 2002 using the timer. In accordance with control by the power gate controller 2001, the power gate 2002 supplies power or stop power supply to the CPU 2003, the sensing portion 2004, and the interface 2007 from the high-potential power supply line (VDD). As the power gate 2002 here, a switching element such as a transistor can be used, for example.

The use of the power gate controller 2001 and the power gate 2002 described above makes it possible to supply power to the sensing portion 2004, the CPU 2003, and the interface 2007 in periods of sensing by a sensor and stop the power supply to the sensing portion 2004, the CPU 2003, and the interface 2007 in periods between the above periods. Such operation of the microcomputer can reduce power consumption as compared to the case where power is constantly supplied to each of the above components.

In the case where a transistor is used as the power gate 2002, it is preferable to use a transistor including an oxide film and having significantly low off-state current, which is also used in the nonvolatile memory portion 2006. By using such a transistor, leakage current during a period in which power supply is stopped by the power gate 2002 can be reduced, and power consumption can be reduced.

In the microcomputer 2000 described in this embodiment, a direct-current power source 2009 may be provided and power may be supplied from the direct-current power source 2009 to the high-potential power supply line (VDD). A high-potential-side electrode of the direct-current power source 2009 is electrically connected to the high-potential power supply line (VDD), and a low-potential-side electrode of the direct-current power source 2009 is electrically connected to a low-potential power supply line (VSS). The low-potential power supply line (VSS) is electrically connected to the microcomputer 2000. Here, the high-potential power supply line (VDD) is supplied with a high potential H. The low-potential power supply line (VSS) is supplied with a low potential L such as a ground potential (GND).

Note that the direct-current power source 2009 is not necessarily provided in the microcomputer of this embodiment; for example, power may be supplied through a wiring from an alternate-current power source which is provided outside the microcomputer.

As the power source, a secondary battery such as a lithium ion secondary battery or a lithium ion polymer secondary battery can also be used, for example. In addition, a solar cell may be provided so that the secondary battery can be charged. As the solar cell, it is possible to use any of the following: a silicon-based solar cell including a single layer or a stacked layer of single crystal silicon, polycrystalline silicon, microcrystalline silicon, or amorphous silicon; an InGaAs-based, GaAs-based, CIS-based, Cu₂ZnSnS₄-based, or CdTe—CdS-based solar cell; a dye-sensitized solar cell including an organic dye; an organic thin film solar cell including a conductive polymer, fullerene, or the like; a quantum dot solar cell having a pin structure in which a quantum dot structure is formed in an i-layer with silicon or the like; and the like.

The sensing portion 2004 measures physical quantities and transmits the measurements to the CPU 2003.

The sensing portion 2004 includes a sensor 2010 electrically connected to the power gate 2002, an amplifier 2011 electrically connected to the power gate 2002, and an AD converter 2012 electrically connected to the power gate 2002 and the CPU 2003. The sensor 2010, the amplifier 2011, and the AD converter 2012 provided in the sensing portion 2004 operate when the power gate 2002 supplies power to the sensing portion 2004.

As the sensor 2010 here, any of a variety of sensors to which mechanical, electromagnetic, thermal, acoustic, and chemical means are applied can be used depending on the intended use of the microcomputer. Examples include a variety of sensors having a function of measuring force, displacement, position, speed, acceleration, angular velocity, rotational frequency, distance, light, liquid, magnetism, temperature, chemical substance, sound, time, hardness, electric field, electric current, voltage, electric power, radiation, flow rate, humidity, gradient, oscillation, odor, or infrared rays.

Here, it is described how the microcomputer 2000 detects a signal.

When a target physical quantity appears, disappears, or changes, a signal based on the physical quantity is input to the sensor 2010 provided in the microcomputer 2000. After the signal is input to the sensor 2010, a potential based on the input signal is input to the amplifier 2011, a potential amplified by the amplifier 2011 is input to the AD converter 2012, and a potential converted from an analog signal into a digital signal by the AD converter 2012 is transmitted to the CPU 2003. In this manner, the microcomputer including the sensor 2010 detects the appearance, disappearance, or change of a physical quantity.

By using the microcomputer 2000 including the sensing portion 2004 described above, an alarm device such as a fire alarm, a gas alarm, a burglar alarm, or a security alarm can be manufactured.

The CPU 2003 performs arithmetic processing on a measurement and transmits a signal based on the result of the arithmetic processing. The signal transmitted from the CPU 2003 is output to the bus line 2008 through the interface 2007.

Furthermore, the signal is not necessarily transmitted via a wire, and may be transmitted wirelessly. For example, in addition to the microcomputer 2000 of this embodiment, a wireless chip may be provided in an electronic device.

The CPU 2003 includes the volatile memory portion 2005 and the nonvolatile memory portion 2006. Before the power gate 2002 stops power supply, data of the volatile memory portion 2005 is stored in the nonvolatile memory portion 2006, and when the power gate 2002 starts power supply, the data in the nonvolatile memory portion 2006 is restored to the volatile memory portion 2005.

The volatile memory portion 2005 includes a plurality of volatile memory elements, a circuit for controlling the plurality of volatile memory elements, and the like. Note that the volatile memory elements included in the volatile memory portion 2005 have a higher access speed than at least nonvolatile memory elements included in the nonvolatile memory portion 2006.

There is no particular limitation on the semiconductor material used for transistors included in the volatile memory elements, but it is preferable to use a material having a band gap which differs from that of a semiconductor material used for transistors having low off-state current and included in the nonvolatile memory elements. As such a semiconductor material, for example, silicon, germanium, silicon germanium, gallium arsenide, or the like can be used, and a single crystal semiconductor is preferably used. In terms of increasing the speed of data processing, it is preferable to use a transistor with high switching speed such as a transistor formed using single crystal silicon, for example.

The nonvolatile memory portion 2006 includes a plurality of nonvolatile memory elements, a circuit for controlling the plurality of nonvolatile memory elements, and the like. The nonvolatile memory elements are electrically connected to nodes where charges corresponding to data of the volatile memory elements are retained, and are used to store the data of the volatile memory elements in a period where power supply is stopped. Thus, the nonvolatile memory elements included in the nonvolatile memory portion 2006 retain data for a longer period than the volatile memory elements at least when power is not supplied.

Here, examples of configurations of the nonvolatile memory elements provided in the nonvolatile memory portion 2006 will be described with reference to FIGS. 33A to 33C.

A nonvolatile memory portion 3107 illustrated in FIG. 33A includes a transistor 3140 and a capacitor 3141 and is electrically connected to a volatile memory portion 3106 through the transistor 3140. Although the transistor 3140 is an n-channel transistor in the following description in this embodiment, a p-channel transistor may be used as appropriate, in which case a potential supplied to a gate electrode may be reversed as appropriate.

Specifically, a source electrode (or a drain electrode) of the transistor 3140 is electrically connected to a node where a charge corresponding to data of the volatile memory portion 3106 is retained. The drain electrode (or the source electrode) of the transistor 3140 is electrically connected to one electrode of the capacitor 3141 (hereinafter, this node may be referred to as a node MD. A gate electrode of the transistor 3140 is supplied with a write control signal WE, and the transistor 3140 is turned on or off depending on the potential of the write control signal WE. The other electrode of the capacitor 3141 is supplied with a predetermined potential such as a ground potential (GND). With the capacitor 3141 provided as described above, more charge can be retained at the node M1, and data retention characteristics can be improved.

As the transistor 3140, a transistor having significantly low off-state current is preferably used. The transistor having significantly low off-state current preferably includes, in a channel formation region, a wide band-gap semiconductor which has a wider band gap and a lower intrinsic carrier density than a silicon semiconductor. For example, the wide band-gap semiconductor may have a band gap greater than 1.1 eV, preferably greater than or equal to 2.5 eV and less than or equal to 4 eV, more preferably greater than or equal to 3 eV and less than or equal to 3.8 eV. As examples of such a wide band-gap semiconductor, a compound semiconductor such as silicon carbide (SiC) or gallium nitride (GaN), an oxide semiconductor including a metal oxide such as an In—Ga—Zn—O-based oxide semiconductor, and the like can be given. Furthermore, a transistor manufactured using amorphous silicon, microcrystalline silicon, or the like can have a lower off-state current than a transistor manufactured using single crystal silicon; thus, amorphous silicon, microcrystalline silicon, or the like may be used for the transistor 3140.

Here, single crystal silicon has a band gap of approximately 1.1 eV, and has a concentration of thermally excited carriers of approximately 1×10¹¹ cm⁻³ even when carriers caused by a donor or an acceptor do not exist at all (intrinsic semiconductor). In contrast, an In—Ga—Zn—O-based oxide semiconductor which is the wide band-gap semiconductor has a band gap of approximately 3.2 eV and has a concentration of thermally excited carriers of approximately 1×10⁻⁷ cm⁻³. The off-state resistance of the transistor (resistance between the source and the drain when the transistor is in an off-state) is inversely proportional to the concentration of thermally excited carriers in the channel formation region. Thus, the resistivity of the In—Ga—Zn—O-based oxide semiconductor in an off state is 18 orders of magnitude higher than that of silicon.

When such a wide band-gap semiconductor is used for the transistor 3140, the off-state current (per unit channel width (1 μm), here) at room temperature (25° C.) is less than or equal to 100 zA (1 zA (zeptoampere) is 1×10⁻²¹ A), preferably less than or equal to 10 zA, for example.

For example, when the off-state current (per unit channel width (1 μm), here) of the transistor 3140 at room temperature (25° C.) is less than or equal to 10 zA (1 zA (zeptoampere) is 1×10⁻²¹ A), data can be retained for 10⁴ seconds or longer. It is needless to say that the retention time depends on transistor characteristics or the capacitance such as a capacitance at an electrode of the transistor.

In this embodiment, as the transistor having significantly low off-state current and used as the transistor 3140, the transistor including the oxide film in one embodiment of the present invention is preferably used.

At the time of storing data of the volatile memory portion 3106, the high potential H is supplied as the write control signal WE to turn on the transistor 3140, whereby a potential of the node where the charge corresponding to the data of the volatile memory portion 3106 is retained is applied to the node M1. Then, the low potential L is supplied as the write control signal WE to turn off the transistor 3140, whereby charge applied to the node M1 is retained. Since the off-state current of the transistor 3140 is significantly low, the charge at the node M1 is retained for a long time.

At the time of restoring the data to the volatile memory portion 3106, the high potential H is supplied as the write control signal WE to turn on the transistor 3140, whereby the potential of the node M1 is applied to the node where the charge corresponding to the data of the volatile memory portion 3106 is retained.

With the use of a wide band-gap semiconductor or the like for the transistor 3140, the off-state current of the transistor 3140 can be significantly low. Thus, when the transistor 3140 is turned off, the potential of the node M1 can be retained for a very long time. With such a configuration, the nonvolatile memory portion 3107 can be used as a nonvolatile memory element which is capable of retaining data without power supply.

The nonvolatile memory portion 3107 may further include a transistor 3142 as illustrated in FIG. 33B, besides the components illustrated in FIG. 33A. A gate electrode of the transistor 3142 is electrically connected to the node M1; a drain electrode (or a source electrode) of the transistor 3142 is electrically connected to the node where the charge corresponding to the data of the volatile memory portion 3106 is retained; and the source electrode (or the drain electrode) of the transistor 3142 is supplied with a predetermined potential.

In the nonvolatile memory portion 3107 illustrated in FIG. 33B, the state of the transistor 3142 changes depending on the potential retained at the node M1 at the time of the data storing. That is, in the case where the high potential H is supplied at the time of the data storing, the transistor 3142 is turned on, and in the case where the low potential L is supplied, the transistor 3142 is turned off.

At the time of restoring the data, the potential of the drain electrode of the transistor 3142 is applied to the node where the charge corresponding to the data of the volatile memory portion 3106 is retained. That is, in the case where the high potential H is applied to the node M1 at the time of the data storing, the transistor 3142 is turned on, and the potential of the source electrode of the transistor 3142 is applied to the volatile memory portion 3106. In the case where the low potential L is applied to the node M1 at the time of the data storing, the transistor 3142 is turned off, and the potential of the source electrode of the transistor 3142 is not applied to the volatile memory portion 3106.

In terms of increasing the speed of data reading, a transistor similar to the transistor that is used for the volatile memory element is preferably used as the transistor 3142.

Note that the source electrode of the transistor 3142 and the other electrode of the capacitor 3141 may be at the same potential or at different potentials. The source electrode of the transistor 3142 may be electrically connected to the other electrode of the capacitor 3141. The capacitor 3141 is not necessarily provided; for example, in the case where the transistor 3142 has large parasitic capacitance, the parasitic capacitance may be substituted for the capacitor 3141.

Here, the drain electrode of the transistor 3140 and the gate electrode of the transistor 3142, i.e., the node M1, have an effect similar to that of a floating gate of a floating gate transistor which is used as a nonvolatile memory element. However, injection of an electric charge into a floating gate and extraction of an electric charge from the floating gate with the use of a high voltage are not needed because data can be directly rewritten by turning on and off the transistor 3140. That is, the nonvolatile memory portion 3107 does not require a high voltage which is needed for writing or erasing of a conventional floating gate transistor. Thus, with the use of the nonvolatile memory portion 3107 described in this embodiment, the consumption of power at the time of data storing can be reduced.

For a similar reason, a decrease in operation speed due to data writing operation or data erasing operation can be prevented; thus, the operation speed of the nonvolatile memory portion 3107 can be increased. Further, for a similar reason, there is no problem of deterioration of a gate insulating film (a tunnel insulating film), which arises in a conventional floating gate transistor. This means that unlike a conventional floating gate transistor, the nonvolatile memory portion 3107 described in this embodiment has no limit on the number of write cycles in principle. Therefore, the nonvolatile memory portion 3107 can be adequately used as a memory device which is required to be rewritable a large number of times and capable of high-speed operation, such as a register.

The nonvolatile memory portion 3107 may further include a transistor 3143 as illustrated in FIG. 33C, besides the components illustrated in FIG. 33B. A gate electrode of the transistor 3143 is supplied with a read control signal RD; a drain electrode (or a source electrode) of the transistor 3143 is electrically connected to the node where the charge corresponding to the data of the volatile memory portion 3106 is retained; and the source electrode (or the drain electrode) of the transistor 3143 is electrically connected to the drain electrode of the transistor 3142.

Here, the read control signal RD is a signal for supplying the high potential H to the gate electrode of the transistor 3143 at the time of the data restoring; at this time, the transistor 3143 can be turned on. Accordingly, at the time of the data restoring, a potential based on whether the transistor 3142 is in an on state or in an off state can be applied to the node where the charge corresponding to the data of the volatile memory portion 3106 is retained.

In terms of increasing the speed of data reading, a transistor similar to the transistor that is used for the volatile memory element is preferably used as the transistor 3143.

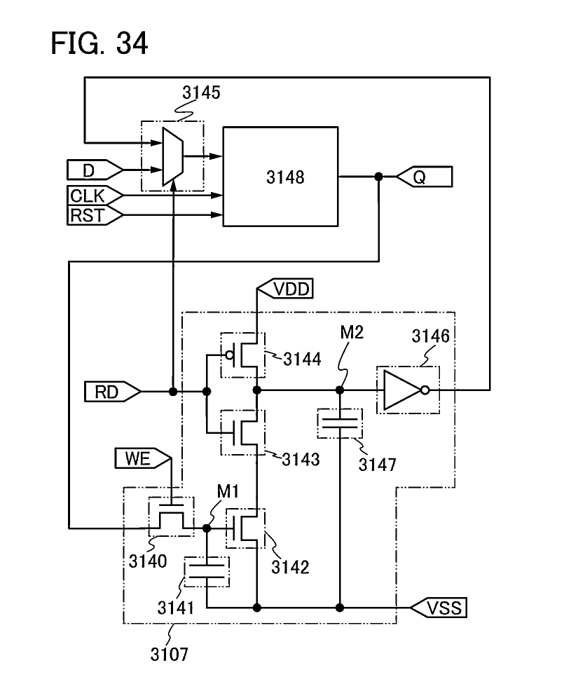

FIG. 34 illustrates an example of a circuit configuration of a nonvolatile register which is capable of retaining one-bit data and includes the nonvolatile memory portion 3107 having the configuration illustrated in FIG. 33C. Note that the same reference numerals are used in FIG. 34 to denote components corresponding to those in FIG. 33C.

The circuit configuration of the register illustrated in FIG. 34 includes a flip-flop 3148, the nonvolatile memory portion 3107, and a selector 3145. Note that in the register illustrated in FIG. 34, the flip-flop 3148 is provided as the volatile memory portion 3106 illustrated in FIG. 33C.

The flip-flop 3148 is supplied with a reset signal RST, a clock signal CLK, and a data signal. The flip-flop 3148 has a function of retaining data of a data signal D input thereto in accordance with the clock signal CLK and outputting the data as a data signal Q.

The nonvolatile memory portion 3107 is supplied with the write control signal WE, the read control signal RD, and the data signal D.

The nonvolatile memory portion 3107 has a function of storing data of the data signal D input thereto in accordance with the write control signal WE and outputting the stored data as the data signal D in accordance with the read control signal RD.

The selector 3145 selects the data signal D or the data signal output from the nonvolatile memory portion 3107 in accordance with the read control signal RD and inputs the selected data signal to the flip-flop 3148.

As illustrated in FIG. 34, in the nonvolatile memory portion 3107, the transistor 3140 and the capacitor 3141 are provided.

The transistor 3140 is an n-channel transistor. One of source and drain electrodes of the transistor 3140 is electrically connected to an output terminal of the flip-flop 3148. The transistor 3140 has a function of controlling the retention of the data signal output from the flip-flop 3148 in accordance with the write control signal WE.

As the transistor 3140, a transistor including an oxide film and having low off-state current can be used as in the configuration illustrated in FIG. 33C.

One of a pair of electrodes of the capacitor 3141 is electrically connected to the other of the source and drain electrodes of the transistor 3140 (hereinafter, this node may be referred to as a node MD. The other of the pair of electrodes of the capacitor 3141 is supplied with the low potential L. The capacitor 3141 has a function of retaining a charge based on the data of the data signal D stored therein at the node M1. Since the transistor 3140 has significantly low off-state current, the charge at the node M1 is retained and the data is retained even when the supply of a power supply voltage is stopped.

A transistor 3144 is a p-channel transistor. One of source and drain electrodes of the transistor 3144 is supplied with the high potential H, and the read control signal RD is input to a gate electrode of the transistor 3144. The power supply voltage corresponds to a difference between the high potential H and the low potential L.

The transistor 3143 is an n-channel transistor. One of source and drain electrodes of the transistor 3143 is electrically connected to the other of the source and drain electrodes of the transistor 3144 (hereinafter, this node may be referred to as a node M2). The read control signal RD is input to a gate electrode of the transistor 3143.

The transistor 3142 is an n-channel transistor. One of source and drain electrodes of the transistor 3142 is electrically connected to the other of the source and drain electrodes of the transistor 3143, and the other of the source and drain electrodes of the transistor 3142 is supplied with the low potential L.

An input terminal of an inverter 3146 is electrically connected to the other of the source and drain electrodes of the transistor 3144. An output terminal of the inverter 3146 is electrically connected to an input terminal of the selector 3145.

One of a pair of electrodes of a capacitor 3147 is electrically connected to the input terminal of the inverter 3146, and the other of the pair of electrodes of the capacitor 3147 is supplied with the low potential L. The capacitor 3147 has a function of retaining a charge based on data of a data signal input to the inverter 3146.

In the register illustrated in FIG. 34 having the above configuration, at the time of storing data of the flip-flop 3148, the high potential H is supplied as the write control signal WE to turn on the transistor 3140, whereby a charge based on the data of the data signal D of the flip-flop 3148 is applied to the node M1. Then, the low potential L is supplied as the write control signal WE to turn off the transistor 3140, whereby the charge applied to the node M1 is retained. In a period where the low potential L is supplied as the read control signal RD, the transistor 3143 is in an off state, the transistor 3144 is in an on state, and the potential of the node M2 is the high potential H.

At the time of restoring the data to the flip-flop 3148, the high potential H is supplied as the read control signal RD to turn off the transistor 3144 and turn on the transistor 3143, whereby the potential corresponding to the charge retained at the node M1 is applied to the node M2. In the case where a charge corresponding to the high potential H of the data signal D is retained at the node M1, the transistor 3142 is in an on state, the low potential L is supplied to the node M2, and the high potential H is returned to the flip-flop 3148 through the inverter 3146. In the case where a charge corresponding to the low potential L of the data signal D is retained at the node M1, the transistor 3142 is in an off state, the high potential H of the node M2 at the time when the low potential L is supplied as the read control signal RD is retained, and the low potential L is returned to the flip-flop 3148 through the inverter 3146.

By providing the volatile memory portion 3106 and the nonvolatile memory portion 3107 in the CPU 2003 as described above, data of the volatile memory portion 3106 can be stored in the nonvolatile memory portion 3107 before power supply to the CPU 2003 is stopped, and the data in the nonvolatile memory portion 3107 can be quickly restored to the volatile memory portion 3106 when power supply to the CPU 2003 is restarted.

By such data storing and restoring, it becomes unnecessary to restart the CPU 2003 with the volatile memory portion 3106 in an initialized state every time power supply is stopped. Thus, after power supply is restarted, the CPU 2003 can immediately start arithmetic processing on a measurement.

Note that the above nonvolatile memory portion 3107 is not limited to the configurations illustrated in FIGS. 33A to 33C and FIG. 34. For example, a phase change memory (PCM), a resistance random access memory (ReRAM), a magnetoresistive random access memory (MRAM), a ferroelectric random access memory (FeRAM), a flash memory, or the like can be used.

The plurality of volatile memory elements included in the volatile memory portion 3106 can be included in a register such as a buffer register or a general purpose register. The volatile memory portion 3106 can be provided with a cache memory including a static random access memory (SRAM) or the like. Data of such a register or a cache memory can be stored in the nonvolatile memory portion 3107.

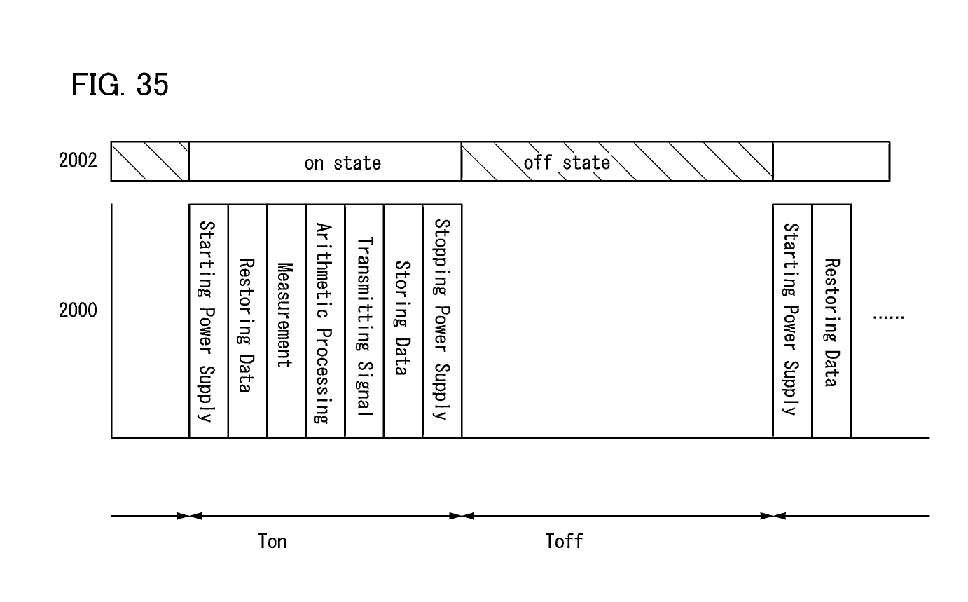

Next, operation of the microcomputer 2000 in one embodiment of the present invention will be described with reference to FIG. 35. FIG. 35 is a diagram illustrating the state of the power gate 2002 and the operation of the microcomputer 2000 in a power supply period Ton and a power supply stop period Toff.

The operation of the microcomputer 2000 is divided into an operation in the power supply period Ton and an operation in the power supply stop period Toff. In the power supply period Ton, the power gate 2002 is in an on state and power is supplied to the CPU 2003, the sensing portion 2004, and the interface 2007. In the power supply stop period Toff, the power gate 2002 is in an off state and power supply to the CPU 2003, the sensing portion 2004, and the interface 2007 is stopped.

The operation of the microcomputer 2000 in the power supply period Ton where the power gate 2002 is in an on state is described. First, by the control by the power gate controller 2001, the power gate 2002 is turned on to start power supply. At this time, power starts to be supplied to the CPU 2003, the sensing portion 2004, and the interface 2007 from the high-potential power supply line (VDD) through the power gate 2002. In the sensing portion 2004, power also starts to be supplied to the sensor 2010, the amplifier 2011, and the AD converter 2012.

Note that power does not necessarily need to be supplied to the CPU 2003, the sensing portion 2004, and the interface 2007 at the same time. For example, power can be supplied at different timings when the CPU 2003, the sensing portion 2004, and the interface 2007 are used.

Next, in the CPU 2003, data is restored from the nonvolatile memory portion 2006 to the volatile memory portion 2005. For details of the data restoring, the above description made with reference to FIGS. 33A to 33C and FIG. 34 can be referred to. By such data restoring in the CPU 2003, it becomes unnecessary to restart the CPU 2003 with the volatile memory portion 2005 in an initialized state every time the power supply period Ton starts. Thus, after power supply is restarted, the CPU 2003 can immediately start arithmetic processing.

Next, the sensing portion 2004 performs measurement of a physical quantity. A potential based on a physical quantity input to the sensor 2010 is input to the amplifier 2011, and a potential amplified by the amplifier 2011 is input to the AD converter 2012. A potential converted from an analog signal into a digital signal by the AD converter 2012 is transmitted to the CPU 2003 as a measurement obtained by the sensing portion 2004.

Next, the CPU 2003 performs arithmetic processing on the measurement transmitted from the sensing portion 2004. For example, arithmetic processing for an output is performed on the measurement transmitted from the sensing portion 2004, and a signal based on the result of the processing is transmitted. The signal based on the result of the processing is transmitted to the bus line 2008 through the interface 2007.

The signal based on the result of the processing may be transmitted directly to another electronic device electrically connected to the CPU 2003, instead of the bus line 2008.

Next, in the CPU 2003, data of the volatile memory portion 2005 is stored in the nonvolatile memory portion 2006. For details of the data storing, the above description made with reference to FIGS. 33A to 33C and FIG. 34 can be referred to.

Next, by the control by the power gate controller 2001, the power gate 2002 is turned off to stop power supply. At this time, power stops being supplied to the CPU 2003, the sensing portion 2004, and the interface 2007 from the high-potential power supply line (VDD) through the power gate 2002. In the sensing portion 2004, power also stops being supplied to the sensor 2010, the amplifier 2011, and the AD converter 2012.

Note that power supply to the CPU 2003, the sensing portion 2004, and the interface 2007 does not necessarily need to be stopped at the same time. For example, power supply can be stopped at different timings when the CPU 2003, the sensing portion 2004, and the interface 2007 stop being used.

When the power supply period Ton ends in the above manner, the power supply stop period Toff starts. Here, when the power gate controller 2001 turns off the power gate 2002, the power gate controller 2001 actuates the timer therein to start time measurement. When the passage of a certain period of time is measured with the timer, the power gate controller 2001 turns on the power gate 2002 again and the power supply period Ton is restarted. Note that the length of time measured by the timer may be changed with software.

By such different operations of the microcomputer 2000 in the power supply period Ton and the power supply stop period Toff with the power gate controller 2001 and the power gate 2002, power consumption can be reduced as compared with the case where power is constantly supplied. Since the power supply stop period Toff can be set much longer than the power supply period Ton, power consumption can be significantly reduced.

Furthermore, by providing the volatile memory portion 2005 and the nonvolatile memory portion 2006 in the CPU 2003, data of the volatile memory portion 2005 can be stored in the nonvolatile memory portion 2006 before power supply to the CPU 2003 is stopped, and the data in the nonvolatile memory portion 2006 can be quickly restored to the volatile memory portion 2005 when power supply to the CPU 2003 is restarted. Thus, after power supply is restarted, the CPU 2003 can immediately start arithmetic processing on a measurement.

With the volatile memory portion 2005 and the nonvolatile memory portion 2006 enabling such data storing and restoring, even when power consumption of the CPU 2003 is reduced by different operations in the power supply period Ton and the power supply stop period Toff, the microcomputer 2000 can be operated without a drastic increase in time necessary to start the CPU 2003.

This embodiment can be implemented in appropriate combinations with any of the other embodiments.

### 7. Seventh Embodiment

### Electric Device

In this embodiment, electric devices including the semiconductor device described in the above embodiment as a component will be described.

### [7.1. Range of Electric Devices]

Electric devices refer to industrial products including portions which operate with electric power. Electric devices include a wide range of applications for business use, industrial use, military use, and the like without being limited to consumer products such as household appliances.

Examples of electric devices include the following: display devices such as televisions and monitors, lighting devices, desktop or laptop personal computers, word processors, image reproduction devices which reproduce still images or moving images stored in recording media such as digital versatile discs (DVDs), portable or stationary audio reproduction devices such as compact disc (CD) players and digital audio players, portable or stationary radio receivers, audio recording and reproduction devices such as tape recorders and IC recorders (voice recorders), headphone stereos, stereos, remote controllers, clocks such as table clocks and wall clocks, cordless phone handsets, transceivers, cellular phones, car phones, portable or stationary game machines, pedometers, calculators, portable information terminals, electronic notebooks, e-book readers, electronic translators, audio input devices such as microphones, cameras such as still cameras and video cameras, toys, electric shavers, electric toothbrushes, high-frequency heating appliances such as microwave ovens, electric rice cookers, electric washing machines, electric vacuum cleaners, water heaters, electric fans, hair dryers, air-conditioning systems such as humidifiers, dehumidifiers, and air conditioners, dishwashing machines, dish drying machines, clothes dryers, futon dryers, electric refrigerators, electric freezers, electric refrigerator-freezers, freezers for preserving DNA, flashlights, electric power tools, alarm devices such as smoke detectors, gas alarms, and security alarms, health and medical equipment such as hearing aids, cardiac pacemakers, X-ray equipment, radiation counters, electric massagers, and dialyzers. Further examples include the following industrial equipment: guide lights, traffic lights, meters such as gas meters and water meters, belt conveyors, elevators, escalators, industrial robots, wireless relay stations, cellular base stations, power storage systems, and power storage devices for leveling the amount of power supply and smart grid. Moreover, examples of electric devices include moving objects such as electric vehicles (EV), hybrid electric vehicles (HEV) which include both an internal-combustion engine and a motor, plug-in hybrid electric vehicles (PHEV), tracked vehicles in which caterpillar tracks are substituted for wheels of the above vehicles, agricultural machines, motorized bicycles including motor-assisted bicycles, motorcycles, electric wheelchairs, electric carts, boats or ships, submarines, aircrafts such as fixed-wing aircrafts and rotary-wing aircrafts, rockets, artificial satellites, space probes, planetary probes, and spacecrafts.

### [7.2. Specific Example of Electric Device]

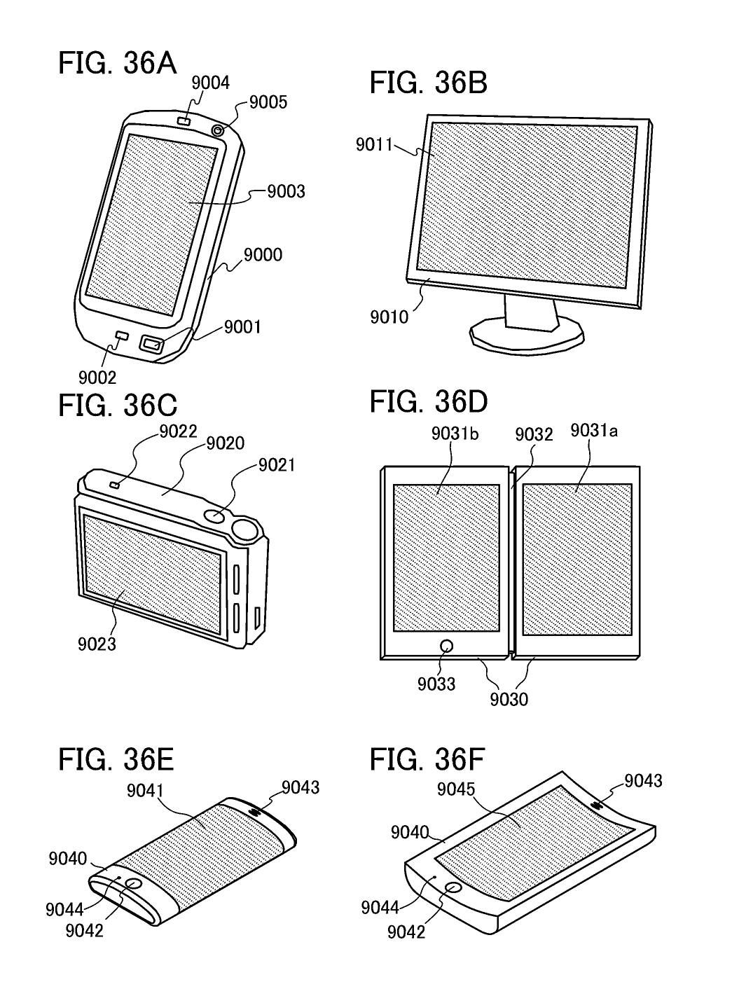

Specific examples of these electric devices are illustrated in FIGS. 36A to 36D.

FIG. 36A illustrates a portable information terminal as one example. The portable information terminal illustrated in FIG. 36A includes a housing 9000, a button 9001, a microphone 9002, a display portion 9003, a speaker 9004, and a camera 9005, and has a function as a cellular phone. One embodiment of the present invention can be applied to an arithmetic unit, a wireless circuit, or a memory circuit inside a main body. Further, one embodiment of the present invention can be applied to the display portion 9003.

FIG. 36B illustrates a display. The display illustrated in FIG. 36B includes a housing 9010 and a display portion 9011. One embodiment of the present invention can be applied to an arithmetic unit, a wireless circuit, or a memory circuit inside a main body. Further, one embodiment of the present invention can be applied to the display portion 9011.

FIG. 36C illustrates a digital still camera. The digital still camera illustrated in FIG. 36C includes a housing 9020, a button 9021, a microphone 9022, and a display portion 9023. One embodiment of the present invention can be applied to an arithmetic unit, a wireless circuit, or a memory circuit inside a main body. Further, one embodiment of the present invention can be applied to the display portion 9023.

FIG. 36D illustrates a foldable portable information terminal. The foldable portable information terminal illustrated in FIG. 36D includes housings 9030, a display portion 9031a, a display portion 9031b, a hinge 9032, and an operation switch 9033. One embodiment of the present invention can be applied to an arithmetic unit, a wireless circuit, or a memory circuit inside a main body. Further, one embodiment of the present invention can be applied to the display portion 9031a and the display portion 9031b.

Part or the whole of the display portion 9031a and/or the display portion 9031b can function as a touch panel. By touching an operation key displayed on the touch panel, a user can input data, for example.

Electric devices illustrated in FIGS. 36E and 36F are examples of portable information terminals each including a display module with a curved surface in a display portion.

The portable information terminal illustrated in FIG. 36E includes an operation button 9042, a speaker 9043, a microphone 9044 in addition to a display portion 9041 provided in a housing 9040. The portable information terminal further includes an external connection port (not illustrated) such as a stereo headphone jack, a memory card slot, a camera connector, or a USB connector.

One embodiment of the present invention can be applied to an arithmetic unit, a wireless circuit, or a memory circuit inside a main body. Further, one embodiment of the present invention can be applied to the display portion 9041. By using a substrate with a curved surface as a support substrate for display elements, a portable information terminal including a panel with a curved surface can be obtained. The display portion 9041 is an example with an outwardly curved surface.

The portable information terminal illustrated in FIG. 36F is an example which has a configuration similar to that of the portable information terminal illustrated in FIG. 36E and includes a display portion 9045 curved along a side surface of the housing 9040. The portable information terminal illustrated in FIG. 36F is an example which has a configuration similar to that of the portable information terminal illustrated in FIG. 36E and includes the display portion 9045 which is curved inwardly.

Each of the display portions of the electric devices illustrated in FIGS. 36A to 36F and the like can also function as an image sensor. For example, an image of a palm print, a fingerprint, or the like is taken by touch on the display portion with the palm or the finger, whereby personal identification can be performed. Furthermore, when a backlight or a sensing light source which emits near-infrared light is provided for the display portion, an image of a finger vein, a palm vein, or the like can also be taken. Such a function can be achieved by using the semiconductor device in one embodiment of the present invention.

Each of the electric devices and the like can be operated with a button provided on the device or a touch panel provided in the display portion, or can be operated by recognition of user's movement (gesture) (also referred to as gesture input) using a camera provided on the device, a sensor provided in the device, or the like. Alternatively, each device can be operated by recognition of user's voice (also referred to as voice input). Such operation can be achieved by using the semiconductor device in one embodiment of the present invention.

The electric devices and the like can be connected to a network. The electric devices and the like not only can display information on the Internet but also can be used as a terminal which controls another device connected to the network from a distant place. Such a function can be achieved by using the semiconductor device in one embodiment of the present invention.

With the use of the semiconductor device in one embodiment of the present invention, an electric device with high performance and low power consumption can be provided.

This embodiment can be implemented in appropriate combinations with any of the other embodiments.

### Example 1

In this example, crystal states of a sputtering target containing a polycrystalline oxide and an oxide film were measured.

### [Measurement of Sputtering Target]

The sputtering target was obtained by mixing and grinding an In₂O₃ oxide powder, a Ga₂O₃ oxide powder, and a ZnO oxide powder to obtain a slurry, molding, drying, and degreasing the slurry, and then baking it at a temperature of 1400° C. in an oxygen atmosphere. Here, the In₂O₃ oxide powder, the Ga₂O₃ oxide powder, and the ZnO oxide powder were mixed at a ratio of 1:1:1 [in molar ratio].

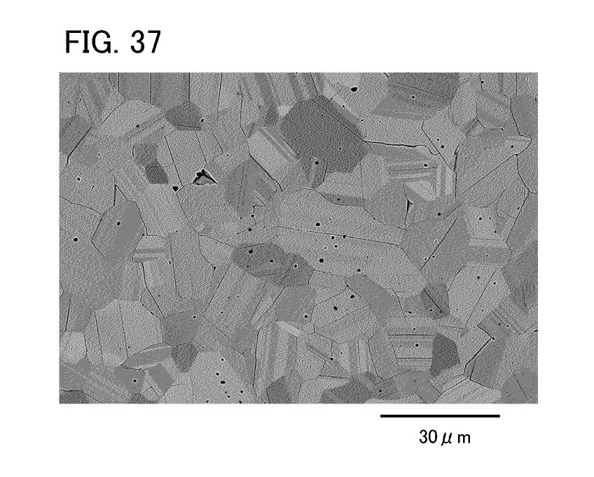

First, EBSD measurement was performed. A backscattered electron image of Sample 1 is shown in FIG. 37. FIG. 37 shows that Sample 1 is polycrystalline with a plurality of crystal grains and includes grain boundaries.

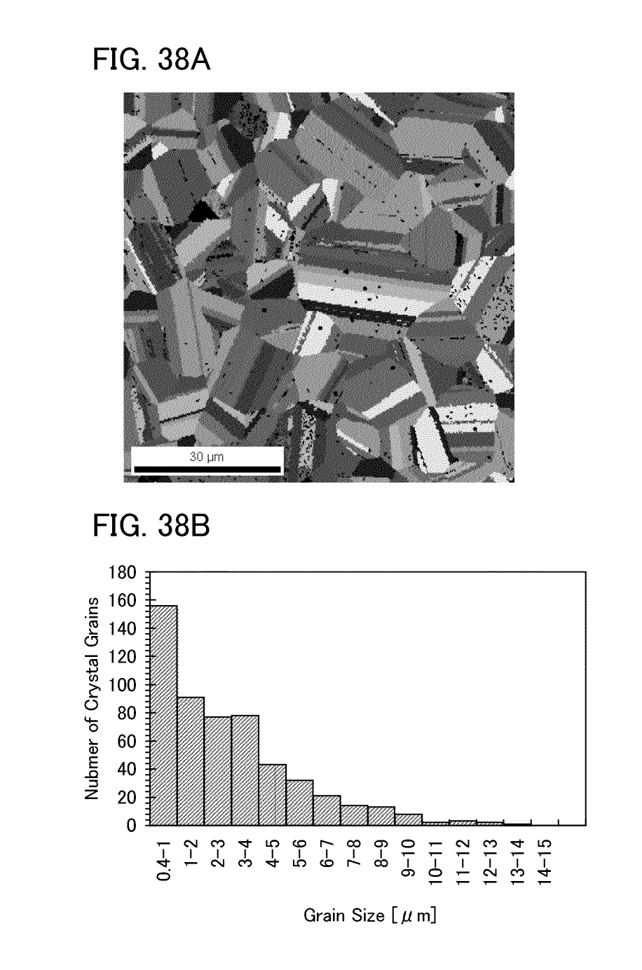

Next, a crystal grain map of Sample 1 and a histogram of crystal grain sizes are shown in FIG. 38A and FIG. 38B, respectively. Note that a square region of 80 μm×80 μm was measured at 0.3 μm steps. Under these conditions, a crystal grain with a grain size of less than about 0.4 μm cannot be counted as a crystal grain. Therefore, crystal grains which are measured to be 1 μm or less specifically have grain sizes ranging from 0.4 μm to 1 μm.

In FIG. 38A, different contrasts of crystal grains indicate different crystal orientations. This suggests that the plurality of crystal grains in the sample have random crystal orientation. In addition, FIG. 38B shows that the sample includes a plurality of crystal grains with varying grain sizes. Note that the average grain size in the sample is 4.38 μm.

### [Measurement of Oxide Film]

Next, an oxide film was formed using the sputtering target having the above composition and manufactured by the above method.

The oxide film was formed to be 300 nm thick over a glass substrate by using a DC magnetron sputtering method. As other conditions, the film formation was performed with a substrate heating temperature of 400° C., a DC power of 0.5 kW, an argon gas of 30 sccm, an oxygen gas of 15 sccm, a pressure of 0.4 Pa, and a distance of 60 mm between the substrate and the target.

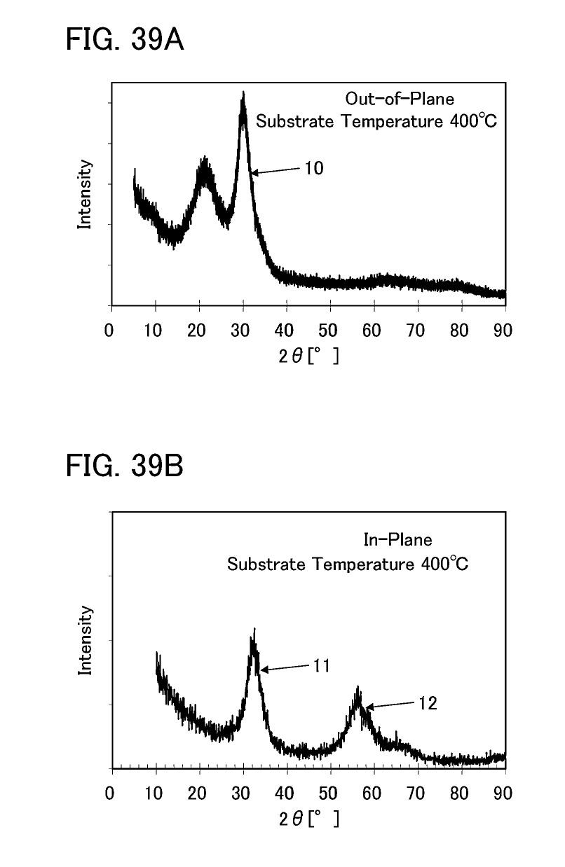

Next, a crystal state of the oxide film was measured using an X-ray diffractometer (XRD). The measurement was performed by out-of-plane 2θ/ω scan and in-plane 2θ/ω scan. FIGS. 39A and 39B show the results.

As shown in FIG. 39A, a peak 10 corresponding to diffraction from the (009) plane of InGaZnO₄ was detected from the oxide film by out-of-plane 2θ/ω scan.

In addition, as shown in FIG. 39B, a peak 11 and a peak 12 corresponding to diffraction from the (001) plane of InGaZnO₄ were detected from the oxide film by in-plane 2θ/ω scan.

The results in FIGS. 39A and 39B show that the oxide film is a c-axis aligned film.

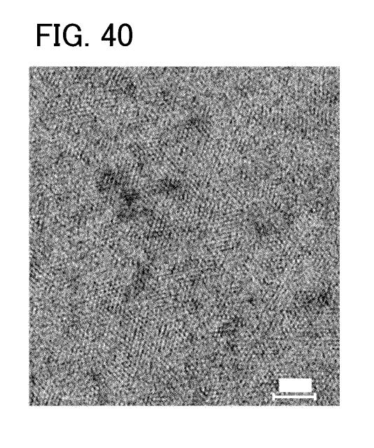

Next, a TEM observation image of the oxide film is shown in FIG. 40.

FIG. 40 shows that the oxide film has a crystalline region and that no clear grain boundary is seen in the oxide film.

As described with reference to FIG. 37, FIGS. 38A and 38B, FIGS. 39A and 39B, and FIG. 40, by employing the sputtering in one embodiment of the present invention, a c-axis aligned oxide film can be formed even in the case of using a sputtering target including a plurality of crystal grains with random c-axes.

This application is based on Japanese Patent Application serial no. 2012-230158 filed with Japan Patent Office on Oct. 17, 2012 and Japanese Patent Application serial no. 2012-263340 filed with Japan Patent Office on Nov. 30, 2012, the entire contents of which are hereby incorporated by reference.

What is claimed is:

1. A method for manufacturing an oxide film, comprising the steps of:
using a sputtering target comprising a polycrystalline oxide including a plurality of crystal grains with randomly oriented c-axes;
forming a plasma space containing an ionized inert gas in contact with the sputtering target and a substrate;
separating particles from a cleavage plane which is parallel to a-b planes of the plurality of crystal grains by collision of the ionized inert gas with the sputtering target; and
transferring the particles to the substrate through the plasma space, maintaining shapes of the particles,
wherein the particles are charged with a same polarity, and
wherein the particles repel each other and are deposited on the substrate so as to be adjacent to each other with c-axes are substantially perpendicular to the substrate.

2. The method for manufacturing an oxide film according to claim 1, wherein the substrate is heated at a temperature higher than or equal to 100° C. and lower than or equal to 600° C. during the manufacture of the oxide film.

3. The method for manufacturing an oxide film according to claim 1, wherein the substrate is heated at a temperature higher than or equal to 150° C. and lower than or equal to 450° C. during the manufacture of the oxide film.

4. The method for manufacturing an oxide film according to claim 1, wherein the particles are positively charged.

5. The method for manufacturing an oxide film according to claim 1, wherein the sputtering target comprises indium, gallium, zinc, and oxygen.

6. The method for manufacturing an oxide film according to claim 1, further comprising the step of removing water adsorbed on the substrate before the separation.

7. The method for manufacturing an oxide film according to claim 1, wherein each of the plurality of crystal grains has a crystal structure in a form of a hexagonal prism.

8. The method for manufacturing an oxide film according to claim 1, wherein the substrate has an amorphous structure.

9. The method for manufacturing an oxide film according to claim 1, wherein the particles are separated at the same time.

10. The method for manufacturing an oxide film according to claim 1, wherein the particles are separated at different timings.

11. The method for manufacturing an oxide film according to claim 1, wherein each of the particles has a flat plate shape.

12. A method for using a sputtering target, comprising the steps of:
sputtering a target comprising a polycrystalline oxide including a plurality of crystal grains with randomly oriented c-axes so that a plurality of particles are separated from the sputtering target, and
depositing the plurality of particles on a substrate,
wherein the particles are charged in the step of sputtering so as to repel each other during the deposition of the particles.

13. The method for using a sputtering target according to claim 12, wherein the target comprises indium, gallium, zinc, and oxygen.
